(19) United States
(12) Patent Application Publication
(10) Pub. No.: US 2025/0098429 A1
(43) Pub. Date: Mar. 20, 2025

(54) DISPLAY DEVICE, DISPLAY MODULE, AND ELECTRONIC DEVICE

(71) Applicant: SEMICONDUCTOR ENERGY LABORATORY CO., LTD., Atsugi-shi, Kanagawa-ken (JP)

(72) Inventors: Yuichi YANAGISAWA, Atsugi, Kanagawa (JP); Ryota HODO, Atsugi, Kanagawa (JP); Hiromi SAWAI, Atsugi, Kanagawa (JP); Yasunori SASAMURA, Hiratsuka, Kanagawa (JP)

(21) Appl. No.: 18/724,014

(22) PCT Filed: Dec. 16, 2022
(86) PCT No.: PCT/IB2022/062345

§ 371 Date: Jun. 25, 2024

(30) Foreign Application Priority Data
Dec. 29, 2021 (JP) 2021-215360

(51) Int. Cl. H10K 59/122; H10K 59/38

(52) U.S. Cl. CPC H10K 59/122; H10K 59/38

(57) ABSTRACT

A high-resolution display device is provided. The display device includes a first light-emitting device, a second light-emitting device, a first insulating layer, a second insulating layer, a first coloring layer, and a second coloring layer. The first light-emitting device includes a first pixel electrode, a first layer, and a common electrode in this order over the first insulating layer. The second light-emitting device includes a second pixel electrode, a second layer, and the common electrode in this order over the first insulating layer. The first insulating layer includes a groove including a region overlapping with the first pixel electrode and a region overlapping with the second pixel electrode. The second insulating layer overlaps with a side surface of the first layer, a side surface of the second layer, and the groove. The common electrode includes a portion positioned over the second insulating layer. The first coloring layer overlaps with the first light-emitting device. The second coloring layer overlaps with the second light-emitting device. The second coloring layer and the first coloring layer transmit light of different colors. The first layer and the second layer contain the same light-emitting material and are apart from each other.

### TECHNICAL FIELD

One embodiment of the present invention relates to a display device, a display module, and an electronic device. One embodiment of the present invention relates to a method for manufacturing a display device.

Note that one embodiment of the present invention is not limited to the above technical field. Examples of the technical field of one embodiment of the present invention include a semiconductor device, a display device, a light-emitting apparatus, a power storage device, a memory device, an electronic device, a lighting device, an input device (e.g., a touch sensor), an input/output device (e.g., a touch panel), a method for driving any of them, and a method for manufacturing any of them.

### BACKGROUND ART

Recent display devices have been expected to be applied to a variety of uses. Usage examples of large-sized display devices include a television device for home use (also referred to as TV or television receiver), digital signage, and a PID (Public Information Display). Examples of a portable information terminal include a smartphone and a tablet terminal.

Furthermore, display devices have been required to have higher resolution. As devices requiring high-resolution display devices, for example, devices for virtual reality (VR), augmented reality (AR), substitutional reality (SR), or mixed reality (MR) have been actively developed.

Light-emitting apparatuses including light-emitting devices (also referred to as light-emitting elements) have been developed as display devices, for example. Light-emitting devices (also referred to as EL devices or EL elements) utilizing electroluminescence (hereinafter referred to as EL) have features such as ease of reduction in thickness and weight, high-speed response to input signals, and driving with a constant DC voltage power source, and have been used in display devices.

Patent Document 1 discloses a display device using an organic EL device (also referred to as organic EL element) for VR.

### REFERENCE

### Patent Document

[Patent Document 1] PCT International Publication No. 2018/087625

### SUMMARY OF THE INVENTION

### Problems to be Solved by the Invention

In a wearable device for VR, AR, SR, or MR, a lens for focus adjustment is provided between eyes and a display device. Since part of the screen is enlarged by the lens, low resolution of the display device might cause a problem of weak sense of reality and immersion. An object of one embodiment of the present invention is to provide a high-resolution display device. An object of one embodiment of the present invention is to provide a high-definition display device. An object of one embodiment of the present invention is to provide a highly reliable display device.

An object of one embodiment of the present invention is to provide a method for manufacturing a high-resolution display device. An object of one embodiment of the present invention is to provide a method for manufacturing a high-definition display device. An object of one embodiment of the present invention is to provide a method for manufacturing a highly reliable display device. An object of one embodiment of the present invention is to provide a method for manufacturing a display device with high yield.

Note that the description of these objects does not preclude the existence of other objects. One embodiment of the present invention does not necessarily achieve all of these objects. Other objects can be derived from the description of the specification, the drawings, and the claims.

### Means for Solving the Problems

A display device includes a first light-emitting device, a second light-emitting device, a first insulating layer, a second insulating layer, a first coloring layer, and a second coloring layer. The first light-emitting device includes a first pixel electrode over the first insulating layer, a first layer over the first pixel electrode, and a common electrode over the first layer. The second light-emitting device includes a second pixel electrode over the first insulating layer, a second layer over the second pixel electrode, and the common electrode over the second layer. The first insulating layer includes a groove. The groove includes a region overlapping with the first pixel electrode and a region overlapping with the second pixel electrode. The second insulating layer overlaps with a side surface of the first layer, a side surface of the second layer, and the groove. The common electrode includes a portion positioned over the second insulating layer. The first coloring layer overlaps with the first light-emitting device. The second coloring layer overlaps with the second light-emitting device. The second coloring layer and the first coloring layer transmit light of different colors. The first layer and the second layer contain the same light-emitting material and are apart from each other.

The display device may include a material layer. In the groove, the material layer is positioned between the first insulating layer and the second insulating layer. The first layer, the second layer, and the material layer contain the same light-emitting material and are apart from each other.

The second insulating layer preferably contains an organic material and is preferably provided to fill the groove.

A display device includes a first light-emitting device, a second light-emitting device, a first insulating layer, a second insulating layer, a first coloring layer, and a second coloring layer. The first light-emitting device includes a first pixel electrode over the first insulating layer, a first layer over the first pixel electrode, and a common electrode over the first layer. The second light-emitting device includes a second pixel electrode over the first insulating layer, a second layer over the second pixel electrode, and the common electrode over the second layer. The first insulating layer includes a first groove and a second groove in a region between the first pixel electrode and the second pixel electrode in a top view. The second insulating layer overlaps with a side surface of the first layer, a side surface of the second layer, the first groove, and the second groove. The common electrode includes a portion positioned over the second insulating layer. The first coloring layer overlaps with the first light-emitting device. The second coloring layer overlaps with the second light-emitting device. The second coloring layer and the first coloring layer transmit light of different colors. The first layer and the second layer contain the same light-emitting material and are apart from each other.

The display device may include a first material layer and a second material layer. In the first groove, the first material layer is positioned between the first insulating layer and the second insulating layer. In the second groove, the second material layer is positioned between the first insulating layer and the second insulating layer. The first layer, the second layer, the first material layer, and the second material layer contain the same light-emitting material and are apart from each other.

The second insulating layer preferably contains an organic material and is preferably provided to fill the first groove and the second groove.

The first layer and the second layer each preferably contain a first light-emitting material emitting blue light and a second light-emitting material emitting light having a longer wavelength than blue light.

Alternatively, the first light-emitting device and the second light-emitting device each preferably emit blue light. In this case, the display device preferably includes a color conversion layer. The color conversion layer is preferably positioned between the first light-emitting device and the first coloring layer and preferably converts blue light into first light having a longer wavelength. The first coloring layer preferably transmits the first light, and the second coloring layer preferably transmits blue light.

Transmittance of one or two or more of red light, green light, and blue light in the second insulating layer is preferably lower than the transmittance in the first insulating layer.

The first insulating layer preferably includes a portion in contact with the first pixel electrode and a portion in contact with the second pixel electrode.

Another embodiment of the present invention is a display module including a display device with one of the above-described structures and being provided with a connector such as a flexible printed circuit board (hereinafter, denoted by an FPC) or a TCP (Tape Carrier Package). Another embodiment of the present invention is a display module including a display device with one of the above-described structures and being equipped with an integrated circuit (IC) by a COG (Chip On Glass) method, a COF (Chip On Film) method, or the like.

Another embodiment of the present invention is an electronic device including the above display module and one or more of a housing, a battery, a camera, a speaker, and a microphone.

### Effect of the Invention

According to one embodiment of the present invention, a high-resolution display device can be provided. According to one embodiment of the present invention, a high-definition display device can be provided. According to one embodiment of the present invention, a highly reliable display device can be provided.

According to one embodiment of the present invention, a method for manufacturing a high-resolution display device can be provided. According to one embodiment of the present invention, a method for manufacturing a high-definition display device can be provided. According to one embodiment of the present invention, a method for manufacturing a highly reliable display device can be provided. According to one embodiment of the present invention, a method for manufacturing a display device with high yield can be provided.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

FIG. 1A is a top view illustrating an example of a display device. FIG. 1B and FIG. 1C are cross-sectional views illustrating an example of the display device.

FIG. 2A and FIG. 2B are cross-sectional views illustrating an example of a display device.

FIG. 3A to FIG. 3D are cross-sectional views illustrating examples of a display device.

FIG. 4 is a cross-sectional view illustrating an example of a display device.

FIG. 5A to FIG. 5C are cross-sectional views illustrating examples of a display device.

FIG. 6A and FIG. 6B are top views illustrating an example of a display device.

FIG. 7A is a top view illustrating an example of a display device. FIG. 7B and FIG. 7C are cross-sectional views illustrating an example of the display device.

FIG. 8A and FIG. 8B are top views illustrating examples of display devices.

FIG. 9A to FIG. 9C are cross-sectional views illustrating examples of display devices.

FIG. 10A and FIG. 10B are cross-sectional views illustrating an example of a display device.

FIG. 11A to FIG. 11C are cross-sectional views illustrating examples of a display device.

FIG. 12A and FIG. 12B are cross-sectional views illustrating examples of a display device.

FIG. 13A to FIG. 13C are cross-sectional views illustrating examples of a display device.

FIG. 14A to FIG. 14C are cross-sectional views illustrating examples of a display device.

FIG. 15A and FIG. 15B are cross-sectional views illustrating examples of a display device.

FIG. 16A to FIG. 16E are cross-sectional views illustrating an example of a method for manufacturing a display device.

FIG. 17A to FIG. 17G are diagrams illustrating examples of a pixel.

FIG. 18A to FIG. 18I are diagrams illustrating examples of a pixel.

FIG. 19A and FIG. 19B are perspective views illustrating an example of a display device.

FIG. 20 is a cross-sectional view illustrating an example of a display device.

FIG. 21 is a cross-sectional view illustrating an example of a display device.

FIG. 22 is a cross-sectional view illustrating an example of a display device.

FIG. 23 is a cross-sectional view illustrating an example of a display device.

FIG. 24 is a cross-sectional view illustrating an example of a display device.

FIG. 25 is a cross-sectional view illustrating an example of a display device.

FIG. 26A to FIG. 26F are diagrams illustrating structure examples of a light-emitting device.

FIG. 27A to FIG. 27C are diagrams illustrating structure examples of a light-emitting device.

FIG. 28A to FIG. 28D are diagrams illustrating examples of an electronic device.

FIG. 29A to FIG. 29F are diagrams illustrating examples of an electronic device.

FIG. 30A to FIG. 30G are diagrams illustrating examples of an electronic device.

### MODE FOR CARRYING OUT THE INVENTION

Embodiments will be described in detail with reference to the drawings. Note that the present invention is not limited to the following description, and it is easily understood by those skilled in the art that the mode and details can be variously changed without departing from the spirit and scope of the present invention. Therefore, the present invention should not be construed as being limited to the description in the following embodiments.

Note that in structures of the invention described below, the same portions or portions having similar functions are denoted by the same reference numerals in different drawings, and the description thereof is not repeated. The same hatching pattern is used for portions having similar functions, and the portions are not denoted by specific reference numerals in some cases.

The position, size, range, or the like of each component illustrated in drawings does not represent the actual position, size, range, or the like in some cases for easy understanding. Therefore, the disclosed invention is not necessarily limited to the position, size, range, or the like disclosed in the drawings.

Note that in this specification and the like, ordinal numbers such as “first” and “second” are used for convenience and do not limit the number of components or the order of components (e.g., the order of steps or the stacking order of layers). An ordinal number used for a component in a certain part in this specification is not the same as an ordinal number used for the component in another part in this specification or claims in some cases.

The term “film” and the term “layer” can be interchanged with each other depending on the case or circumstances. For example, the term “conductive layer” can be replaced with the term “conductive film”. As another example, the term “insulating film” can be replaced with the term “insulating layer”.

In this specification and the like, a device manufactured using a metal mask or an FMM (a fine metal mask or a high-resolution metal mask) is sometimes referred to as a device having an MM (metal mask) structure. In this specification and the like, a device manufactured without using a metal mask or an FMM is sometimes referred to as a device having an MML (metal maskless) structure.

In this specification and the like, a hole or an electron is sometimes referred to as a carrier. Specifically, a hole-injection layer or an electron-injection layer may be referred to as a carrier-injection layer, a hole-transport layer or an electron-transport layer may be referred to as a carrier-transport layer, and a hole-blocking layer or an electron-blocking layer may be referred to as a carrier-blocking layer. Note that the above-described carrier-injection layer, carrier-transport layer, and carrier-blocking layer cannot be clearly distinguished from each other on the basis of the cross-sectional shape, properties, or the like in some cases. One layer may have two or three functions of the carrier-injection layer, the carrier-transport layer, and the carrier-blocking layer in some cases.

In this specification and the like, a light-emitting device (also referred to as a light-emitting element) includes an EL layer between a pair of electrodes. The EL layer includes at least a light-emitting layer. Examples of layers (also referred to as functional layers) included in the EL layer include a light-emitting layer, a hole-injection layer, an electron-injection layer, a hole-transport layer, an electron-transport layer, a hole-blocking layer, and an electron-blocking layer. In this specification and the like, one of the pair of electrodes may be referred to as a pixel electrode and the other may be referred to as a common electrode.

Note that in this specification and the like, the term “island shape” refers to a state where two or more layers formed using the same material in the same step are physically separated from each other. For example, “island-shaped light-emitting layer” means a state where the light-emitting layer and its adjacent light-emitting layer are physically separated from each other.

Note that in this specification and the like, disconnection refers to a phenomenon in which a layer, a film, or an electrode is divided because of the shape of the formation surface (e.g., a step).

In this specification and the like, a tapered shape refers to a shape in which part or the whole of the side surface of a structure is inclined to a substrate surface or a formation surface. In this specification and the like, the angle between the inclined side surface and the substrate surface is referred to as a taper angle in some cases. Note that each of the side surface of the structure, the substrate surface, and the formation surface is not necessarily completely flat and may be substantially flat with a slight curvature or substantially flat with slight unevenness.

### Embodiment 1

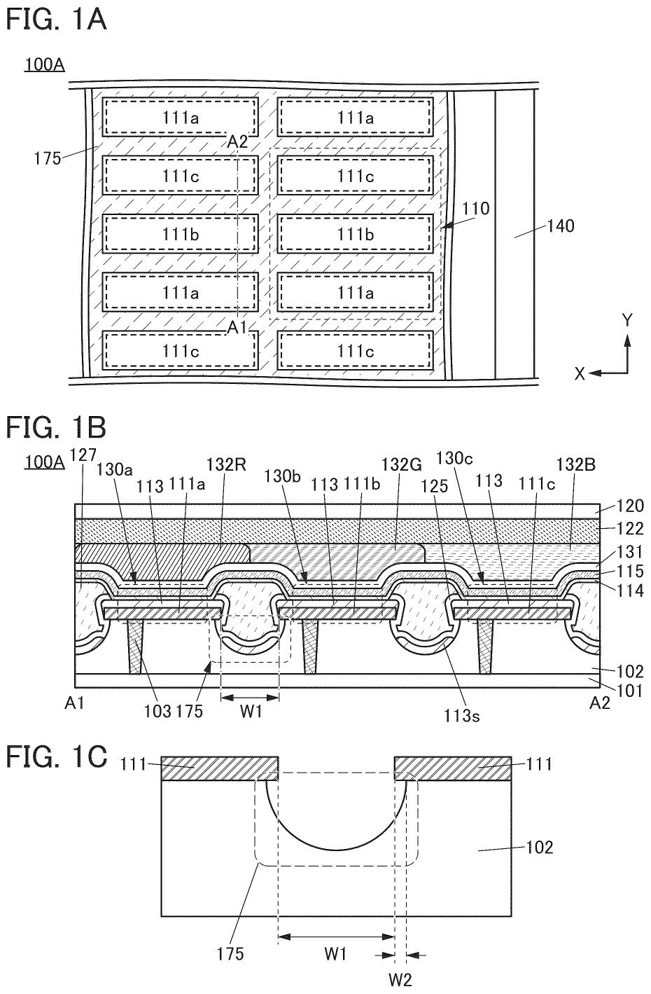

In this embodiment, a display device of one embodiment of the present invention will be described with reference to FIG. 1 to FIG. 15.

The display device of one embodiment of the present invention includes a plurality of subpixels in a pixel. The subpixels include light-emitting devices containing the same light-emitting material. Some or all of the subpixels include coloring layers and/or color conversion layers at positions overlapping with the light-emitting devices. For example, coloring layers that transmit visible light of different colors are provided for the subpixels, whereby the display device can perform full-color display. The presence or absence of a color conversion layer and kinds of color conversion layers to be used are made different among the subpixels, whereby the display device can perform full-color display.

In the case where light-emitting devices containing the same light-emitting material are used, layers included in the light-emitting devices other than a pixel electrode (e.g., a light-emitting layer) can be used in common between a plurality of subpixels. Therefore, the plurality of subpixels can share one continuous film. However, some of the layers included in the light-emitting devices have relatively high conductivity. When the plurality of subpixels share a continuous film with high conductivity, leakage current might be generated between adjacent subpixels. Particularly when an increase in the resolution or the aperture ratio of a display device reduces the distance between adjacent subpixels, the leakage current might become too large to ignore and cause a decrease in display quality of the display device. For example, current leaking to an adjacent light-emitting device might cause light emission from an undesired light-emitting device (such a phenomenon is also referred to as crosstalk).

In view of the above, in the display device of one embodiment of the present invention, at least one layer included in an EL layer is formed into an island shape in each light-emitting device. When at least one layer included in the EL layer is separately formed for each light-emitting device, occurrence of crosstalk between adjacent subpixels can be inhibited. This enables the display device to have high color reproducibility and high contrast, so that the display device can have both high resolution and high display quality. Note that in the display device of one embodiment of the present invention, some layers included in EL layers may be formed into island shapes in some subpixels; in that case, the layers may be formed as continuous layers in the other subpixels. In that case, the continuous layer preferably has a locally thinned portion. With the structure in which the EL layer has a small thickness portion (also referred to as a thin portion), occurrence of crosstalk between adjacent subpixels can be inhibited.

For example, an island-shaped EL layer can be formed by a vacuum evaporation method using a metal mask. However, this method causes a deviation from the designed shape and position of an island-shaped EL layer due to various influences such as low accuracy of the metal mask, positional deviation between the metal mask and a substrate, a warp of the metal mask, and vapor-scattering-induced expansion of the outline of a film to be formed; accordingly, it is difficult to achieve high resolution and a high aperture ratio of the display device. In addition, the outline of the layer may blur during vapor deposition, whereby the thickness of an end portion may be small. That is, the thickness of the island-shaped EL layer formed using a metal mask may vary from area to area. In the case where a display device with a large size, high definition, or high resolution is manufactured, the manufacturing yield might be reduced because of low dimensional accuracy of the metal mask and a change in shape due to heat or the like.

In view of the above, in manufacture of the display device of one embodiment of the present invention, an island-shaped EL layer is formed without using a shadow mask (e.g., a metal mask).

For example, as the difference between the level of the top surface of an insulating layer exposed between adjacent pixel electrodes and the level of the top surface of the pixel electrode (also referred to as a step between adjacent pixel electrodes) is larger, it becomes easier to form a locally thinned portion in an EL layer and to divide the EL layer to form island-shaped EL layers for light-emitting devices. By utilizing the step between adjacent pixel electrodes, the EL layer can be locally thinned or divided in a self-aligned manner in formation of the EL layer. In other words, occurrence of crosstalk can be inhibited without increasing the number of steps, so that a display device with high color reproducibility and high contrast can be achieved.

In a method for manufacturing a display device of one embodiment of the present invention, in order to make a large step between adjacent pixel electrodes, a groove is provided in an insulating layer exposed between the adjacent pixel electrodes. An EL layer is formed after the groove is provided, whereby the EL layer can be divided with use of the groove.

Note that when the EL layer has a portion with a small thickness or the EL layer is separately formed for each light-emitting device, the light-emitting device might be short-circuited due to contact between an exposed portion of the pixel electrode and a common electrode.

In the case where a step between adjacent pixel electrodes is large, the common electrode provided over the EL layer might be disconnected due to the step.

In view of the above, in the method for manufacturing a display device of one embodiment of the present invention, an insulating layer that covers the side surface of the pixel electrode and the side surface of an island-shaped EL layer is provided. Furthermore, the insulating layer preferably covers part of the top surface of the island-shaped EL layer. Then, a common electrode is provided to cover the insulating layer and the EL layer.

This can prevent contact between the pixel electrode and the common electrode. Therefore, a short circuit of the light-emitting device can be inhibited and the reliability of the light-emitting device can be improved. Moreover, disconnection of the common electrode due to a step between adjacent pixel electrodes can be inhibited. This can inhibit a connection defect of the common electrode. Moreover, an increase in electric resistance of the common electrode, which is caused by local thinning of the common electrode, can be inhibited.

Note that in the light-emitting device, all layers included in the EL layer are not necessarily formed into island shapes, and some layers can be continuous films shared by a plurality of light-emitting devices. In the method for manufacturing the display device of one embodiment of the present invention, some layers included in the EL layer are formed into island shapes, an insulating layer that covers the side surface of the pixel electrode and the side surface of the island-shaped EL layer is provided, and then the other layers (sometimes referred to as common layers) included in the EL layer and a common electrode (also referred to as an upper electrode) are formed over the insulating layer so as to be shared by the plurality of light-emitting devices (formed as one film). For example, a carrier-injection layer and the common electrode can be formed so as to be shared by the plurality of light-emitting devices.

A formation method using a fine metal mask, for example, does not easily reduce the distance between adjacent light-emitting devices (also referred to as the shortest distance) to less than 10 μm; by contrast, the method for manufacturing a display device of one embodiment of the present invention can shorten the distance between adjacent light-emitting devices, the distance between adjacent island-shaped EL layers, or the distance between adjacent pixel electrodes to less than 10 μm, less than or equal to 8 μm, less than or equal to 5 μm, less than or equal to 3 μm, less than or equal to 2 μm, less than or equal to 1.5 μm, less than or equal to 1 μm, or less than or equal to 0.5 μm, for example, in a process over a glass substrate. Using a light exposure apparatus for LSI can further shorten the distance between adjacent light-emitting devices, the distance between adjacent island-shaped EL layers, or the distance between adjacent pixel electrodes to less than or equal to 500 nm, less than or equal to 200 nm, less than or equal to 100 nm, or even less than or equal to 50 nm, for example, in a process over a Si wafer. Accordingly, the area of a non-light-emitting region that may exist between two light-emitting devices can be significantly reduced, and the aperture ratio can be close to 100%. For example, the aperture ratio of the display device of one embodiment of the present invention is higher than or equal to 40%, higher than or equal to 50%, higher than or equal to 60%, higher than or equal to 70%, higher than or equal to 80%, or higher than or equal to 90%; that is, an aperture ratio lower than 100% can be achieved.

Increasing the aperture ratio of the display device can improve the reliability of the display device. Specifically, increasing the aperture ratio can reduce the density of current flowing to the light-emitting device which is needed for obtaining the same display; thus, the lifetime of the display device can be increased.

The display device of one embodiment of the present invention can have a resolution higher than or equal to 1000 ppi, preferably higher than or equal to 2000 ppi, further preferably higher than or equal to 3000 ppi, still further preferably higher than or equal to 5000 ppi, yet still further preferably higher than or equal to 6000 ppi, and lower than or equal to 20000 ppi or lower than or equal to 30000 ppi.

In this embodiment, cross-sectional structures of the display device of one embodiment of the present invention are mainly described, and a method for manufacturing the display device of one embodiment of the present invention will be described in detail in Embodiment 2.

[Display device 100A]

FIG. 1A illustrates a top view of a display device 100A. Note that for simplification, some components are not illustrated in a top view of a display device used in this embodiment.

FIG. 1B illustrates a cross-sectional view taken along the dashed-dotted line A1-A2 in FIG. 1A. FIG. 1C illustrates an enlarged view of a pixel electrode and the vicinity thereof. Pixel electrodes 111a, 111b, and 111c in the display device 100A illustrated in FIG. 1B each have a structure similar to that of a pixel electrode 111 illustrated in FIG. 1C. Note that for simplification, some components are not illustrated in FIG. 1C.

The display device 100A includes a display portion in which a plurality of pixels 110 are arranged and a connection portion 140 outside the display portion. A plurality of light-emitting devices are arranged in a matrix in the display portion. The connection portion 140 can also be referred to as a cathode contact portion.

The pixel 110 illustrated in FIG. 1A employs stripe arrangement. The pixel 110 illustrated in FIG. 1A is composed of three subpixels. The three subpixels emit light of different colors. Examples of the three subpixels include subpixels of three colors of red (R), green (G), and blue (B) and subpixels of three colors of yellow (Y), cyan (C), and magenta (M). The number of types of subpixels is not limited to three and may be four or more. Examples of the four subpixels include subpixels of four colors of R, G, B, and white (W), subpixels of four colors of R, G, B, and Y, and four subpixels of R, G, B, and infrared light (IR). Note that a pixel layout applicable to the display device of one embodiment of the present invention will be described in detail in Embodiment 3.

In this specification and the like, the row direction is referred to as X direction and the column direction is referred to as Y direction in some cases. The X direction and the Y direction intersect with each other and are, for example, orthogonal to each other (see FIG. 1A). FIG. 1A illustrates an example in which subpixels of different colors are arranged in the Y direction and subpixels of the same color are arranged in the X direction.

Although the plan view (also referred to as the top view) in FIG. 1A illustrates an example in which the connection portion 140 is positioned on the right side of the display portion, there is no particular limitation on the position of the connection portion 140. The connection portion 140 is provided in at least one of the upper side, the right side, the left side, and the lower side of the display portion in the top view, or may be provided in two or more sides. The connection portion 140 may be provided so as to surround the four sides of the display portion, for example. The top surface shape of the connection portion 140 can be, for example, a belt-like shape, an L shape, a U shape, or a frame-like shape. The number of the connection portions 140 can be one or more. Note that in this specification and the like, a top surface shape of a component means the contour shape of the component in a plan view. A plan view means that the component is observed from a normal direction of a surface where the component is formed or from a normal direction of a surface of a support (e.g., a substrate) where the component is formed.

As illustrated in FIG. 1B, in the display device 100A, an insulating layer 102 is provided over a layer 101 including transistors, a plug 103 is provided in an opening in the insulating layer 102, light-emitting devices 130a, 130b, and 130c are provided over the insulating layer 102, and a protective layer 131 is provided to cover these light-emitting devices. Coloring layers 132R, 132G, and 132B are provided over the protective layer 131, and a substrate 120 is attached onto the coloring layers 132R, 132G, and 132B with a resin layer 122. The coloring layer 132R is provided in a position overlapping with the light-emitting device 130a. The coloring layer 132G is provided in a position overlapping with the light-emitting device 130b. The coloring layer 132B is provided in a position overlapping with the light-emitting device 130c. In a region between adjacent light-emitting devices, an insulating layer 125 and an insulating layer 127 over the insulating layer 125 are provided.

Although FIG. 1B illustrates a plurality of cross sections of the insulating layer 125 and the insulating layer 127, the insulating layer 125 and the insulating layer 127 are each one continuous layer when the display device 100A is seen from above. In other words, the display device 100A can have a structure including one insulating layer 125 and one insulating layer 127, for example. Note that the display device 100A may include a plurality of insulating layers 125 that are separated from each other and a plurality of insulating layers 127 that are separated from each other.

The display device of one embodiment of the present invention can have any of a top-emission structure in which light is emitted in a direction opposite to the substrate where the light-emitting device is formed, a bottom-emission structure in which light is emitted toward the substrate where the light-emitting device is formed, and a dual-emission structure in which light is emitted toward both surfaces. In this embodiment, a top-emission display device is described as an example.

FIG. 1A illustrates the pixel electrode 111a included in the light-emitting device 130a, the pixel electrode 111b included in the light-emitting device 130b, and the pixel electrode 111c included in the light-emitting device 130c. FIG. 1A also illustrates a groove 175 included in the insulating layer 102. In the top view of the display portion, the groove 175 is provided in a portion of the insulating layer 102 that does not overlap with the pixel electrode. The groove 175 having such a shape can be formed using the pixel electrode (and a resist mask used in forming the pixel electrode) as a mask and thus preparation of another mask is not needed, which is preferable. The groove 175 is provided to reach dashed lines inside the pixel electrodes 111a, 111b, and 111c. That is, part of the groove 175 can be regarded as being positioned under the pixel electrodes 111a, 111b, and 111c.

Although the pixel electrodes 111a, 111b, and 111c illustrated in FIG. 1A have the same or substantially the same size, one embodiment of the present invention is not limited thereto. The aperture ratios of the light-emitting devices 130a, 130b, and 130c can each be determined as appropriate; the aperture ratios may be different from each other, or two or more of them may be equal to or substantially equal to each other.

As an example, this embodiment describes the case where the pixel 110 includes three subpixels: a subpixel emitting red light, a subpixel emitting green light, and a subpixel emitting blue light.

The subpixel emitting red light includes the light-emitting device 130a and the coloring layer 132R transmitting red light. Thus, light emitted from the light-emitting device 130a is extracted as red light to the outside of the display device through the coloring layer 132R.

The subpixel emitting green light includes the light-emitting device 130b and the coloring layer 132G transmitting green light. Thus, light emitted from the light-emitting device 130b is extracted as green light to the outside of the display device through the coloring layer 132G.

The subpixel emitting blue light includes the light-emitting device 130c and the coloring layer 132B transmitting blue light. Thus, light emitted from the light-emitting device 130c is extracted as blue light to the outside of the display device through the coloring layer 132B.

An example of blue light is light having a peak wavelength in the emission spectrum of greater than or equal to 400 nm and less than 480 nm. An example of green light is light having a peak wavelength in the emission spectrum of greater than or equal to 480 nm and less than 580 nm. An example of red light is light having a peak wavelength in the emission spectrum of greater than or equal to 580 nm and less than or equal to 700 nm.

The coloring layer is a colored layer that selectively transmits light in a specific wavelength range and absorbs light in the other wavelength ranges. As the coloring layer 132R, a color filter transmitting light in the red wavelength range can be used, for example. As the coloring layer 132G, a color filter transmitting light in the green wavelength range can be used, for example. As the coloring layer 132B, a color filter transmitting light in the blue wavelength range can be used, for example. Examples of materials that can be used for the coloring layer include a metal material, a resin material, and a resin material containing a pigment or dye.

The layer 101 including transistors includes at least a substrate and a plurality of transistors over the substrate. The layer 101 including transistors may include one or more insulating layers between the substrate and the transistors. The layer 101 including transistors may include one or more insulating layers covering the transistors.

The layer 101 including transistors preferably includes a pixel circuit for driving the light-emitting device. The layer 101 including transistors preferably includes a driver circuit (a gate driver, a source driver, or the like) for driving the pixel circuit.

Structure examples of the layer 101 including transistors will be described later in Embodiment 4.

The insulating layer 102 is provided between the layer 101 including transistors and the light-emitting devices, and includes the groove 175 (also referred to as a depressed portion) between two adjacent light-emitting devices. In that case, first layers 113 described later are formed in the state where a large step is provided between adjacent pixel electrodes, so that the first layers 113 can be easily formed separately for the light-emitting devices.

In FIG. 1A, the groove is provided between the subpixels exhibiting different colors and between the subpixels exhibiting the same color. In the display device of one embodiment of the present invention, the groove is preferably provided at least between the subpixels exhibiting different colors. This can inhibit light emission of another color caused by current flowing to an adjacent subpixel. Accordingly, high color reproducibility and high contrast can be achieved.

The insulating layer 102 may have either a single-layer structure or a stacked-layer structure of two or more layers. The insulating layer 102 can be formed using one or both of an inorganic insulating film and an organic insulating film.

Examples of an inorganic insulating film that can be used for the insulating layer 102 include an oxide insulating film, a nitride insulating film, an oxynitride insulating film, and a nitride oxide insulating film.

Examples of the oxide insulating film include a silicon oxide film, an aluminum oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film.

Note that in this specification and the like, an oxynitride refers to a material in which the oxygen content is higher than the nitrogen content, and a nitride oxide refers to a material in which the nitrogen content is higher than the oxygen content. For example, silicon oxynitride refers to a material in which the oxygen content is higher than the nitrogen content, and silicon nitride oxide refers to a material in which the nitrogen content is higher than the oxygen content.

Examples of an organic insulating material that can be used for the insulating layer 102 include an acrylic resin, a polyimide resin, an epoxy resin, an imide resin, a polyamide resin, a polyimide-amide resin, a silicone resin, a siloxane resin, a benzocyclobutene-based resin, a phenol resin, and precursors of these resins.

As illustrated in FIG. 1B and FIG. 1C, the groove 175 preferably has a downward-convex arc shape in the cross-sectional view, for example. Note that the insulating layer 102 provided with such a groove 175 can be regarded as having a concave curved shape (also referred to as a concave surface). Furthermore, the downward-convex arc shape includes a downward-convex semicircular shape. With the groove 175 having such a shape, the first layer 113 can be easily divided between adjacent light-emitting devices. Thus, leakage current can be inhibited from flowing between the adjacent light-emitting devices. Accordingly, light emission caused by the leakage current can be inhibited, so that display with high contrast can be obtained. Furthermore, even in the case where the resolution is increased, the range of choices for materials can be widened since the first layer 113 can be formed using a material with high conductivity, which facilitates an improvement in emission efficiency, a reduction in power consumption, and an improvement in reliability.

Part of the groove 175 is preferably positioned below the pixel electrode 111. In other words, the groove 175 preferably includes a region positioned below the pixel electrode 111. The groove 175 preferably includes a portion overlapping with the pixel electrode, in which case the first layer 113 can be divided more easily.

The groove 175 preferably includes, for example, a first region overlapping with the pixel electrode 111a, a second region overlapping with the pixel electrode 111b, a third region overlapping with the pixel electrode 111c, and a fourth region overlapping with none of the pixel electrodes 111a, 111b, and 111c. The fourth region is positioned between the first region and the second region, between the second region and the third region, and between the first region and the third region. The first region to the third region each overlap with an end portion of the pixel electrode. The first region can be regarded as being positioned below the pixel electrode 111a. The second region can be regarded as being positioned below the pixel electrode 111b. The third region can be regarded as being positioned below the pixel electrode 111c.

A width W1 illustrated in FIG. 1B and FIG. 1C is the Y-direction width of the groove 175 in the region not overlapping with the pixel electrode 111. Note that in the display device 100A illustrated in FIG. 1B and FIG. 1C, the width W1 can be rephrased as the shortest distance between the facing end portions of the pixel electrodes 111. A width W2 illustrated in FIG. 1C is the Y-direction width of the groove 175 in the region overlapping with the pixel electrode 111.

The width W1 is preferably 2 times or more the thickness of the first layer 113. The width W1 is preferably greater than or equal to 2 times and less than or equal to 12 times, further preferably greater than or equal to 2 times and less than or equal to 10 times, still further preferably greater than or equal to 2 times and less than or equal to 9 times the thickness of the first layer 113. This enables the groove 175 to cause disconnection of the first layer 113 so that the island-shaped first layer 113 can be easily formed over each pixel electrode 111. In that case, the first layer 113 is placed to cover the side surface and the top surface of the pixel electrode 111 as illustrated in FIG. 1B. Note that in this specification and the like, a state where a layer covers a structure body indicates a state where the layer covers part of an end surface of the structure body or a state where the layer completely covers the structure body so as to surround the end surface of the structure body.

Note that the width W1 can be adjusted as appropriate in accordance with the processing accuracy at the time of forming the groove 175, the film formation conditions of the first layer 113, and the like. In the case where the first layer 113 is formed by a vacuum evaporation method, for example, the first layer 113 might be disconnected even when the width W1 is less than 2 times the thickness of the first layer 113. For example, the width W1 may be greater than or equal to 1 time and less than or equal to 12 times, less than or equal to 10 times, or less than or equal to 9 times the thickness of the first layer 113.

The width W2 is set to a width such that the first layer 113 is disconnected. The width W2 is preferably greater than or equal to 2 nm, greater than or equal to 5 nm, greater than or equal to 10 nm, or greater than or equal to 20 nm, and less than or equal to 500 nm, less than or equal to 300 nm, less than or equal to 200 nm, less than or equal to 150 nm, or less than or equal to 100 nm.

The plug 103 electrically connects an electrode or a wiring included in the layer 101 including transistors and the pixel electrode included in the light-emitting device. The plug 103 is provided to fill the opening provided in the insulating layer 102. A surface of the insulating layer 102 that is in contact with the pixel electrode and a surface of the plug 103 that is in contact with the pixel electrode are preferably aligned or substantially aligned with each other.

Examples of a conductive material that can be used for the plug 103 include metals such as aluminum, titanium, chromium, nickel, copper, yttrium, zirconium, molybdenum, gold, silver, platinum, magnesium, iron, cobalt, palladium, tantalum, and tungsten; an alloy containing one or more of these metal materials; and a nitride of any of these metal materials. The plug 103 may have either a single-layer structure or a stacked-layer structure of two or more layers.

The plug 103 has, for example, any of a single-layer structure of an aluminum film containing silicon, a two-layer structure in which an aluminum film is stacked over a titanium film, a two-layer structure in which an aluminum film is stacked over a tungsten film, a two-layer structure in which a copper film is stacked over a copper-magnesium-aluminum alloy film, a two-layer structure in which a copper film is stacked over a titanium film, a two-layer structure in which a copper film is stacked over a tungsten film, a three-layer structure in which an aluminum film or a copper film is stacked over a titanium film or a titanium nitride film and a titanium film or a titanium nitride film is formed thereover, and a three-layer structure in which an aluminum film or a copper film is stacked over a molybdenum film or a molybdenum nitride film and a molybdenum film or a molybdenum nitride film is formed thereover. Note that an oxide such as indium oxide, tin oxide, or zinc oxide may be used. The use of copper containing manganese increases controllability of a shape by etching, which is preferable.

As the light-emitting device, for example, an OLED (Organic Light Emitting Diode) or a QLED (Quantum-dot Light-Emitting Diode) is preferably used. Examples of a light-emitting substance contained in the light-emitting device include a substance exhibiting fluorescence (a fluorescent material), a substance exhibiting phosphorescence (a phosphorescent material), a substance exhibiting thermally activated delayed fluorescence (a thermally activated delayed fluorescence (TADF) material), and an inorganic compound (e.g., a quantum dot material). An LED (Light Emitting Diode) such as a micro-LED can also be used as the light-emitting device.

The light-emitting device can emit infrared, red, green, blue, cyan, magenta, yellow, or white light, for example.

Of the pair of electrodes (the pixel electrode and the common electrode) included in the light-emitting device, an electrode through which light is extracted is preferably formed using a conductive film that transmits visible light and the other electrode through which light is not extracted is preferably formed using a conductive film that reflects visible light.

Examples of a material that forms the pair of electrodes of the light-emitting device include a metal, an alloy, an electrically conductive compound, and a mixture thereof. Specific examples of the material include metals such as aluminum, magnesium, titanium, chromium, manganese, iron, cobalt, nickel, copper, gallium, zinc, indium, tin, molybdenum, tantalum, tungsten, palladium, gold, platinum, silver, yttrium, and neodymium, and an alloy containing any of these metals in appropriate combination. Other examples of the material include indium tin oxide (In—Sn oxide, also referred to as ITO), an In—Si—Sn oxide (also referred to as ITSO), indium zinc oxide (In—Zn oxide), and an In—W—Zn oxide. Other examples of the material include an alloy containing aluminum (aluminum alloy), such as an alloy of aluminum, nickel, and lanthanum (Al—Ni—La), and an alloy containing silver, such as an alloy of silver and magnesium and an alloy of silver, palladium, and copper (also referred to as Ag—Pd—Cu or APC). Other examples of the material include elements belonging to Group 1 or Group 2 of the periodic table, which are not exemplified above (e.g., lithium, cesium, calcium, and strontium), rare earth metals such as europium and ytterbium, an alloy containing any of these metals in appropriate combination, and graphene.

The light-emitting device preferably employs a microcavity structure. Accordingly, one of the pair of electrodes included in the light-emitting device preferably includes an electrode having a transmitting property and a reflecting property with respect to visible light (a semi-transmissive and semi-reflective electrode), and the other preferably includes an electrode having a reflecting property with respect to visible light (a reflective electrode). When the light-emitting device has a microcavity structure, light obtained from the light-emitting layer can be resonated between the electrodes, whereby light emitted from the light-emitting device can be intensified. The color purity can be increased when the light-emitting device has a microcavity structure.

That is, as the electrode through which light is extracted in the light-emitting device, an electrode having a visible-light-transmitting property (a transparent electrode) or a semi-transmissive and semi-reflective electrode can be used.

The light transmittance of the transparent electrode is higher than or equal to 40%. For example, an electrode having a visible light (light with wavelengths greater than or equal to 400 nm and less than 750 nm) transmittance higher than or equal to 40% is preferably used as the transparent electrode of the light-emitting device. The semi-transmissive and semi-reflective electrode has a visible light reflectance higher than or equal to 10% and lower than or equal to 95%, preferably higher than or equal to 30% and lower than or equal to 80%. The reflective electrode has a visible light reflectance higher than or equal to 40% and lower than or equal to 100%, preferably higher than or equal to 70% and lower than or equal to 100%. These electrodes preferably have a resistivity less than or equal to 1×10⁻² Ωcm.

The pixel electrode and the common electrode may each have a single-layer structure or a stacked-layer structure.

One of the pair of electrodes included in the light-emitting device functions as an anode, and the other electrode functions as a cathode. The case where the pixel electrode functions as an anode and the common electrode functions as a cathode is described below as an example in some cases.

The light-emitting device 130a includes the pixel electrode 111a over the insulating layer 102, the island-shaped first layer 113 over the pixel electrode 111a, a common layer 114 over the first layer 113, and a common electrode 115 over the common layer 114.

The light-emitting device 130b includes the pixel electrode 111b over the insulating layer 102, the island-shaped first layer 113 over the pixel electrode 111b, the common layer 114 over the first layer 113, and the common electrode 115 over the common layer 114.

The light-emitting device 130c includes the pixel electrode 111c over the insulating layer 102, the island-shaped first layer 113 over the pixel electrode 111c, the common layer 114 over the first layer 113, and the common electrode 115 over the common layer 114.

In each of the light-emitting devices 130a, 130b, and 130c, the first layer 113 and the common layer 114 can be collectively referred to as an EL layer.

In the EL layer included in the light-emitting device, the island-shaped layer provided in each light-emitting device is referred to as the first layer 113, and the layer shared by the plurality of light-emitting devices is referred to as the common layer 114 in this specification and the like. Note that in this specification and the like, an island-shaped EL layer, an EL layer formed into an island shape, or the like sometimes refers to the first layer 113, excluding the common layer 114.

The light-emitting devices 130a, 130b, and 130c each independently include the island-shaped first layer 113. These first layers 113 are formed in the same step and have the same structure. Therefore, these first layers 113 can be regarded as containing the same light-emitting material.

The first layer 113 can be configured to emit white light. For example, the first layer 113 contains a first light-emitting material that emits blue light and a second light-emitting material that emits light having a longer wavelength than blue light.

Note that in the case where the light-emitting device including the EL layer emitting white light has a microcavity structure, light of a specific wavelength such as red, green, or blue is sometimes intensified and emitted.

For example, the first layer 113 is configured to emit white light and has a microcavity structure, whereby red light emission can be obtained from the light-emitting device 130a, green light emission can be obtained from the light-emitting device 130b, and blue light emission can be obtained from the light-emitting device 130c.

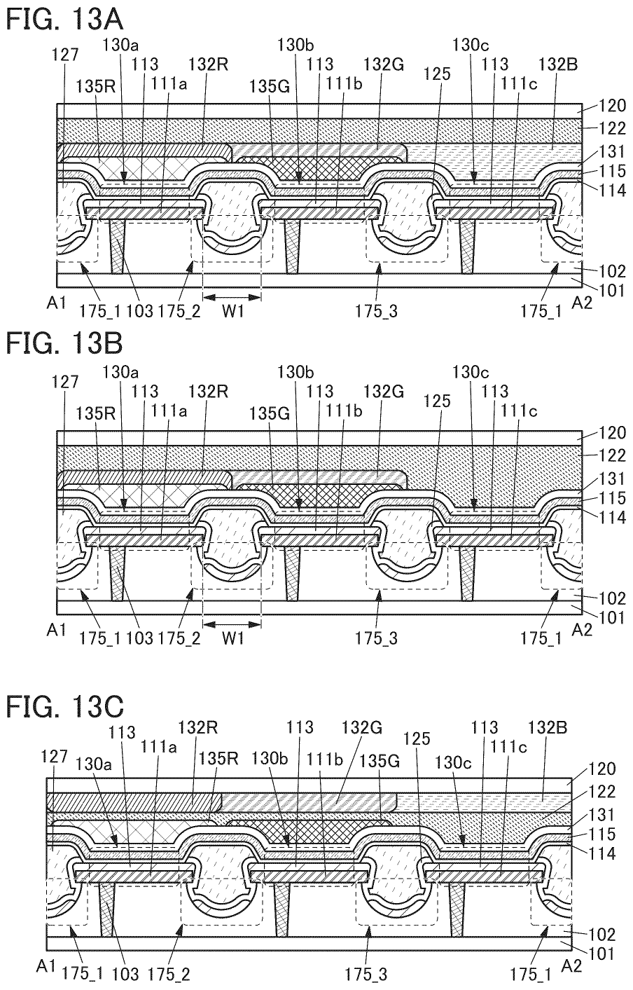

Note that the display device 100A is a structure example in which a light-emitting device and a coloring layer are combined; alternatively, a light-emitting device and a color conversion layer can be combined in the display device of one embodiment of the present invention. The structure in which a light-emitting device and a color conversion layer are combined will be described later with reference to FIG. 13 to FIG. 15.

The light-emitting device of this embodiment may have either a single structure (a structure including only one light-emitting unit) or a tandem structure (a structure including a plurality of light-emitting units). The light-emitting unit includes one or two or more light-emitting layer(s).

The first layer 113 includes at least a light-emitting layer. For example, the first layer 113 can have a structure including a light-emitting layer that emits blue light and a light-emitting layer that emits light having a longer wavelength than blue light.

In the case where a light-emitting device having a tandem structure is used, the first layer 113 can have a structure including a light-emitting unit that emits blue light and a light-emitting unit that emits light having a longer wavelength than blue light, for example. A charge-generation layer is preferably provided between the light-emitting units. The tandem structure enables a light-emitting device capable of high-luminance light emission to be obtained.

The first layer 113 may include, in addition to a light-emitting layer, one or more of a hole-injection layer, a hole-transport layer, a hole-blocking layer, a charge-generation layer, an electron-blocking layer, an electron-transport layer, and an electron-injection layer.

For example, the first layer 113 may include a hole-injection layer, a hole-transport layer, a light-emitting layer, an electron-transport layer, and an electron-injection layer in this order from the anode side. In addition, an electron-blocking layer may be provided between the hole-transport layer and the light-emitting layer. In addition, a hole-blocking layer may be provided between the electron-transport layer and the light-emitting layer.

The first layer 113 may include a first light-emitting unit, a charge-generation layer over the first light-emitting unit, and a second light-emitting unit over the charge-generation layer, for example.

The common layer 114 includes an electron-injection layer or a hole-injection layer, for example. Alternatively, the common layer 114 may include a stack of an electron-transport layer and an electron-injection layer, and may include a stack of a hole-transport layer and a hole-injection layer. The common layer 114 is shared by the light-emitting devices 130a, 130b, and 130c.

Embodiment 5 can be referred to for the details of the structure and materials of the light-emitting device.

In FIG. 1B, the first layers 113 included in the light-emitting devices are isolated from each other. When the first layer 113 is provided in an island shape for each light-emitting device, leakage current between adjacent light-emitting devices can be inhibited. This can prevent crosstalk-induced unintended light emission, so that a display device with extremely high contrast can be obtained. Specifically, a display device having high current efficiency at low luminance can be obtained.

A material layer 113s that is formed in the same step as the first layer 113 and has the same structure as the first layer 113 is positioned over the insulating layer 102 (specifically, positioned in the groove 175). The material layer 113s is a layer that is separated from the first layer 113 in formation of a layer forming the first layer 113 to be independently provided over the insulating layer 102. The material layer 113s is positioned between the insulating layer 125 and the insulating layer 102.

Note that a region where the first layer 113, the common electrode 115, and any of the pixel electrodes 111a, 111b, and 111c overlap with each other can be referred to as a light-emitting region and is a region where EL emission is obtained. The light-emitting region and the region where the material layer 113s is provided are regions where PL (Photoluminescence) emission is obtained. Thus, the light-emitting region and the region where the material layer 113s is provided can be distinguished from each other by observing EL emission and PL emission.

In FIG. 1B, an insulating layer (also referred to as a partition, a bank, a spacer, or the like) that covers an end portion of the top surface of the pixel electrode 111a is not provided between the pixel electrode 111a and the first layer 113. An insulating layer that covers an end portion of the top surface of the pixel electrode 111b is not provided between the pixel electrode 111b and the first layer 113. This allows the distance between adjacent light-emitting devices to be extremely short. As a result, a display device with high resolution or high definition can be obtained. In addition, a mask for forming the insulating layer is not needed, which leads to a reduction in manufacturing cost of the display device.

Furthermore, light emitted from the EL layer can be extracted efficiently with a structure in which an insulating layer that covers part of the top surface (also referred to as an end portion of the top surface) of the pixel electrode is not provided between the pixel electrode and the EL layer, i.e., a structure in which an insulating layer is not provided between the pixel electrode and the EL layer. Therefore, the viewing angle dependence of the display device of one embodiment of the present invention can be extremely small. A reduction in the viewing angle dependence leads to an increase in visibility of an image on the display device. For example, in the display device of one embodiment of the present invention, the viewing angle (the maximum angle with a certain contrast ratio maintained when the screen is seen from an oblique direction) can be greater than or equal to 100° and less than 180°, preferably greater than or equal to 150° and less than or equal to 170°. Note that the viewing angle refers to that in both the vertical direction and the horizontal direction.

In FIG. 1B, the first layers 113 are formed to cover the entire top surfaces of the pixel electrodes 111a, 111b, and 111c. Such a structure enables the entire top surface of the pixel electrode to be a light-emitting region. Furthermore, the aperture ratio can be easily increased as compared with the structure in which the insulating layer that covers part of the top surface of the pixel electrode is provided.

In FIG. 1B, the first layers 113 are formed to cover the side surfaces of the pixel electrodes 111a, 111b, and 111c. In other words, the end portions of the first layers 113 are positioned outward from the end portions of the pixel electrodes 111a, 111b, and 111c. This prevents direct contact between the pixel electrodes and the common electrode 115, thereby inhibiting a short circuit of the light-emitting devices.

The common electrode 115 is shared by the light-emitting devices 130a, 130b, and 130c. The common electrode 115 shared by the plurality of light-emitting devices is electrically connected to a conductive layer provided in the connection portion 140. The connection portion 140 is preferably provided with a conductive layer formed using the same material in the same step as the pixel electrodes 111a, 111b, and 111c.

The insulating layer 125 is provided to cover the side surface of the first layer 113. The insulating layer 125 may also cover part of the top surface of the first layer 113. When the insulating layer 125 covers both the side surface and part of the top surface of the first layer 113, peeling of the first layer 113 can be prevented and the reliability of the light-emitting device can be improved.

The insulating layer 125 is provided to cover the groove 175. In the groove 175, the insulating layer 125 preferably includes a portion in contact with the insulating layer 102. Specifically, the insulating layer 125 is preferably in contact with a sidewall of the groove. Thus, the pixel electrode 111 and the first layer 113 are sealed with the insulating layer 102 and the insulating layer 125. The insulating layer 125 functions as a protective layer that prevents diffusion of impurities such as water into the pixel electrode 111 and the first layer 113.

The insulating layer 125 includes an opening portion reaching the first layer 113. In the opening portion, the first layer 113 is in contact with the common layer 114. The common electrode 115 includes a region overlapping with the first layer 113 in the opening portion.

The insulating layer 125 includes a region positioned between the insulating layer 127 and the first layer 113, and functions as a protective layer for preventing the insulating layer 127 from being in contact with the first layer 113. When the first layer 113 is in contact with the insulating layer 127, the first layer 113 might be dissolved in an organic solvent or the like used in formation of the insulating layer 127. In view of the above, by employing a structure in which the insulating layer 125 is provided between the first layer 113 and the insulating layer 127 as described in this embodiment, the side surface of the first layer 113 can be protected.

The insulating layer 125 may have either a single-layer structure or a stacked-layer structure of two or more layers. The insulating layer 125 can be formed using one or both of an inorganic insulating film and an organic insulating film.

Examples of an inorganic insulating film that can be used for the insulating layer 125 include an oxide insulating film, a nitride insulating film, an oxynitride insulating film, and a nitride oxide insulating film. Specific examples of these inorganic insulating films are as listed in the description of the insulating layer 102. Alternatively, a magnesium oxide film or an indium gallium zinc oxide film may be used as the insulating layer 125. In particular, when a metal oxide film such as an aluminum oxide film or a hafnium oxide film or an inorganic insulating film such as a silicon oxide film that is formed by an ALD method is used as the insulating layer 125, it is possible to form the insulating layer 125 that has a small number of pinholes and has an excellent function of protecting the first layer 113.

The insulating layer 125 may function as a protective layer that prevents diffusion of impurities such as water into the first layer 113. As the insulating layer 125, it is preferable to use an inorganic insulating film with low moisture permeability, such as a silicon oxide film, a silicon nitride film, or an aluminum oxide film.

Between adjacent light-emitting devices, the first layers 113 are provided such that their side surfaces face each other with the insulating layer 127 therebetween. The insulating layer 127 is provided to fill the groove 175. The insulating layer 127 has a top surface with a smooth convex shape, and the common layer 114 and the common electrode 115 are provided to cover the top surface of the insulating layer 127.

The insulating layer 127 functions as a planarization film that fills a step positioned between adjacent light-emitting devices. Providing the insulating layer 127 can inhibit the common electrode 115 from being disconnected due to the groove 175.

The top surface of the insulating layer 127 preferably has a shape with higher flatness; however, it may have a projecting portion, a convex surface, a concave surface, or a depressed portion. For example, the top surface of the insulating layer 127 preferably has a smooth convex shape with high flatness.

As the insulating layer 127, an insulating layer containing an organic material can be suitably used. Specific examples of organic insulating materials that can be used for the insulating layer 127 are as listed in the description of the insulating layer 102. Examples of organic materials used for the insulating layer 127 include polyvinyl alcohol (PVA), polyvinyl butyral, polyvinyl pyrrolidone, polyethylene glycol, polyglycerin, pullulan, water-soluble cellulose, and an alcohol-soluble polyamide resin.

Moreover, a photosensitive resin can be used for the insulating layer 127. A photoresist may be used for the photosensitive resin. As the photosensitive resin, a positive photosensitive material or a negative photosensitive material can be used.

The insulating layer 127 may contain a material absorbing visible light. That is, the insulating layer 127 may be a colored layer. For example, the insulating layer 127 itself may be formed of a material absorbing visible light, or the insulating layer 127 may contain a pigment absorbing visible light. For example, for the insulating layer 127, it is possible to use a resin that can be used as a color filter transmitting red, blue, or green light and absorbing other light, a resin that contains carbon black as a pigment and functions as a black matrix, or the like.

The insulating layer 127 absorbs visible light, whereby light emitted from the light-emitting device can be inhibited from leaking to an adjacent subpixel.

The insulating layer 127 absorbs visible light, whereby light emitted from the light-emitting device can be inhibited from entering the layer 101 including transistors. For example, in the case of using, as the transistor, a transistor (an OS transistor) that includes a metal oxide (also referred to as an oxide semiconductor) in its semiconductor layer where a channel is formed, the amount of light entering the OS transistor is reduced, thereby increasing the reliability of the OS transistor. Specifically, negative-bias stress temperature photodegradation of the OS transistor can be inhibited. In that case, it is particularly preferable that the insulating layer 127 absorb blue light and light having higher energy (a shorter wavelength) than blue light.

Note that one of the insulating layer 125 and the insulating layer 127 is not necessarily provided. For example, depending on the materials or the like of the first layer 113 and the insulating layer 127, it is sometimes possible that the insulating layer 125 is not provided and the first layer 113 and the insulating layer 127 are provided to be in contact with each other. In addition, depending on the shape of the groove 175, the thicknesses of the layers included in the light-emitting device, or the like, even when the insulating layer 127 is not provided, the common electrode 115 can sometimes be formed without being disconnected.

The protective layer 131 is preferably provided over the light-emitting devices 130a, 130b, and 130c. Providing the protective layer 131 can improve the reliability of the light-emitting devices. The protective layer 131 may have either a single-layer structure or a stacked-layer structure of two or more layers.

There is no limitation on the conductivity of the protective layer 131. As the protective layer 131, one or more types of insulating films, semiconductor films, and conductive films can be used.

The protective layer 131 including an inorganic film can prevent oxidation of the common electrode 115 and inhibit entry of impurities (e.g., moisture and oxygen) into the light-emitting devices, for example. Accordingly, deterioration of the light-emitting devices can be inhibited and the reliability of the display device can be improved.

Examples of an inorganic insulating film that can be used for the protective layer 131 include an oxide insulating film, a nitride insulating film, an oxynitride insulating film, and a nitride oxide insulating film. Specific examples of these inorganic insulating films are as listed in the description of the insulating layer 102. In particular, the protective layer 131 preferably includes a nitride insulating film or a nitride oxide insulating film, and further preferably includes a nitride insulating film.

As the protective layer 131, an inorganic film containing ITO, an In—Zn oxide, a Ga—Zn oxide, an Al—Zn oxide, an indium gallium zinc oxide (In—Ga—Zn oxide, also referred to as IGZO), or the like can also be used. The inorganic film preferably has high resistance, specifically, higher resistance than the common electrode 115. The inorganic film may further contain nitrogen.

When light emitted from the light-emitting device is extracted through the protective layer 131, the protective layer 131 preferably has a high visible-light-transmitting property. For example, ITO, IGZO, and aluminum oxide are preferable because they are inorganic materials having a high visible-light-transmitting property.

The protective layer 131 can have, for example, a stacked-layer structure of an aluminum oxide film and a silicon nitride film over the aluminum oxide film, or a stacked-layer structure of an aluminum oxide film and an IGZO film over the aluminum oxide film. Such a stacked-layer structure can inhibit entry of impurities (e.g., water and oxygen) into the EL layer.

The protective layer 131 may have a stacked structure of two layers formed by different formation methods. Specifically, the first layer of the protective layer 131 may be formed by an ALD method, and the second layer of the protective layer 131 may be formed by a sputtering method.

The protective layer 131 may include an organic insulating film. Specific examples of organic insulating materials that can be used for the protective layer 131 are as listed in the description of the insulating layer 102. Examples of organic materials used for the protective layer 131 include polyvinyl alcohol (PVA), polyvinyl butyral, polyvinyl pyrrolidone, polyethylene glycol, polyglycerin, pullulan, water-soluble cellulose, and an alcohol-soluble polyamide resin. As the protective layer 131, a stacked film of an inorganic insulating film and an organic insulating film can also be used. For example, a structure in which an organic insulating film is sandwiched between a pair of inorganic insulating films is preferable. Furthermore, the organic insulating film preferably functions as a planarization film. This enables the top surface of the organic insulating film to be flat, which results in improved coverage with the inorganic insulating film thereover and a higher barrier property. The top surface of the protective layer 131 is flat, which is preferable because the influence of an uneven shape due to a component below the protective layer 131 can be reduced in the case where a component (e.g., one or more of a color filter, a color conversion layer, an electrode of a touch sensor, and a lens array) is provided above the protective layer 131.

In the case where the coloring layers 132R, 132G, and 132B and the like are directly formed over the protective layer 131 as illustrated in FIG. 1B and the like, a layer having a planarization function is preferably used as the insulating layer 131. An organic film is preferably used as the insulating layer 131, in which case the flatness of the surface of the insulating layer 131 can be increased.

A light-blocking layer may be provided on the surface of the substrate 120 on the resin layer 122 side. Moreover, a variety of optical members can be provided on the outer side of the substrate 120 (the surface opposite to the resin layer 122 side). Examples of the optical members include a polarizing plate, a retardation plate, a light diffusion layer (e.g., a diffusion film), an anti-reflective layer, and a light-condensing film. Furthermore, an antistatic film inhibiting the attachment of dust, a water repellent film inhibiting the attachment of stain, a hard coat film inhibiting generation of a scratch caused by the use, an impact-absorbing layer, or the like may be provided as a surface protective layer on the outer side of the substrate 120. For example, a glass layer or a silica layer (SiOₓ layer) is preferably provided as the surface protective layer, in which case generation of surface contamination and a scratch can be inhibited. For the surface protective layer, DLC (diamond like carbon), aluminum oxide (AlOₓ), a polyester-based material, or a polycarbonate-based material may be used, for example. For the surface protective layer, a material having a high visible light transmittance is preferably used. The surface protective layer is preferably formed using a material with high hardness.

For the substrate 120, glass, quartz, ceramic, sapphire, a resin, a metal, an alloy, or a semiconductor can be used, for example. The substrate through which light from the light-emitting device is extracted is formed using a material that transmits the light. When a flexible material is used for the substrate 120, the flexibility of the display device can be increased and a flexible display can be provided. Furthermore, a polarizing plate may be used as the substrate

For the substrate 120, for example, any of the following can be used: polyester resins such as polyethylene terephthalate (PET) and polyethylene naphthalate (PEN), a polyacrylonitrile resin, an acrylic resin, a polyimide resin, a polymethyl methacrylate resin, a polycarbonate (PC) resin, a polyethersulfone (PES) resin, polyamide resins (e.g., nylon and aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, and cellulose nanofiber. Glass that is thin enough to have flexibility may be used as the substrate 120.

In the case where a circularly polarizing plate overlaps with the display device, a highly optically isotropic substrate is preferably used as the substrate included in the display device. A highly optically isotropic substrate has a low birefringence (i.e., a small amount of birefringence).

The absolute value of a retardation (phase difference) of a highly optically isotropic substrate is preferably less than or equal to 30 nm, further preferably less than or equal to 20 nm, still further preferably less than or equal to 10 nm.

Examples of the film having high optical isotropy include a triacetyl cellulose (TAC, also referred to as cellulose triacetate) film, a cycloolefin polymer (COP) film, a cycloolefin copolymer (COC) film, and an acrylic film.

In the case where a film is used for the substrate and the film absorbs water, creases might be generated in the display device and the shape of the display device might be changed. Thus, for the substrate, a film with a low water absorption rate is preferably used. For example, a film with a water absorption rate lower than or equal to 1% is preferably used, a film with a water absorption rate lower than or equal to 0.1% is further preferably used, and a film with a water absorption rate lower than or equal to 0.01% is still further preferably used.

For the resin layer 122, a variety of curable adhesives such as a photocurable adhesive like an ultraviolet curable adhesive, a reactive curable adhesive, a thermosetting adhesive, and an anaerobic adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferable. A two-component-mixture-type resin may be used. An adhesive sheet or the like may be used.

As materials that can be used for a gate, a source, and a drain of a transistor, an electrode of a light-emitting device, and conductive layers such as wirings and electrodes included in the display device, any of metals such as aluminum, titanium, chromium, nickel, copper, yttrium, zirconium, molybdenum, silver, tantalum, and tungsten, or an alloy containing any of these metals as its main component can be given, for example. A film containing these materials can be used in a single layer or as a stacked-layer structure.

For a gate, a source, and a drain of a transistor, an electrode of a light-emitting device, and conductive layers such as wirings and electrodes included in the display device, a light-transmitting conductive material can also be used. As a light-transmitting conductive material, a conductive oxide such as indium oxide, indium tin oxide, indium zinc oxide, zinc oxide, or zinc oxide containing gallium, or graphene can be used. Alternatively, a metal material such as gold, silver, platinum, magnesium, nickel, tungsten, chromium, molybdenum, iron, cobalt, copper, palladium, or titanium, or an alloy material containing the metal material can be used. Alternatively, a nitride of the metal material (e.g., titanium nitride) or the like may be used. Note that in the case of using the metal material or the alloy material (or the nitride thereof), the material is preferably made thin enough to have a light-transmitting property. A stacked film of any of the above materials can be used for the conductive layer. For example, a stacked film of indium tin oxide and an alloy of silver and magnesium, or the like is preferably used because conductivity can be increased.

As an insulating material that can be used for each insulating layer, for example, a resin such as an acrylic resin or an epoxy resin, and an inorganic insulating material such as silicon oxide, silicon oxynitride, silicon nitride oxide, silicon nitride, or aluminum oxide can be given.

### [Display Device 100B]

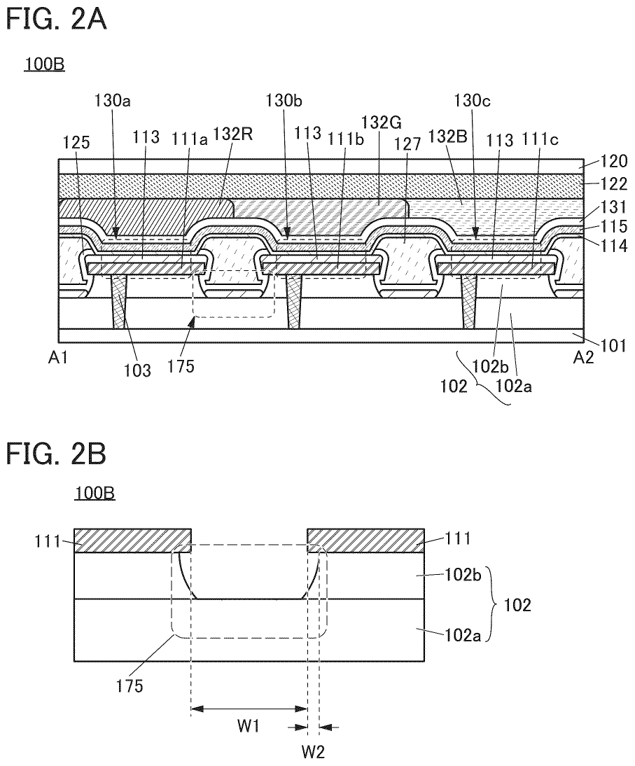

FIG. 2A illustrates a cross-sectional view of a display device 100B. FIG. 2B illustrates an enlarged view of the pixel electrode and the vicinity thereof. The pixel electrodes 111a, 111b, and 111c in the display device 100B illustrated in FIG. 2A each have a structure similar to that of the pixel electrode 111 illustrated in FIG. 2B. Note that for simplification, some components are not illustrated in FIG. 2B.

The display device 100B is different from the display device 100A illustrated in FIG. 1B in that the insulating layer 102 has a two-layer structure. The insulating layer 102 includes an insulating layer 102a over the layer 101 including transistors and an insulating layer 102b having a groove portion over the insulating layer 102a.

In the cross-sectional view, the groove 175 included in the display device 100B has a flat bottom surface and a concave curved sidewall.

The width W1 illustrated in FIG. 2B is the Y-direction width of the groove 175 in the region not overlapping with the pixel electrode 111. Note that in FIG. 2B, the width W1 can be rephrased as the shortest distance between the facing end portions of the pixel electrodes 111. The width W2 illustrated in FIG. 2B is the Y-direction width of the groove 175 in the region overlapping with the pixel electrode 111.

The insulating layer 102a is preferably formed using an insulating material that functions as an etching stopper film at the time when the groove 175 is formed by etching the insulating layer 102b. For example, in the case where a silicon oxide film or a silicon oxynitride film is used for the insulating layer 102b, it is preferable to use a silicon nitride film, an aluminum oxide film, or a hafnium oxide film for the insulating layer 102a.

The insulating layer 102a functioning as an etching stopper film can prevent the depth of the groove 175 from becoming too large even when the width W1 illustrated in FIG. 2B is large. Thus, the degree of freedom in the shape (e.g., width and depth) of the groove 175 can be increased. Note that the description of the width W1 and the width W2 illustrated in FIG. 1C can be referred to for the preferable range of the width W1 and the width W2 illustrated in FIG. 2B.

The depth of the groove 175 is preferably larger than the thickness of the first layer 113. This structure can cause disconnection of the first layer 113. Note that in FIG. 2B, the depth of the groove 175 corresponds to the thickness of the insulating layer 102b.

Although the insulating layer 102 has the stacked-layer structure of the two layers of the insulating layer 102a and the insulating layer 102b in the display device 100B, the present invention is not limited thereto. For example, the insulating layer 102 may have a stacked-layer structure of three or more layers, or one or both of the insulating layer 102a and the insulating layer 102b may have a stacked-layer structure.

### [Display Device 100C]

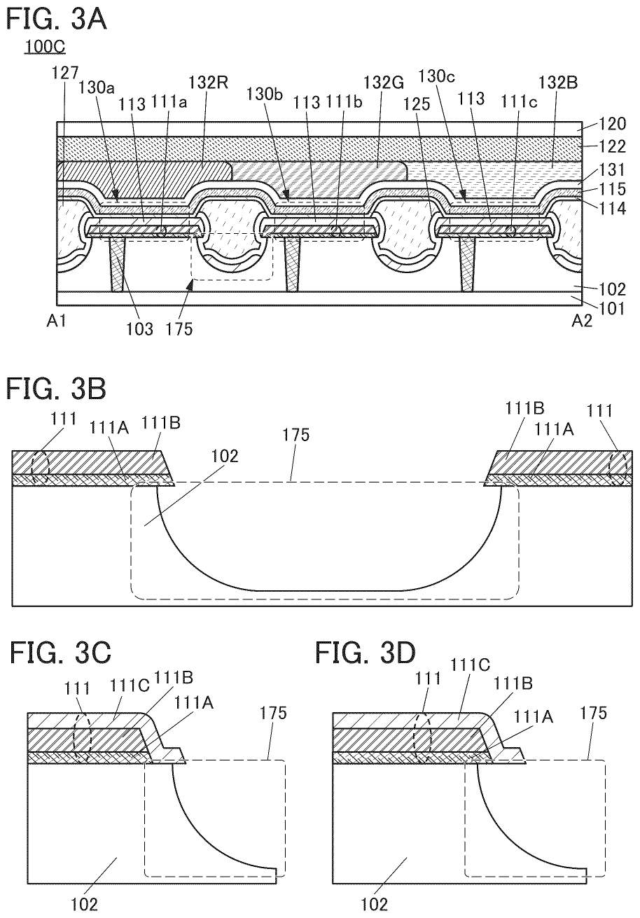

FIG. 3A illustrates a cross-sectional view of a display device 100C. The display device 100C is different from the display device 100A illustrated in FIG. 1B in the structure of the pixel electrode. FIG. 3B to FIG. 3D each illustrate an enlarged view of the pixel electrode and the vicinity thereof. Note that for simplification, some components are not illustrated in FIG. 3B to FIG. 3D.

The pixel electrodes 111a, 111b, and 111c in the display device 100C illustrated in FIG. 3A each have a structure similar to that of the pixel electrode 111 illustrated in FIG. 3B. The pixel electrode 111 illustrated in FIG. 3B includes a pixel electrode 111A and a pixel electrode 111B over the pixel electrode 111A.

The pixel electrode 111 illustrated in FIG. 3C and FIG. 3D has a three-layer structure of the pixel electrode 111A, the pixel electrode 111B over the pixel electrode 111A, and a pixel electrode 111C covering the top surfaces and the side surfaces of the pixel electrode 111A and the pixel electrode 111B.

As illustrated in FIG. 3A to FIG. 3D, the end portion of the pixel electrode may have a tapered shape. Specifically, the end portion of the pixel electrode may have a tapered shape with a taper angle less than 90° (also referred to as a forward tapered shape). Alternatively, the end portion of the pixel electrode may have a tapered shape with a taper angle greater than 90° (also referred to as an inversely tapered shape).

In FIG. 3B to FIG. 3D, a single-layer structure of a titanium nitride film is preferably used for the pixel electrode 111A. In FIG. 3B to FIG. 3D, a single-layer structure of a titanium film or a three-layer structure in which a titanium film, an aluminum film, and a titanium film are stacked in this order is preferably used for the pixel electrode 111B. Provision of a titanium nitride film for the pixel electrode 111A can inhibit the bottom surface of the pixel electrode 111B (the bottom surface of the titanium film in the above example) from being damaged when a groove is formed in the insulating layer 102. The pixel electrode 111B in FIG. 3B may include, as the uppermost layer, an ITO film or an ITSO film over the titanium film.

The pixel electrode 111C illustrated in FIG. 3C and FIG. 3D preferably includes an ITO film or an ITSO film. In the case where a single-layer structure of a titanium film is used for the pixel electrode 111B in FIG. 3C and FIG. 3D, a three-layer structure in which an ITO film, an APC film, and an ITO film are stacked in this order or a three-layer structure in which an ITSO film, an APC film, and an ITSO film are stacked in this order is preferably used for the pixel electrode 111C.

In the case where a three-layer structure in which a titanium film, an aluminum film, and a titanium film are stacked in this order is used for the pixel electrode 111B in FIG. 3C and FIG. 3D, a single-layer structure of an ITO film or a single-layer structure of an ITSO film is preferably used for the pixel electrode 111C.

Note that an aluminum film is suitable for a reflective electrode because of its high reflectivity. Meanwhile, when aluminum and an oxide conductive layer are exposed to a chemical solution in a structure in which the aluminum and the oxide conductive layer are in contact with each other, galvanic corrosion might occur. For this reason, a titanium film is preferably provided between the aluminum film and the oxide conductive layer.

The shape of the insulating layer 102 illustrated in FIG. 3C can be formed by performing a step of forming the groove 175 after formation of the pixel electrode 111C, for example. In FIG. 3C, part of the groove 175 can be regarded as being positioned under the pixel electrode 111C. Alternatively, as illustrated in FIG. 3D, part of the groove 175 may be positioned under the pixel electrodes 111A, 111B, and 111C. The shape of the insulating layer 102 illustrated in FIG. 3D can be formed by performing a step of forming the groove 175 after formation of the pixel electrode 111C, for example. Even when a step of forming the groove 175 is performed after formation of the pixel electrode 111B but before formation of the pixel electrode 111C, for example, the insulating layer 102 illustrated in FIG. 3D can be formed. The timing of forming the groove 175 can be determined as appropriate in accordance with a chemical solution used for forming the groove 175, materials of the pixel electrodes 111A, 111B, and 111C, and the like.

### [Display Device 100D]

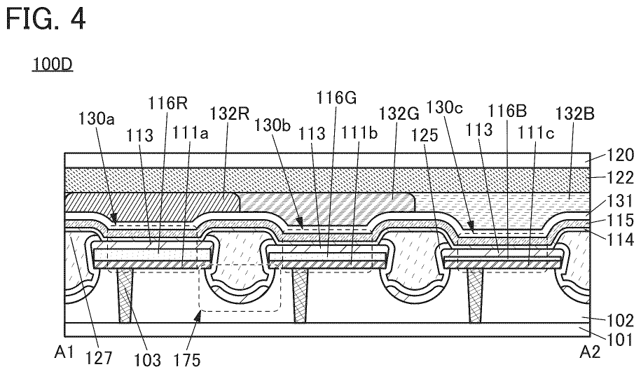

FIG. 4 illustrates a cross-sectional view of a display device 100D. The display device 100D is different from the display device 100A illustrated in FIG. 1B in that the light-emitting devices each include an optical adjustment layer.

The pixel electrodes 111a, 111b, and 111c may have different thicknesses in the display device of one embodiment of the present invention. Alternatively, optical adjustment layers with different thicknesses may be provided over the pixel electrodes 111a, 111b, and 111c in the display device of one embodiment of the present invention.

In FIG. 4, an optical adjustment layer 116R is provided over the pixel electrode 111a, an optical adjustment layer 116G is provided over the pixel electrode 111b, and an optical adjustment layer 116B is provided over the pixel electrode 111c.

FIG. 4 illustrates an example in which the thickness of the optical adjustment layer 116R is larger than the thickness of the optical adjustment layer 116G and the thickness of the optical adjustment layer 116G is larger than the thickness of the optical adjustment layer 116B. The thickness of each optical adjustment layer is preferably determined in the following manner: the thickness of the optical adjustment layer 116R is set to intensify red light, the thickness of the optical adjustment layer 116G is set to intensify green light, and the thickness of the optical adjustment layer 116B is set to intensify blue light. This achieves a microcavity structure, so that the color purity of light emitted from each light-emitting device can be increased.

The optical adjustment layer is preferably formed using a conductive material transmitting visible light among the conductive materials that can be used for the electrode of the light-emitting device.

### [Display Devices 100E and 100F]

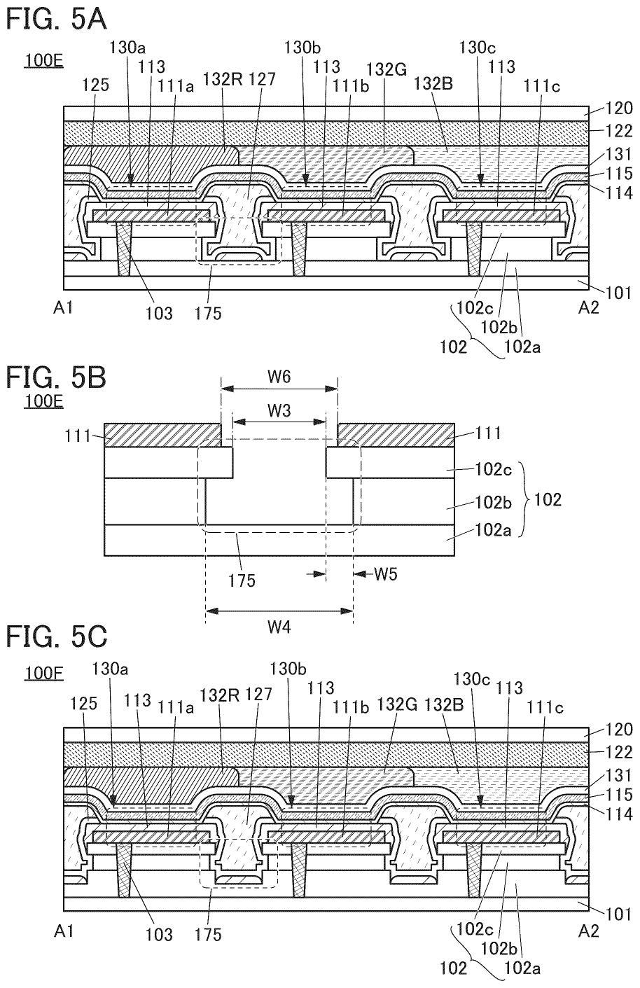

FIG. 5A illustrates a cross-sectional view of a display device 100E, and FIG. 5B illustrates a cross-sectional view of the groove 175 and the vicinity thereof in the display device 100E. Note that for simplification, some components are not illustrated in FIG. 5B. FIG. 5C illustrates a cross-sectional view of a display device 100F. The display device 100E and the display device 100F are different from the display device 100A in the shape of the groove 175.

As illustrated in FIG. 5A, the groove 175 included in the display device 100E has an inverted T shape in the cross-sectional view of the display device 100E.

In the cross-sectional view of the display device, the groove 175 illustrated in FIG. 5B includes a region having a first width W3 and a region having a second width W4 therebelow. As illustrated in FIG. 5B, the half of the difference between the first width W3 and the second width W4 is a width W5, and the shortest distance between the facing end portions of the pixel electrodes 111 is a distance W6.

It is preferable that the first width W3 be smaller than the distance W6 and that the second width W4 be larger than the first width W3. This structure easily causes disconnection of the first layer 113.

As illustrated in FIG. 5C, the groove 175 included in the display device 100F has a cross shape in the cross-sectional view of the display device 100F.

Note that in the case where the groove 175 has the inverted T shape illustrated in FIG. 5A and FIG. 5B or the cross shape illustrated in FIG. 5C, there is no particular limitation on which is larger, the second width W4 or the distance W6. FIG. 5A and FIG. 5B illustrate an example in which the second width W4 is larger than the distance W6. FIG. 5C illustrates an example in which the second width W4 is substantially equal to the distance W6. The second width W4 may be smaller than the distance W6, equal to the distance W6, or larger than the distance W6. In the case where the second width W4 is smaller than the distance W6, the groove 175 is not positioned below the pixel electrode 111.

As illustrated in FIG. 5A to FIG. 5C, the insulating layer 102 preferably has a stacked-layer structure of the insulating layer 102a, the insulating layer 102b, and an insulating layer 102c. In addition, the etching rate of a material used for the insulating layer 102b is preferably different from that of a material used for the insulating layer 102a and the insulating layer 102c. With such a structure, the groove 175 with the shape illustrated in FIG. 5A to FIG. 5C can be formed.

With the groove 175 having the above shape, the first layer 113 can be divided between adjacent light-emitting devices. Accordingly, leakage current between the adjacent light-emitting devices can be prevented. Thus, display with a high contrast can be performed as described above. Furthermore, an improvement in efficiency, a reduction in power consumption, and an improvement in reliability are facilitated.

The width W5 corresponds to the width W2 illustrated in FIG. 1C. Thus, the description of the width W2 illustrated in FIG. 1C can be referred to for the preferable range of the width W5.

In the display device 100E, the thickness of the insulating layer 102b is preferably larger than the thickness of the first layer 113. In the display device 100F, the sum of the thickness of the insulating layer 102b and the depth of the groove provided in the insulating layer 102a is preferably larger than the thickness of the first layer 113. This structure easily causes disconnection of the first layer 113.

Although FIG. 5A illustrates the structure in which the thickness of the insulating layer 102b is larger than the thickness of the insulating layer 102c, there is no particular limitation on which is larger, the thickness of the insulating layer 102b or the thickness of the insulating layer 102c, as long as the first layer 113 is disconnected. The thickness of the insulating layer 102b may be equal to the thickness of the insulating layer 102c, or the thickness of the insulating layer 102b may be smaller than the thickness of the insulating layer 102c. Similarly, there is no particular limitation on which is larger, the thickness of the insulating layer 102a or the thickness of the insulating layer 102c. Similarly, there is no particular limitation on which is larger, the thickness of the insulating layer 102a or the thickness of the insulating layer 102b.

Although FIG. 5A to FIG. 5C illustrate the examples in which the insulating layer 102 has the three-layer structure, the structure of the insulating layer 102 is not limited thereto. For example, the insulating layer 102 may have a stacked-layer structure of two layers or four or more layers, or any one or more of the insulating layer 102a, the insulating layer 102b, and the insulating layer 102c may have a stacked-layer structure.

Here, a method for forming the groove 175 included in the display device 100E illustrated in FIG. 5A and the groove 175 included in the display device 100F illustrated in FIG. 5C will be described.

First, a groove having the first width W3 is formed in the insulating layer 102c and the insulating layer 102b to expose the top surface of the insulating layer 102a. The groove is preferably formed by an etching method. Note that at the time of forming the groove, part of the top surface of the insulating layer 102a in a region overlapping with the groove is removed in some cases.

Next, the side surface of the insulating layer 102b exposed in the groove is etched by an isotropic etching method to make the end surface recede (such etching is also referred to as side etching). Thus, the groove in the insulating layer 102b extends in the horizontal direction with respect to the substrate surface, so that a region having the second width W4 is generated in the groove 175.

In the above manner, the groove 175 included in the display device 100E illustrated in FIG. 5A and the groove 175 included in the display device 100F illustrated in FIG. 5C can be formed.

### [Display Device 200A]

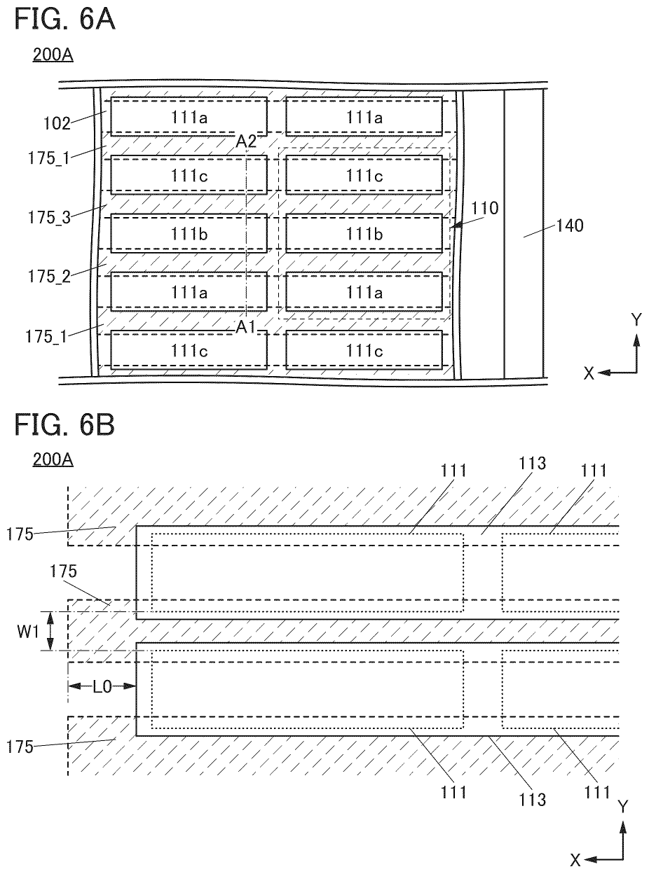

FIG. 6A illustrates a top view of a display device 200A. FIG. 1B can be referred to for a cross-sectional view along the dashed-dotted line A1-A2 in FIG. 6A; thus, the detailed description thereof is omitted.

FIG. 6A illustrates the pixel electrode 111a included in the light-emitting device 130a, the pixel electrode 111b included in the light-emitting device 130b, and the pixel electrode 111c included in the light-emitting device 130c.

FIG. 6A illustrates a groove 175_1, a groove 175_2, and a groove 175_3 included in the insulating layer 102. The groove 175_1 is provided to reach dashed lines inside the pixel electrodes 111a and 111c. The groove 175_2 is provided to reach dashed lines inside the pixel electrodes 111a and 111b. The groove 175_3 is provided to reach dashed lines inside the pixel electrodes 111b and 111c. That is, parts of the grooves 175_1, 175_2, and 175_3 can be regarded as being positioned under the pixel electrodes.

In the insulating layer 102 in FIG. 6A, the groove is provided between two pixel electrodes 111 adjacent to each other in the Y direction. In that case, the first layers 113 are formed in the state where a large step is provided between the pixel electrodes adjacent to each other in the Y direction, so that the first layers 113 can be easily formed separately for the subpixels exhibiting different colors. This can inhibit leakage current from flowing between two light-emitting devices. Thus, light emission caused by the leakage current can be inhibited, so that display with high contrast can be obtained. Furthermore, even in the case where the resolution is increased, the range of choices for materials can be widened since the first layer 113 can be formed using a material with high conductivity, which facilitates an improvement in emission efficiency, a reduction in power consumption, and an improvement in reliability.

Meanwhile, a groove is not provided between two pixel electrodes 111 adjacent to each other in the X direction. Thus, the first layer 113 is not divided between the subpixels exhibiting the same color, and is formed as a continuous film.

In the description common to the groove 175_1, the groove 175_2, and the groove 175_3, the term “groove 175” is used in some cases. In the description common to the pixel electrode 111a, the pixel electrode 111b, and the pixel electrode 111c, the term “pixel electrode 111” is used in some cases.

FIG. 6B illustrates a top view of an end portion of the groove 175 and the vicinity thereof.

The groove 175 preferably extends beyond an end portion of the first layer 113 in the X direction. In FIG. 6B, the distance between the end portion of the groove 175 and the end portion of the first layer 113 is denoted by a distance L0. With this structure, the first layer 113 can be easily divided between the light-emitting devices adjacent to each other in the Y direction.

Although not illustrated in FIG. 6A and FIG. 6B, the common electrode 115 preferably extends beyond the end portion of the groove 175 in the X direction.

Here, a method for forming the groove 175 included in the display device 200A illustrated in FIG. 6A and FIG. 6B is described.

First, a belt-like pixel electrode in which the X direction is the long side direction is formed. Then, the insulating layer 102 is etched using the pixel electrode (and a resist mask for forming the belt-like pixel electrode) as a mask, so that the grooves 175_1, 175_2, and 175_3 in each of which the X direction is the long side direction are formed. After that, the belt-like pixel electrode is divided in the Y direction, so that the island-shaped pixel electrodes illustrated in FIG. 6A and FIG. 6B are formed.

In the above manner, the groove 175 included in the display device 200A illustrated in FIG. 6A and FIG. 6B can be formed.

### [Display Device 200B]

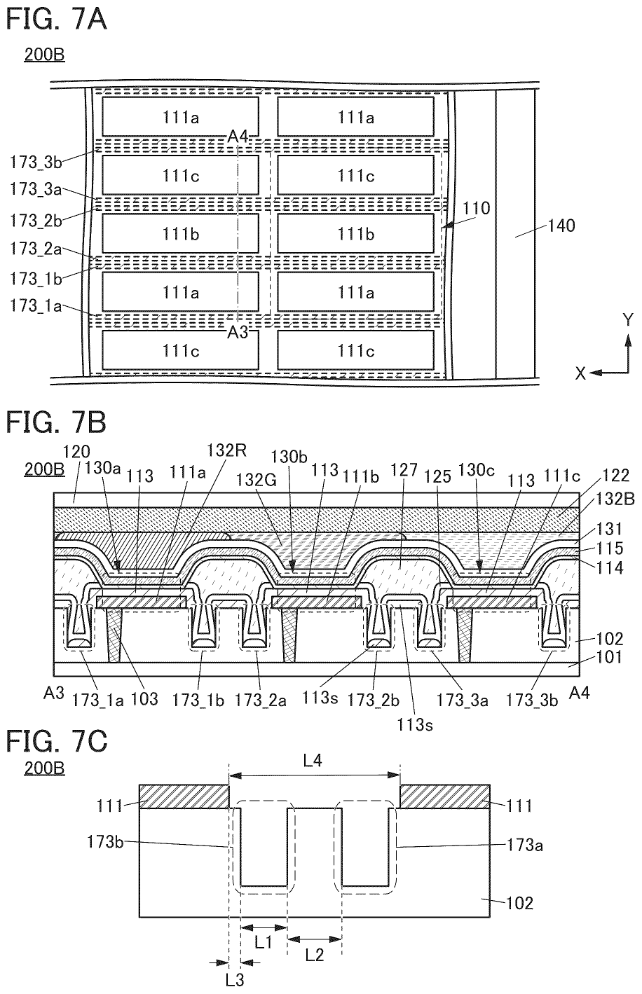

FIG. 7A illustrates a top view of a display device 200B, and FIG. 7B illustrates a cross-sectional view taken along the dashed-dotted line A3-A4 in FIG. 7A.

In the display device 200B, two grooves are provided between two light-emitting devices adjacent to each other in the Y direction.

In FIG. 7A, the insulating layer 102 includes two grooves between two pixel electrodes adjacent to each other in the Y direction. As illustrated in FIG. 7A and FIG. 7B, between the light-emitting device 130a (the pixel electrode 111a) and the light-emitting device 130b (the pixel electrode 111b), a groove 173_1b on the light-emitting device 130a side and a groove 173_2a on the light-emitting device 130b side are provided. Similarly, between the light-emitting device 130b (the pixel electrode 111b) and the light-emitting device 130c (the pixel electrode 111c), a groove 173_2b on the light-emitting device 130b side and a groove 173_3a on the light-emitting device 130c side are provided. Between the light-emitting device 130a (the pixel electrode 111a) and the light-emitting device 130c (the pixel electrode 111c), a groove 173_1a on the light-emitting device 130a side and a groove 173_3b on the light-emitting device 130c side are provided. In the description common to the grooves 173_1a, 173_2a, and 173_3a, the term “groove 173a” is used in some cases. In the description common to the grooves 173_1b, 173_2b, and 173_3b, the term “groove 173b” is used in some cases.

In the display device 200B, the first layer 113 is divided between two light-emitting devices adjacent to each other in the Y direction with use of the grooves 173a and 173b. This can inhibit leakage current from flowing between the two light-emitting devices. Thus, light emission caused by the leakage current can be inhibited, so that display with high contrast can be obtained. Furthermore, even in the case where the resolution is increased, the range of choices for materials can be widened since the first layer 113 can be formed using a material with high conductivity, which facilitates an improvement in emission efficiency, a reduction in power consumption, and an improvement in reliability.

Although the sidewalls of the grooves 173a and 173b illustrated in FIG. 7B each have a shape perpendicular to a surface of the layer 101 including transistors (the substrate), the shapes of the sidewalls of the grooves 173a and 173b are not limited thereto as long as the first layer 113 is disconnected. The sidewalls of the grooves 173a and 173b may each have a tapered shape or an inverse tapered shape. The sidewalls of the grooves 173a and 173b may each have a curve or a step.

Note that the number of grooves provided in the insulating layer 102 in a region positioned between two pixel electrodes 111 adjacent to each other in the Y direction is preferably one or two but may be three or more.

It is preferable that the insulating layer 125 be provided in contact with the side surface of the first layer 113 and be in contact with part of the top surface of the first layer 113, as illustrated in FIG. 7B.

In FIG. 7B, the insulating layer 125 is provided to overlap with the grooves 173_1a, 173_1b, 173_2a, 173_2b, 173_3a, and 173_3b. The insulating layer 125 preferably includes a portion in contact with the insulating layer 102. Specifically, the insulating layer 125 is preferably in contact with a sidewall of the groove. Thus, the pixel electrode 111 and the first layer 113 are sealed with the insulating layer 102 and the insulating layer 125. The insulating layer 125 functions as a protective layer that prevents diffusion of impurities such as water into the pixel electrode 111 and the first layer 113.

The material layer 113s that is formed in the same step as the first layer 113 and has the same structure as the first layer 113 is positioned over the insulating layer 102. The material layer 113s is a layer that is separated from the first layer 113 in formation of a layer forming the first layer 113 to be independently provided over the insulating layer 102. FIG. 7B illustrates the material layer 113s remaining in the groove 173a, in the groove 173b, and over a region between the two grooves 173a and 173b. The material layer 113s is positioned between the insulating layer 125 and the insulating layer 102.

Between the light-emitting devices adjacent to each other in the Y direction, the first layers 113 are provided such that their side surfaces face each other with the insulating layer 127 therebetween. The insulating layer 127 is positioned between the light-emitting devices adjacent to each other in the Y direction, and is provided to fill a region between two first layers 113. The insulating layer 127 is provided to fill the grooves 173a and 173b.

FIG. 7C illustrates a cross-sectional view of the grooves included in the display device 200B and the vicinity thereof. Note that for simplification, some components are not illustrated in FIG. 7C.

A width L1 illustrated in FIG. 7C is a width of the groove 173b in the Y direction. The width L1 is preferably greater than or equal to 2 times and less than or equal to 5 times, further preferably greater than or equal to 2 times and less than or equal to 4 times, still further preferably greater than or equal to 2 times and less than or equal to 3 times the thickness of the first layer 113.

This enables the groove 173b to cause disconnection of the first layer 113 so that the first layer 113 can be formed over each pixel electrode 111. In that case, the first layer 113 is placed to cover the side surface and the top surface of the pixel electrode 111 as illustrated in FIG. 7B. In other words, in the cross-sectional view of the display device 200B, the end portion of the first layer 113 is positioned outward from the end portion of the pixel electrode 111. In other words, the end portion of the first layer 113 covers the end portion of the pixel electrode 111. The first layer 113 includes a region in contact with the insulating layer 102. Note that the favorable range of the value of the width of the groove 173a in the Y direction is similar to that of the width L1.

A distance L2 illustrated in FIG. 7C is a distance between the groove 173a and the groove 173b adjacent to each other. In other words, the distance L2 is the shortest distance between the end portions of adjacent grooves. A distance L3 illustrated in FIG. 7C is a distance between the pixel electrode 111 and the groove 173b adjacent to the pixel electrode 111. In other words, the distance L3 is the shortest distance between the end portion of the pixel electrode 111 and the end portion of the groove 173b adjacent to the pixel electrode 111.

The distance L2 and the distance L3 are preferably adjusted as appropriate in accordance with the processing accuracy in the case of using a photolithography method, the thickness of the first layer 113, the thickness of the insulating layer 125, or the like. For example, the distance L2 is greater than or equal to 200 nm and less than or equal to 800 nm, preferably greater than or equal to 250 nm and less than or equal to 700 nm, further preferably greater than or equal to 350 nm and less than or equal to 600 nm. For example, the distance L3 is greater than or equal to 50 nm and less than or equal to 400 nm, preferably greater than or equal to 50 nm and less than or equal to 200 nm, further preferably greater than or equal to 50 nm and less than or equal to 150 nm. The favorable range of the value of the distance between the pixel electrode 111 and the groove 173a adjacent to the pixel electrode 111 is similar to that of the distance L3.

A distance L4 illustrated in FIG. 7C is the shortest distance between the pixel electrodes 111 included in two adjacent light-emitting devices. The distance L4 depends on the width L1, the distance L2, and the distance L3. With the above structure, the distance L4 is greater than or equal to 700 nm and less than or equal to 2000 nm, preferably greater than or equal to 900 nm and less than or equal to 1600 nm, further preferably greater than or equal to 1000 nm and less than or equal to 1400 nm.

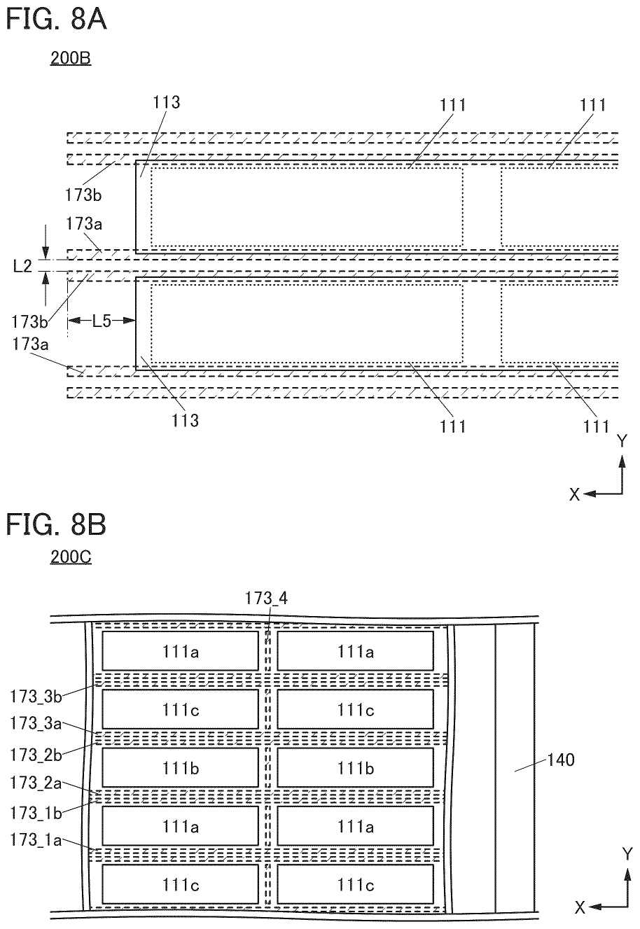

FIG. 8A illustrates a top view of an end portion of the groove 173a, an end portion of the groove 173b, and the vicinity thereof.

The grooves 173a and 173b preferably extend beyond the end portion of the first layer 113 in the X direction. In FIG. 8A, the distance between the end portions of the grooves 173a and 173b and the end portion of the first layer 113 is denoted by a distance L5. With this structure, the first layer 113 can be easily divided between the light-emitting devices adjacent to each other in the Y direction.

Although not illustrated in FIG. 8A, the common electrode 115 preferably extends beyond the end portion of the groove 173 in the X direction. [Display device 200C]

FIG. 8B illustrates a top view of a display device 200C. The display device 200C is an example in which a groove 173_4 is provided between two light-emitting devices that emit light of the same color. In FIG. 8B, the groove 173_4 is provided between two pixel electrodes 111a (two light-emitting devices 130a) adjacent in the X direction, between two pixel electrodes 111b (two light-emitting devices 130b) adjacent in the X direction, and between two pixel electrodes 111c (two light-emitting devices 130c) adjacent in the X direction.

FIG. 8B illustrates an example in which the groove 173_4 does not intersect with (is not connected to) another groove. Note that a structure may also be employed in which the groove 173_4 intersects with (is connected to) one or more of the groove 173_1a, the groove 173_1b, the groove 173_2a, the groove 173_2b, the groove 173_3a, and the groove 173_3b.

It is preferable that the first layer 113 be disconnected not only between subpixels exhibiting different colors but also between subpixels exhibiting the same color so that the island-shaped first layer 113 is provided for each light-emitting device. This enables the display device to have high color reproducibility and high contrast, so that the display device can have both high resolution and high display quality.

### [Display Device 200D]

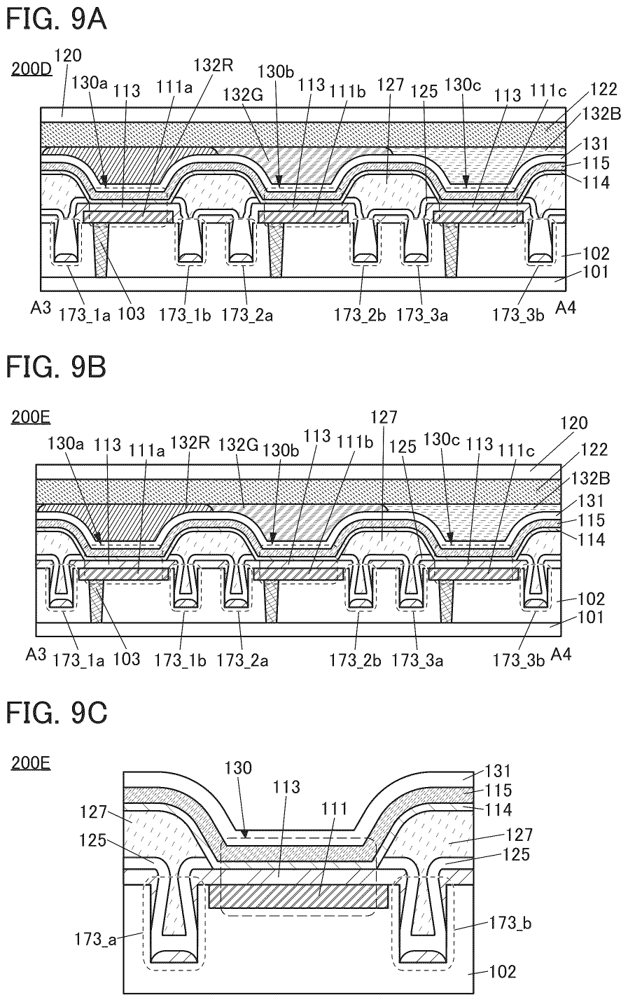

FIG. 9A illustrates a cross-sectional view of a display device 200D. The display device 200D is different from the display device 200B illustrated in FIG. 7B in that the insulating layer 125 is provided to fill the groove.

The insulating layer 125 is provided to fill the groove as illustrated in FIG. 9A depending on the thickness of the insulating layer 125, the size of the width L1, the size of the distance L3, or the like. For example, the insulating layer 125 is provided to fill the grooves 173_1a, 173_1b, 173_2a, 173_2b, 173_3a, and 173_3b. In that case, the insulating layer 127 is provided over the insulating layer 125 and the insulating layer 102.

### [Display Device 200E]

FIG. 9B illustrates a cross-sectional view of a display device 200E. The display device 200E is different from the display device 200B illustrated in FIG. 7B in the placement of the pixel electrode. FIG. 9C illustrates an enlarged view of the pixel electrode and the vicinity thereof. Note that for simplification, some components are not illustrated in FIG. 9C.

In the display device 200E, the pixel electrode 111 is formed to be embedded in the insulating layer 102. That is, the top surface of the pixel electrode 111 is level or substantially level with the top surface of the insulating layer 102. With such a structure, the first layer 113 can be formed on a flat surface.

The display device 200E has a structure in which the first layer 113 is provided on a flat surface and the first layer 113 does not cover the end portion of the pixel electrode 111. Thus, a reduction in the thickness of the first layer 113 can be prevented, which can prevent the occurrence of a short circuit between the upper electrode (the common electrode 115) and the lower electrode (the pixel electrode 111) of the light-emitting device 130.

### [Display Device 200F]

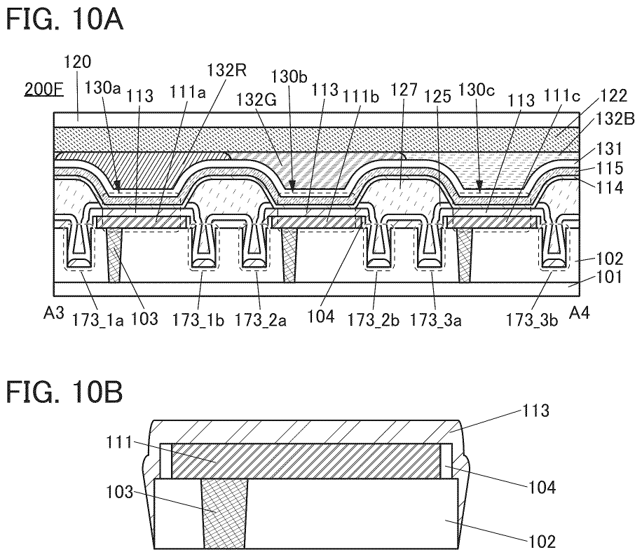

FIG. 10A illustrates a cross-sectional view of a display device 200F. The display device 200F is different from the display device 200B illustrated in FIG. 7B in including a sidewall insulating layer 104 (also referred to as a sidewall, a sidewall protective layer, an insulating layer, or the like) in contact with the side surface of the pixel electrode. FIG. 10B illustrates an enlarged view of the pixel electrode and the vicinity thereof.

In the first layer 113, a portion covering the end portion of the pixel electrode has a small thickness, and an electric field is easily concentrated thereon. The sidewall insulating layer 104 is preferably provided, in which case current flowing from the side surface of the pixel electrode to the first layer 113 can be inhibited.

In the case where a light-emitting device having a tandem structure is used, contact between a charge-generation layer included in the first layer 113 and the side surface of the pixel electrode might cause a short circuit of the light-emitting device. Providing the sidewall insulating layer 104 can inhibit a short circuit of the light-emitting device and achieve a highly reliable display device.

The sidewall insulating layer 104 may have either a single-layer structure or a stacked-layer structure of two or more layers. The sidewall insulating layer 104 preferably includes an inorganic insulating film. Examples of an inorganic insulating film that can be used for the sidewall insulating layer 104 include an oxide insulating film, a nitride insulating film, an oxynitride insulating film, and a nitride oxide insulating film. Specific examples of these inorganic insulating films are as listed in the description of the insulating layer 102.

There is no particular limitation on the method for forming the sidewall insulating layer 104. The sidewall insulating layer 104 can be formed, for example, by a sputtering method, a CVD method, a PECVD method, or an ALD method. A sputtering method, a CVD method, or a PECVD method, which has a higher film formation speed than an ALD method, is particularly preferably employed, in which case the sidewall insulating layer 104 that is thick enough to ensure the insulating property can be formed with high productivity.

As the sidewall insulating layer 104, a silicon oxide film, a silicon nitride film, a silicon oxynitride film, or a silicon nitride oxide film is preferably used, for example. In that case, a highly reliable display device can be manufactured with high productivity.

As the sidewall insulating layer 104, an aluminum oxide film may be formed by an ALD method. An ALD method enables the sidewall insulating layer 104 with high coverage to be formed.

The cross-sectional views of the display devices illustrated in FIG. 1B, FIG. 2A, FIG. 3A, FIG. 4, FIG. 5A, FIG. 5C, FIG. 7B, FIG. 9A, FIG. 9B, and FIG. 10A each illustrate an example in which the coloring layers 132R, 132G, and 132B are provided over the light-emitting devices with the protective layer 131 therebetween. With such a structure, the alignment accuracy of the light-emitting devices and the coloring layers can be improved. The distance between the light-emitting devices and the coloring layers is preferably reduced, in which case color mixing can be inhibited and the viewing angle characteristics can be improved.

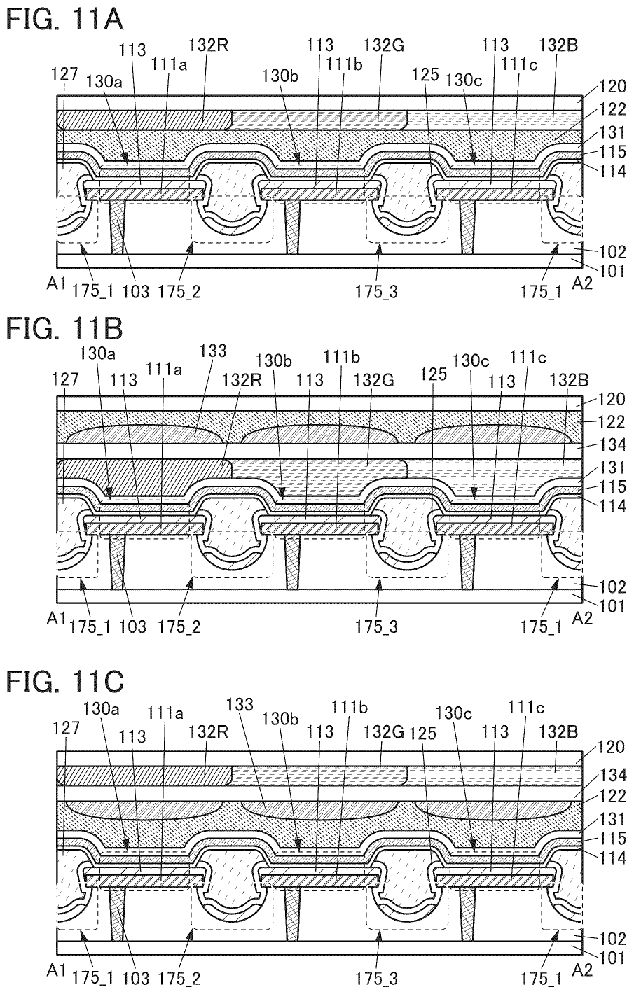

FIG. 11 to FIG. 15 each illustrate a cross-sectional view taken along the dashed-dotted line A1-A2 in FIG. 1A.

As illustrated in FIG. 11A, the substrate 120 provided with the coloring layers 132R, 132G, and 132B may be attached to the protective layer 131 with the resin layer 122. The coloring layers 132R, 132G, and 132B are provided on the substrate 120, whereby the temperature of heat treatment in the formation process of the coloring layers 132R, 132G, and 132B can be increased.

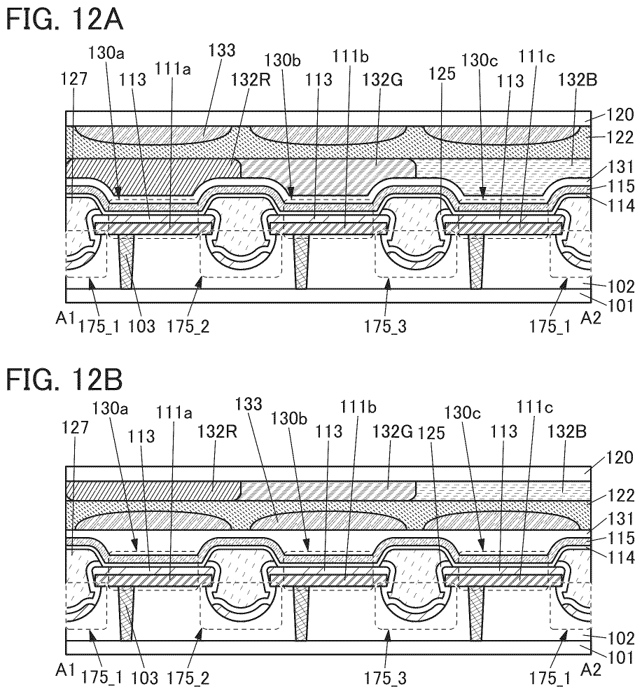

As illustrated in FIG. 11B, FIG. 11C, FIG. 12A, and FIG. 12B, a lens array 133 may be provided in the display device. The lens array 133 can be provided to overlap with the light-emitting device.

FIG. 11B illustrates an example in which the coloring layers 132R, 132G, and 132B are provided over the light-emitting devices with the protective layer 131 therebetween, an insulating layer 134 is provided over the coloring layers 132R, 132G, and 132B, and the lens array 133 is provided over the insulating layer 134. The coloring layers 132R, 132G, and 132B and the lens array 133 are directly formed over the substrate provided with the light-emitting devices, whereby the alignment accuracy of the light-emitting devices and the coloring layers or the lens array can be improved.

For the insulating layer 134, one or both of an inorganic insulating film and an organic insulating film can be used. The insulating layer 134 may have either a single-layer structure or a stacked-layer structure. For the insulating layer 134, a material that can be used for the insulating layer 102 can be used, for example. The insulating layer 134 preferably has a planarization function. Light emitted from the light-emitting device is extracted through the insulating layer 134, so that the insulating layer 134 preferably has a high visible-light-transmitting property.

In FIG. 11B, light emitted from the light-emitting device passes through the coloring layer and then passes through the lens array 133, resulting in being extracted to the outside of the display device. The distance between the light-emitting devices and the coloring layers are preferably reduced, in which case color mixing can be inhibited and the viewing angle characteristics can be improved. Note that the lens array 133 may be provided over the light-emitting device and the coloring layer may be provided over the lens array 133.

FIG. 11C illustrates an example in which the substrate 120 provided with the coloring layers 132R, 132G, and 132B and the lens array 133 is attached onto the protective layer 131 with the resin layer 122. The substrate 120 is provided with the coloring layers 132R, 132G, and 132B and the lens array 133, whereby the temperature of heat treatment in the formation process of these coloring layers can be increased.

FIG. 11C illustrates an example in which the coloring layers 132R, 132G, and 132B are provided in contact with the substrate 120, the insulating layer 134 is provided in contact with the coloring layers 132R, 132G, and 132B, and the lens array 133 is provided in contact with the insulating layer 134.

In FIG. 11C, light emitted from the light-emitting device passes through the lens array 133 and then passes through the coloring layer, resulting in being extracted to the outside of the display device. Note that the lens array 133 may be provided in contact with the substrate 120, the insulating layer 134 may be provided in contact with the lens array 133, and the coloring layer may be provided in contact with the insulating layer 134. In that case, light emitted from the light-emitting device passes through the coloring layer and then passes through the lens array 133, resulting in being extracted to the outside of the display device.

As illustrated in FIG. 12A and FIG. 12B, either the lens array or the coloring layer may be provided over the protective layer 131 and the other may be provided on the substrate 120.

FIG. 12A illustrates an example in which the coloring layers 132R, 132G, and 132B are provided over the light-emitting devices with the protective layer 131 therebetween and the substrate 120 provided with the lens array 133 is attached onto the coloring layers 132R, 132G, and 132B with the resin layer 122.

FIG. 12B illustrates an example in which the lens array 133 is provided over the light-emitting devices with the protective layer 131 therebetween and the substrate 120 provided with the coloring layers 132R, 132G, and 132B is attached onto the lens array 133 and the protective layer 131 with the resin layer 122.

The lens array 133 may include a convex surface facing the substrate 120 side or a convex surface facing the light-emitting device side.

The lens array 133 can be formed using one or both of an inorganic material and an organic material. For example, a material containing a resin can be used for the lens. Moreover, a material containing one or both of an oxide and a sulfide can be used for the lens. As the lens array 133, a microlens array can be used, for example. The lens array 133 may be directly formed over the substrate or the light-emitting device. Alternatively, a lens separately formed may be attached thereto.

Coloring layers of different colors preferably include a region where they overlap with each other. The region where the coloring layers of different colors overlap with each other can function as a light-blocking layer. This can further reduce reflection of external light.

Next, a display device having a structure in which a light-emitting device and a color conversion layer are combined will be described. Hereinafter, a structure in which the light-emitting devices 130a, 130b, and 130c emit white or blue light is mainly described as an example.

A display device illustrated in FIG. 13A is different from the display device 100A illustrated in FIG. 1B in that a color conversion layer 135R is provided between the protective layer 131 and the coloring layer 132R and a color conversion layer 135G is provided between the protective layer 131 and the coloring layer 132G.

The subpixel emitting red light includes the light-emitting device 130a and the color conversion layer 135R that converts at least blue light into red light. Thus, light emitted from the light-emitting device 130a is extracted as red light to the outside of the display device through the color conversion layer 135R.

The subpixel emitting red light preferably further includes the coloring layer 132R that transmits red light. In some cases, part of blue light (and green light) emitted from the light-emitting device 130a is transmitted through the color conversion layer 135R without being converted. When light transmitted through the color conversion layer 135R is extracted through the coloring layer 132R, the coloring layer 132R absorbs light other than red light, and the color purity of light emitted from the subpixel can be improved.

The subpixel emitting green light includes the light-emitting device 130b and the color conversion layer 135G that converts at least blue light into green light. Thus, light emitted from the light-emitting device 130b is extracted as green light to the outside of the display device through the color conversion layer 135G.

The subpixel emitting green light preferably further includes the coloring layer 132G that transmits green light. Accordingly, the color purity of light emitted from the subpixel can be increased.

The subpixel emitting blue light includes the light-emitting device 130c that emits at least blue light. Light emitted from the light-emitting device 130c is extracted as blue light to the outside of the display device.

The subpixel emitting blue light preferably further includes the coloring layer 132B that transmits blue light. Accordingly, the color purity of light emitted from the subpixel can be increased.

Note that the subpixels emitting light of different colors can each independently have a structure including or not including a coloring layer.

In the case where the light-emitting device 130a emits white light, the color conversion layer 135R preferably converts blue light and green light into red light and transmits red light. When such a color conversion layer 135R is provided to overlap with the light-emitting device 130a, a blue light component and a green light component in white light can be converted into a red light component to be extracted to the outside of the display device. Thus, the structure with the color conversion layer 135R can increase efficiency of extracting red light compared with a structure without the color conversion layer 135R.

As described above, it is preferable that light transmitted through the color conversion layer 135R be extracted to the outside of the display device through the coloring layer 132R that transmits red light. It is particularly preferable that the coloring layer 132R be provided to cover an end portion of the color conversion layer 135R as illustrated in FIG. 13A. Thus, for example, blue light and green light transmitted through the color conversion layer 135R without being converted by the color conversion layer 135R can be absorbed by the coloring layer 132R. Accordingly, the color purity of light emitted from the subpixel can be increased.

Similarly, in the case where the light-emitting device 130b emits white light, the color conversion layer 135G preferably converts blue light into green light and transmits green light. When such a color conversion layer 135G is provided to overlap with the light-emitting device 130b, a blue light component in white light can be converted into a green light component to be extracted to the outside of the display device. Thus, the structure with the color conversion layer 135G can increase efficiency of extracting green light compared with a structure without the color conversion layer 135G.

In addition, it is preferable that light transmitted through the color conversion layer 135G be extracted to the outside of the display device through the coloring layer 132G that transmits green light. Thus, the color purity of light emitted from the subpixel can be increased.

In the case where the light-emitting device 130c emits white light, the coloring layer 132B that transmits blue light is preferably provided to overlap with the light-emitting device 130c. Thus, a blue light component in white light can be extracted to the outside of the display device.

Note that in the case where the light-emitting device including the EL layer emitting white light has a microcavity structure, light of a specific wavelength such as red, green, or blue is sometimes intensified and emitted.

For example, the first layer 113 is configured to emit white light and has a microcavity structure, whereby red light emission can be obtained from the light-emitting device 130a, green light emission can be obtained from the light-emitting device 130b, and blue light emission can be obtained from the light-emitting device 130c.

Here, with the microcavity structure, light with a desired wavelength can be intensified and extracted in the front direction; however, light extracted in the oblique direction includes a white light component.

Thus, providing the color conversion layer 135R and the color conversion layer 135G in the display device with a microcavity structure is preferable because light extraction efficiency can be increased. In addition, providing the coloring layers 132R, 132G, and 132B is preferable because the color purity of light emitted from the subpixels can be increased.

For example, the first layer 113 can be configured to emit blue light. For example, the first layer 113 contains a light-emitting material that emits blue light.

In the case where the light-emitting device 130a emits blue light, the color conversion layer 135R preferably converts blue light into red light and transmits red light. When such a color conversion layer 135R is provided to overlap with the light-emitting device 130a, blue light emitted from the first layer 113 can be converted into red light to be extracted to the outside of the display device.

Similarly, in the case where the light-emitting device 130b emits blue light, the color conversion layer 135G preferably converts blue light into green light and transmits green light. When such a color conversion layer 135G is provided to overlap with the light-emitting device 130b, blue light emitted from the first layer 113 can be converted into green light to be extracted to the outside of the display device.

That is, a full-color display device can be achieved even with a structure in which the first layer 113 emits blue light.

Note that also in the case where the first layer 113 emits blue light, the coloring layers 132R, 132G, and 132B are preferably used because the color purity of light emitted from the subpixels can be increased.

Also in the case where the first layer 113 emits blue light, a microcavity structure may be employed so that blue light emitted from the light-emitting device is intensified. Alternatively, a microcavity structure is not necessarily employed.

The first layer 113 may emit light with a shorter wavelength than blue light; for example, the first layer 113 may emit violet light or ultraviolet light. The first layer 113 contains a light-emitting material that emits violet light or ultraviolet light, for example.

Here, an example of light with a shorter wavelength than blue light is light having a peak wavelength of the emission spectrum of greater than or equal to 100 nm and less than 400 nm.

In the case where the light-emitting device 130c emits light with a shorter wavelength than blue light, it is preferable that a color conversion layer that converts light emitted from the light-emitting device 130c into blue light and transmits blue light be provided to overlap with the light-emitting device 130c. The coloring layer 132B is preferably provided in a position overlapping with the light-emitting device 130c with the color conversion layer therebetween.

As described above, also the subpixel emitting blue light can employ a structure with a color conversion layer or a structure with a combination of a color conversion layer and a coloring layer.

Note that in the case where the light-emitting devices 130a and 130b emit light with a shorter wavelength than blue light, the color conversion layers 135R and 135G are preferably capable of converting light with a shorter wavelength than blue light into red or green light.

For the color conversion layer, one or both of a phosphor and a quantum dot (QD) are preferably used. In particular, a quantum dot has an emission spectrum with a narrow peak width, so that light emission with high color purity can be obtained. Thus, the display quality of the display device can be improved.

The color conversion layer can be formed by a droplet discharge method (e.g., an inkjet method), a coating method, an imprinting method, or a variety of printing methods (screen printing or offset printing), for example. Alternatively, a color conversion film such as a quantum dot film may be used.

When a film to be the color conversion layer is processed, a photolithography method is preferably employed. For example, a thin film is formed using a material in which a quantum dot is mixed with a photoresist, and the thin film is processed by a photolithography method, whereby an island-shaped color conversion layer can be formed.

There is no particular limitation on a material of a quantum dot, and examples include a Group 14 element, a Group 15 element, a Group 16 element, a compound of a plurality of Group 14 elements, a compound of an element belonging to any of Group 4 to Group 14 and a Group 16 element, a compound of a Group 2 element and a Group 16 element, a compound of a Group 13 element and a Group 15 element, a compound of a Group 13 element and a Group 17 element, a compound of a Group 14 element and a Group 15 element, a compound of a Group 11 element and a Group 17 element, iron oxides, titanium oxides, spinel chalcogenides, and a variety of semiconductor clusters.

Specific examples include cadmium selenide; cadmium sulfide; cadmium telluride; zinc selenide; zinc oxide; zinc sulfide; zinc telluride; mercury sulfide; mercury selenide; mercury telluride; indium arsenide; indium phosphide; gallium arsenide; gallium phosphide; indium nitride; gallium nitride; indium antimonide; gallium antimonide; aluminum phosphide; aluminum arsenide; aluminum antimonide; lead selenide; lead telluride; lead sulfide; indium selenide; indium telluride; indium sulfide; gallium selenide; arsenic sulfide; arsenic selenide; arsenic telluride; antimony sulfide; antimony selenide; antimony telluride; bismuth sulfide; bismuth selenide; bismuth telluride; silicon; silicon carbide; germanium; tin; selenium; tellurium; boron; carbon; phosphorus; boron nitride; boron phosphide; boron arsenide; aluminum nitride; aluminum sulfide; barium sulfide; barium selenide; barium telluride; calcium sulfide; calcium selenide; calcium telluride; beryllium sulfide; beryllium selenide; beryllium telluride; magnesium sulfide; magnesium selenide; germanium sulfide; germanium selenide; germanium telluride; tin sulfide; tin selenide; tin telluride; lead oxide; copper fluoride; copper chloride; copper bromide; copper iodide; copper oxide; copper selenide; nickel oxide; cobalt oxide; cobalt sulfide; iron oxide; iron sulfide; manganese oxide; molybdenum sulfide; vanadium oxide; tungsten oxide; tantalum oxide; titanium oxide; zirconium oxide; silicon nitride; germanium nitride; aluminum oxide; barium titanate; a compound of selenium, zinc, and cadmium; a compound of indium, arsenic, and phosphorus; a compound of cadmium, selenium, and sulfur; a compound of cadmium, selenium, and tellurium; a compound of indium, gallium, and arsenic; a compound of indium, gallium, and selenium; a compound of indium, selenium, and sulfur; a compound of copper, indium, and sulfur; and combinations thereof. What is called an alloyed quantum dot, whose composition is represented by a given ratio, may be used.

Examples of the quantum dot include a core-type quantum dot, a core-shell quantum dot, and a core-multishell quantum dot. Quantum dots have a high proportion of surface atoms and thus have high reactivity and easily aggregate together. To prevent aggregation of quantum dots and increase dispersiveness to a dispersion medium, it is preferable that a protective agent be attached to, or a protective group be provided at the surfaces of quantum dots. It can also reduce reactivity and improve electrical stability.

Since band gaps of quantum dots are increased as their size is decreased, the size is adjusted as appropriate so that light with a desired wavelength can be obtained. Light emission from the quantum dots is shifted to a blue color side, i.e., a high energy side, as the crystal size is decreased; thus, emission wavelengths of the quantum dots can be adjusted over a wavelength range in the spectrum of an ultraviolet region, a visible light region, and an infrared region by changing the size of quantum dots. The size (diameter) of quantum dots is, for example, greater than or equal to 0.5 nm and less than or equal to 20 nm, preferably greater than or equal to 1 nm and less than or equal to 10 nm. The emission spectra are narrowed as the size distribution of quantum dots gets smaller, and thus light emission with high color purity can be obtained. The shape of quantum dots is not particularly limited and may be a spherical shape, a rod shape, a circular shape, or other shapes. A quantum rod, which is a rod-shaped quantum dot, has a function of emitting directional light.

FIG. 13A illustrates an example in which the color conversion layers 135R and 135G and the coloring layers 132R, 132G, and 132B are provided over the light-emitting devices with the protective layer 131 therebetween. With such a structure, the alignment accuracy of the light-emitting devices and the color conversion layers or the coloring layers can be improved. In addition, reducing the distance between the light-emitting device and the color conversion layer is preferable because light leaking without being converted can be inhibited. The distance between the light-emitting devices and the coloring layers is preferably reduced, in which case color mixing can be inhibited and the viewing angle characteristics can be improved.

The structure illustrated in FIG. 13B is different from the structure illustrated in FIG. 13A in not including the coloring layer 132B. For example, in the case where the first layer 113 emits blue light, a structure without the coloring layer 132B may be employed as illustrated in FIG. 13B. Blue light emitted from the light-emitting device 130c is extracted to the outside of the display device through the protective layer 131, the resin layer 122, and the substrate 120.

As illustrated in FIG. 13C, the color conversion layers 135R and 135G may be provided over the light-emitting devices with the protective layer 131 therebetween, and the substrate 120 provided with the coloring layers 132R, 132G, and 132B may be attached to the protective layer 131 and the color conversion layers 135R and 135G with the resin layer 122.

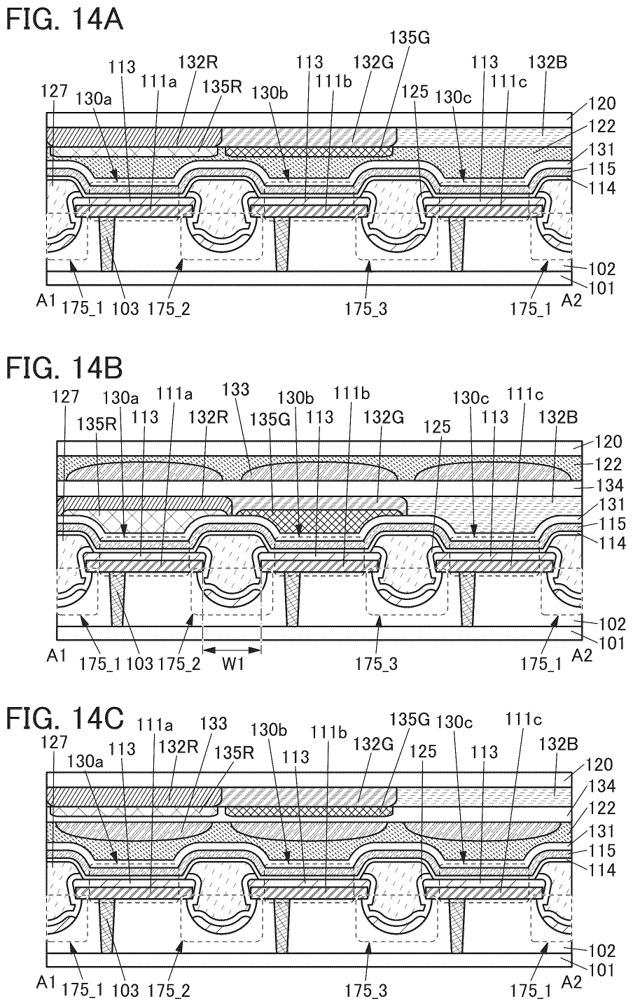

As illustrated in FIG. 14A, the substrate 120 provided with the color conversion layers 135R and 135G and the coloring layers 132R, 132G, and 132B may be attached to the protective layer 131 with the resin layer 122. The color conversion layers 135R and 135G and the coloring layers 132R, 132G, and 132B are provided on the substrate 120, whereby the temperature of heat treatment in the formation process of the color conversion layers 135R and 135G and the coloring layers 132R, 132G, and 132B can be increased. Specifically, one or both of the color conversion layer and the coloring layer can be formed at a temperature higher than the upper temperature limit of the light-emitting device.

The substrate 120 is provided with the coloring layers 132R, 132G, and 132B, the color conversion layer 135R is provided in a position overlapping with the coloring layer 132R, and the color conversion layer 135G is provided in a position overlapping with the coloring layer 132G.

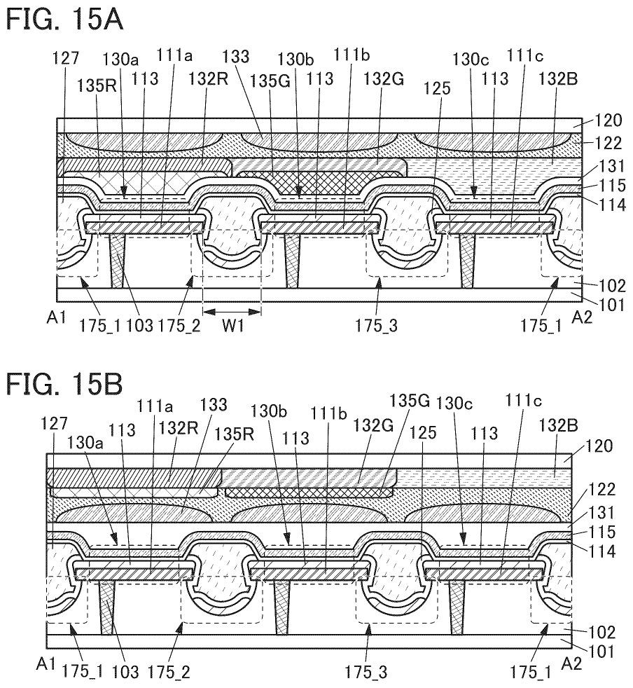

As described above, the arrangement of the light-emitting device, the color conversion layer, and the coloring layer can be appropriately selected from various structures in which the color conversion layer is positioned between the light-emitting device and the coloring layer. As illustrated in FIG. 14B, FIG. 14C, FIG. 15A, and FIG. 15B, the lens array 133 may be provided in the display device. The lens array 133 can be provided to overlap with the light-emitting device.

Like the structure illustrated in FIG. 13A, a structure illustrated in FIG. 14B is provided with, over the protective layer 131, the color conversion layer 135R overlapping with the light-emitting device 130a, the coloring layer 132R over the color conversion layer 135R, the color conversion layer 135G overlapping with the light-emitting device 130b, the coloring layer 132G over the color conversion layer 135G, and the coloring layer 132B overlapping with the light-emitting device 130c. FIG. 14B shows an example in which the insulating layer 134 covering the coloring layers 132R, 132G, and 132B is further provided and the lens array 133 is further provided over the insulating layer 134. The color conversion layers 135R and 135G, the coloring layers 132R, 132G, and 132B, and the lens array 133 are directly formed over the substrate provided with the light-emitting devices, whereby the alignment accuracy of the light-emitting devices and the color conversion layer, the coloring layer, or the lens array can be improved.

In FIG. 14B, light emitted from the light-emitting device passes through (the color conversion layer and) the coloring layer and then passes through the lens array 133, resulting in being extracted to the outside of the display device. The distance between the light-emitting devices and the coloring layers are preferably reduced, in which case color mixing can be inhibited and the viewing angle characteristics can be improved. Note that the lens array 133 may be provided over the light-emitting device and the coloring layer may be provided over the lens array 133.

FIG. 14C illustrates an example in which the substrate 120 provided with the coloring layers 132R, 132G, and 132B, the color conversion layers 135R and 135G, and the lens array 133 is attached onto the protective layer 131 with the resin layer 122. The substrate 120 is provided with the coloring layers 132R, 132G, and 132B, the color conversion layers 135R and 135G, and the lens array 133, whereby the temperature of heat treatment in the formation process of these coloring layers can be increased.

FIG. 14C illustrates an example in which the coloring layers 132R, 132G, and 132B are provided in contact with the substrate 120, the color conversion layer 135R is provided in contact with the coloring layer 132R, the color conversion layer 135G is provided in contact with the coloring layer 132G, the insulating layer 134 is provided in contact with the color conversion layers 135R and 135G and the coloring layer 132B, and the lens array 133 is provided in contact with the insulating layer 134.

In FIG. 14C, light emitted from the light-emitting device passes through the lens array 133 and then passes through (the color conversion layer and) the coloring layer, resulting in being extracted to the outside of the display device.

Note that the lens array 133 may be provided in contact with the substrate 120, the insulating layer 134 may be provided in contact with the lens array 133, and the coloring layer and the color conversion layer may be provided in contact with the insulating layer 134. In that case, light emitted from the light-emitting device passes through (the color conversion layer and) the coloring layer and then passes through the lens array 133, resulting in being extracted to the outside of the display device.

In FIG. 14C, the color conversion layers 135R and 135G are not necessarily formed on the substrate 120 and may be formed over and in contact with the protective layer 131.

As illustrated in FIG. 15A and FIG. 15B, either the lens array or the coloring layer may be provided over the protective layer 131 and the other may be provided on the substrate 120.

FIG. 15A illustrates an example in which the color conversion layers 135R and 135G and the coloring layers 132R, 132G, and 132B are provided over the light-emitting devices with the protective layer 131 therebetween and the substrate 120 provided with the lens array 133 is attached onto the coloring layers 132R, 132G, and 132B with the resin layer 122.

FIG. 15B illustrates an example in which the lens array 133 is provided over the light-emitting devices with the protective layer 131 therebetween and the substrate 120 provided with the coloring layers 132R, 132G, and 132B and the color conversion layers 135R and 135G is attached onto the lens array 133 and the protective layer 131 with the resin layer 122.

Note that in FIG. 15B, the color conversion layers 135R and 135G are not necessarily formed on the substrate 120 and may be formed over and in contact with the protective layer 131.

As described above, the lens array 133 can be arranged by a variety of arrangement methods in the structure in which the light-emitting device, the color conversion layer, and the coloring layer are arranged such that the color conversion layer is positioned between the light-emitting device and the coloring layer. The lens array 133 can be provided between the light-emitting device and the color conversion layer, between the color conversion layer and the coloring layer, or closer to the substrate 120 than the coloring layer is.

In the display device of one embodiment of the present invention, the island-shaped EL layer is provided for each light-emitting device, whereby generation of leakage current between subpixels can be inhibited. This can prevent crosstalk-induced unintended light emission, so that a display device with extremely high contrast can be obtained.

In the method for manufacturing the display device of one embodiment of the present invention, an EL layer can be formed into an island shape without using a metal mask. Thus, the display device can have both high resolution and high display quality.

This embodiment can be combined with any of the other embodiments as appropriate.

In this specification, in the case where a plurality of structure examples are described in one embodiment, the structure examples can be combined as appropriate.

### Embodiment 2

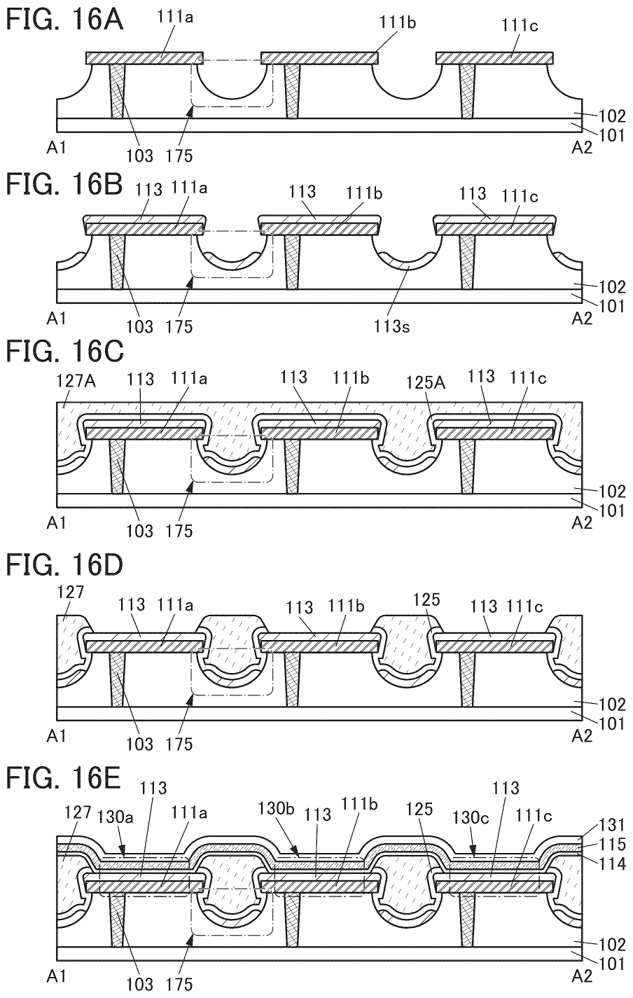

In this embodiment, a method for manufacturing a display device of one embodiment of the present invention will be described with reference to FIG. 16. Note that as for a material and a formation method of each component, portions similar to the portions described in Embodiment 1 are not described in some cases. The structure of the light-emitting device will be described in detail in Embodiment 5.

FIG. 16 illustrates cross-sectional views each taken along the dashed-dotted line A1-A2 in FIG. 1A.

Thin films included in the display device (e.g., insulating films, semiconductor films, and conductive films) can be formed by a sputtering method, a chemical vapor deposition (CVD) method, a vacuum evaporation method, a pulsed laser deposition (PLD) method, or an atomic layer deposition (ALD) method. Examples of the CVD method include a plasma enhanced CVD (PECVD) method and a thermal CVD method. An example of the thermal CVD method is a metal organic chemical vapor deposition (MOCVD) method.

The thin films included in the display device (e.g., insulating films, semiconductor films, and conductive films) may be formed by a wet film formation method. Examples of the wet film formation method include a spin coating method, a dip coating method, a spray coating method, an ink-jet method, dispensing, screen printing (stencil printing), offset printing (planography), a doctor knife method, slit coating, roll coating, curtain coating, and knife coating.

Specifically, for manufacturing the light-emitting device, a vacuum process such as an evaporation method and a solution process such as a spin coating method or an ink-jet method can be used. Examples of the evaporation method include physical vapor deposition methods (PVD methods) such as a sputtering method, an ion plating method, an ion beam evaporation method, a molecular beam evaporation method, and a vacuum evaporation method, and a chemical vapor deposition method (CVD method). Specifically, functional layers (a hole-injection layer, a hole-transport layer, a hole-blocking layer, a light-emitting layer, an electron-blocking layer, an electron-transport layer, an electron-injection layer, a charge-generation layer, and the like) included in the EL layer can be formed by, for example, an evaporation method (a vacuum evaporation method or the like), a coating method (a dip coating method, a die coating method, a bar coating method, a spin coating method, a spray coating method, or the like), or a printing method (an ink-jet method, screen printing, offset printing, a flexography (relief printing), gravure printing (intaglio printing), a micro-contact printing method, or the like).

For processing the thin films included in the display device, for example, a photolithography method can be employed. Alternatively, the thin films may be processed by a nanoimprinting method, a sandblasting method, a lift-off method, or the like. Alternatively, island-shaped thin films may be directly formed by a film formation method using a shielding mask such as a metal mask.

There are two typical examples of a photolithography method. In one of the methods, a resist mask is formed over a thin film to be processed, the thin film is processed by etching or the like, and then the resist mask is removed. In the other method, a photosensitive thin film is formed and then processed into a desired shape by light exposure and development.

As light used for light exposure in a photolithography method, for example, an i-line (with a wavelength of 365 nm), a g-line (with a wavelength of 436 nm), an h-line (with a wavelength of 405 nm), or light in which these lines are mixed can be used. Besides, ultraviolet light, KrF laser light, or ArF laser light can be used, for example. Light exposure may be performed by liquid immersion exposure technique. As the light used for light exposure, extreme ultraviolet (EUV) light or X-rays may be used. Instead of the light used for light exposure, an electron beam can also be used. Extreme ultraviolet light, X-rays, or an electron beam is preferably used, in which case extremely minute processing can be performed. Note that a photomask is not needed when light exposure is performed by scanning with a beam such as an electron beam.

For etching of the thin films, a dry etching method, a wet etching method, or a sandblasting method can be employed, for example.

The resist mask can be removed by dry etching treatment such as ashing, wet etching treatment, wet etching treatment after dry etching treatment, or dry etching treatment after wet etching treatment.

For the planarization treatment of the thin film, typically, a polishing method such as a chemical mechanical polishing (CMP) method can be suitably used. Alternatively, dry etching treatment or plasma treatment may be used. Note that polishing treatment, dry etching treatment, or plasma treatment may be performed a plurality of times, or these treatments may be performed in combination. In the case where the treatments are performed in combination, the order of steps is not particularly limited and can be set as appropriate depending on the roughness of the surface to be processed.

To process a thin film to have a desired thickness with high precision, a CMP method is used, for example. In that case, first, polishing is performed at a constant processing speed until part of the top surface of the thin film is exposed. After that, polishing is performed under a condition with a lower processing speed until the thin film has a desired thickness, so that highly accurate processing can be performed.

Examples of a method for detecting the end of the polishing include an optical method in which the surface to be processed is irradiated with light and a change in the reflected light is detected; a physical method in which a change in the polishing resistance received by the processing apparatus from the surface to be processed is detected; and a method in which a magnetic line is applied to the surface to be processed and a change in the magnetic line due to the generated eddy current is used.

After the top surface of the thin film is exposed, polishing treatment is performed under a condition with a low processing speed while the thickness of the thin film is monitored by an optical method using a laser interferometer or the like, whereby the thickness of the thin film can be controlled with high accuracy. Note that the polishing treatment may be performed a plurality of times until the thin film has a desired thickness, as necessary.

First, a variety of circuits are formed over a substrate, whereby the layer 101 including transistors is formed (FIG. 16A).

The layer 101 including transistors can employ a structure in which a semiconductor circuit including a semiconductor element such as a transistor is provided over a substrate.

As the substrate, a substrate having at least heat resistance high enough to withstand heat treatment performed later can be used. As the substrate, an insulating substrate or a semiconductor substrate is preferably used. Examples of an insulating substrate include a glass substrate, a quartz substrate, a sapphire substrate, and a ceramic substrate. Examples of a semiconductor substrate include a single crystal semiconductor substrate or a polycrystalline semiconductor substrate including silicon, silicon carbide, or the like as a material; a compound semiconductor substrate including silicon germanium, gallium nitride, gallium arsenide, indium arsenide, indium gallium arsenide, indium phosphide, or the like as a material; and an SOI (Silicon On Insulator) substrate.

Examples of the semiconductor circuit formed over the substrate include a pixel circuit, a gate line driver circuit (gate driver), and a source line driver circuit (source driver). In addition to the above, one or both of an arithmetic circuit and a memory circuit may be formed.

Next, an insulating film to be the insulating layer 102 is formed. Then, an opening reaching the layer 101 including transistors is formed in the insulating film in a position where the plug 103 is formed. The opening is preferably an opening reaching an electrode or a wiring provided in the layer 101 including transistors. Then, a conductive film is formed to fill the opening and planarization treatment is performed to expose the top surface of the insulating film.

Thus, the plug 103 embedded in the insulating layer 102 can be formed (see FIG. 16A).

Then, a conductive film to be the pixel electrodes is formed over the insulating layer 102 and the plug 103, a resist mask is formed by a photolithography method, and an unnecessary portion of the conductive film is removed by etching. Thus, the pixel electrode 111a, the pixel electrode 111b, and the pixel electrode 111c can be formed (FIG. 16A). The conductive film to be the pixel electrodes can be formed by a sputtering method or a vacuum evaporation method, for example. The conductive film can be processed by a wet etching method or a dry etching method. The conductive film is preferably processed by anisotropic etching. The pixel electrodes 111a, 111b, and 111c are formed to overlap with the plug 103 and are electrically connected to the plug 103.

Next, part of the insulating layer 102 is partly etched using the pixel electrodes 111a, 111b, and 111c and the resist mask, whereby the groove 175 is formed in the insulating layer 102 (FIG. 16A). Thus, the groove 175 illustrated in FIG. 1A can be formed. After that, the resist mask is removed.

The groove 175 formed in the insulating layer 102 facilitates local thinning of the first layer 113 to be formed later or division of the first layer 113 between the light-emitting devices.

The groove 175 can be formed by an isotropic etching method. For example, wet etching treatment or isotropic plasma etching treatment can be used. In particular, in the case where an inorganic insulating film is used as the insulating layer 102, wet etching treatment is preferably used. In the case where an inorganic insulating film is used as the insulating layer 102, isotropic dry etching treatment is preferably used. Thus, the groove 175 part of which is positioned below the pixel electrode can be formed.

Note that a groove may be formed in the insulating layer 102 before the pixel electrodes 111a, 111b, and 111c are formed (specifically, before the conductive film to be the pixel electrodes is formed). In that case, the groove can be formed using a mask different from the resist mask for forming the pixel electrodes, which expands options of the top surface layout of the groove. For example, the groove illustrated in FIG. 6A, FIG. 7A, or FIG. 8B is preferably formed before the conductive film to be the pixel electrodes is formed.

Next, the first layer 113 is formed over the pixel electrodes 111a, 111b, and 111c (FIG. 16B). In the case of manufacturing a light-emitting device emitting blue light, the first layer 113 contains a light-emitting material emitting blue light. In the case of manufacturing a light-emitting device emitting white light, the first layer 113 contains a light-emitting material emitting blue light and a light-emitting material emitting light having a longer wavelength than blue light.

FIG. 16B illustrates an example in which the island-shaped first layer 113 is provided for each light-emitting device. That is, the island-shaped first layer 113 is provided over each of the pixel electrodes 111a, 111b, and 111c.

In a region between the pixel electrode 111a and the pixel electrode 111b, the material layer 113s is provided over the insulating layer 102 (specifically, in the groove 175). Similarly, the material layer 113s is provided over the insulating layer 102 also in a region between the pixel electrode 111b and the pixel electrode 111c and a region between the pixel electrode 111c and the pixel electrode 111a. The material layer 113s is formed in the same step as the first layer 113 and has the same structure as the first layer 113.

In such a manner, the film to be the first layer 113 is disconnected owing to the groove 175.

The first layer 113 can be formed by an evaporation method, specifically a vacuum evaporation method, for example. The first layer 113 may be formed by a transfer method, a printing method, an ink-jet method, or a coating method.

Note that when steps performed after formation of the first layer 113 are performed at temperature higher than the upper temperature limit of the first layer 113, deterioration of the first layer 113 proceeds, which might result in a decrease in the emission efficiency and reliability of the light-emitting device.

Thus, the upper temperature limit of a compound contained in the light-emitting device is preferably higher than or equal to 100° C. and lower than or equal to 180° C. or higher than or equal to 120° C. and lower than or equal to 180° C., further preferably higher than or equal to 140° C. and lower than or equal to 180° C.

Examples of indicators of the upper temperature limit include the glass transition point (Tg), the softening point, the melting point, the thermal decomposition temperature, and the 5% weight loss temperature. For example, as an indicator of the upper temperature limit of a layer included in the first layer 113, a glass transition point of a material contained in the layer can be used. In the case where the layer is a mixed layer formed of a plurality of materials, a glass transition point of a material contained in the highest proportion can be used, for example. Alternatively, the lowest temperature among the glass transition points of the materials may be used.

In particular, it is preferable that the upper temperature limit of the functional layer provided over the light-emitting layer be high. It is further preferable that the upper temperature limit of the functional layer provided over and in contact with the light-emitting layer be high. When the functional layer has high heat resistance, the light-emitting layer can be effectively protected and damage to the light-emitting layer can be reduced.

In addition, it is particularly preferable that the upper temperature limit of the light-emitting layer be high. In this case, the light-emitting layer can be inhibited from being damaged by heating and being decreased in emission efficiency and lifetime.

Increasing the upper temperature limit of the light-emitting device can improve the reliability of the light-emitting device. Furthermore, the allowable temperature range in the manufacturing process of the display device can be widened, thereby improving the manufacturing yield and the reliability.

Next, an insulating film 125A to be the insulating layer 125 later is formed to cover the pixel electrodes 111a, 111b, and 111c, the first layer 113, and the material layer 113s, and an insulating film 127A is formed over the insulating film 125A (FIG. 16C).

The insulating film 125A and the insulating film 127A are each preferably formed by a formation method that causes less damage to the first layer 113. In particular, the insulating film 125A, which is formed in contact with the top surface and the side surface of the first layer 113, is preferably formed by a formation method that causes less damage to the first layer 113 than the formation method of the insulating film 127A.

The insulating film 125A and the insulating film 127A are each formed at a temperature lower than the upper temperature limit of the first layer 113. When the insulating film 125A is formed at a high substrate temperature, the formed film, even with a small thickness, can have a low impurity concentration and a high barrier property against one or both of water and oxygen.

The insulating film 125A and the insulating film 127A are preferably formed at a substrate temperature higher than or equal to 60° C., higher than or equal to 80° C., higher than or equal to 100° C., or higher than or equal to 120° C. and lower than or equal to 200° C., lower than or equal to 180° C., lower than or equal to 160° C., lower than or equal to 150° C., or lower than or equal to 140° C.

As the insulating film 125A, an insulating film is preferably formed within the above substrate temperature range to have a thickness greater than or equal to 3 nm, greater than or equal to 5 nm, or greater than or equal to 10 nm and less than or equal to 200 nm, less than or equal to 150 nm, less than or equal to 100 nm, or less than or equal to 50 nm.

The insulating film 125A is preferably formed by an ALD method, for example. An ALD method is preferably used, in which case damage due to the film formation can be reduced and a film with high coverage can be formed. As the insulating film 125A, an aluminum oxide film is preferably formed by an ALD method, for example.

The insulating film 125A needs to be formed with good coverage in the groove 175 provided in the insulating layer 102. By an ALD method, an atomic layer can be deposited one by one on the bottom surface and the side surface of the groove 175, whereby the insulating film 125A can be formed on the groove 175 with good coverage. In addition, film formation damage can be reduced.

Alternatively, the insulating film 125A may be formed by a sputtering method, a CVD method, or a PECVD method that has a higher film formation speed than an ALD method. In that case, a highly reliable display device can be manufactured with high productivity.

The insulating film 127A is preferably formed by the above-described wet film formation method. For example, the insulating film 127A is preferably formed by spin coating using a photosensitive resin, specifically, a photosensitive resin composition containing an acrylic resin.

Heat treatment (also referred to as pre-baking) is preferably performed after the insulating film 127A is formed. The heat treatment is performed at a temperature lower than the upper temperature limit of the first layer 113. The substrate temperature in the heat treatment is preferably higher than or equal to 50° C. and lower than or equal to 200° C., further preferably higher than or equal to 60° C. and lower than or equal to 150° C., still further preferably higher than or equal to 70° C. and lower than or equal to 130° C. Accordingly, a solvent contained in the insulating film 127A can be removed.

Then, light exposure is performed so that part of the insulating film 127A is exposed to visible light or ultraviolet rays.

Light used for the light exposure preferably includes the i-line (wavelength: 365 nm). Light used for the light exposure may include one or both of the g-line (wavelength: 436 nm) and the h-line (wavelength: 405 nm).

Next, the region of the insulating film 127A exposed to light is removed by development, so that the insulating layer 127 is formed (FIG. 16D). An alkaline solution is preferably used as a developer, and for example, an aqueous solution of tetramethyl ammonium hydroxide (TMAH) can be used.

There is no particular limitation on the development method, and a dip method, a spin method, a puddle method, a vibration method, or the like can be employed, for example. Note that in order to stabilize the etching rate, a method in which new liquid is constantly supplied is preferably employed. Alternatively, a method in which supply and holding (development) of liquid are repeated (also referred to as a step puddle method) is preferably employed. The step puddle method is preferable because liquid consumption can be reduced and the etching rate can be stabilized as compared to the method in which new liquid is constantly supplied.

Heat treatment (also referred to as post-baking) is preferably performed after the insulating layer 127 is formed. The heat treatment is performed at a temperature lower than the upper temperature limit of the first layer 113. The substrate temperature in the heat treatment is preferably higher than or equal to 50° C. and lower than or equal to 200° C., further preferably higher than or equal to 60° C. and lower than or equal to 150° C., still further preferably higher than or equal to 70° C. and lower than or equal to 130° C. The heating atmosphere may be either an air atmosphere or an inert gas atmosphere. Alternatively, the heating atmosphere may be either an atmospheric pressure atmosphere or a reduced pressure atmosphere. The heat treatment is preferably performed in a reduced-pressure atmosphere, in which case drying can be performed at a lower temperature. The heat treatment in this step is preferably performed at a higher substrate temperature than the heat treatment (pre-baking) after formation of the insulating film 127A.

Next, etching treatment is performed using the insulating layer 127 as a mask to remove part of the insulating film 125A. Consequently, the insulating film 125 including an opening portion is formed, and the top surface of the first layer 113 is exposed (FIG. 16D). The etching treatment is preferably performed by a wet etching method. Employing a wet etching method can reduce damage to the first layer 113 as compared with the case of employing a dry etching method.

In the case of employing a wet etching method, it is preferable to use a developer, a tetramethylammonium hydroxide (TMAH) aqueous solution, diluted hydrofluoric acid, oxalic acid, phosphoric acid, acetic acid, nitric acid, or a chemical solution containing a mixed solution of any of these acids, for example. In the case of employing a wet etching method, a mixed acid chemical solution containing water, phosphoric acid, diluted hydrofluoric acid, and nitric acid may be used. A chemical solution used for the wet etching treatment may be alkaline or acid.

Additional heat treatment may be performed after part of the first layer 113 is exposed. The heat treatment can remove water contained in the first layer 113 and water adsorbed onto the surface of the first layer 113, for example. For example, heat treatment in an inert gas atmosphere or a reduced-pressure atmosphere can be performed. The heat treatment can be performed at a substrate temperature higher than or equal to 50° C. and lower than or equal to 200° C., preferably higher than or equal to 60° C. and lower than or equal to 150° C., further preferably higher than or equal to 70° C. and lower than or equal to 130° C. The heat treatment is preferably performed in a reduced-pressure atmosphere, in which case dehydration can be performed at a lower temperature. Note that the temperature range of the heat treatment is preferably set as appropriate in consideration of the upper temperature limit of the first layer 113. In consideration of the upper temperature limit of the first layer 113, a temperature higher than or equal to 70° C. and lower than or equal to 130° C. is particularly preferable in the above temperature ranges.

Next, the common layer 114 is formed over the first layer 113 and the insulating layer 127, the common electrode 115 is formed over the common layer 114, and the protective layer 131 is formed over the common electrode 115 (FIG. 16E). In the case of employing the structure including the coloring layers over the protective layer 131 (FIG. 1B and the like), the coloring layers 132R, 132G, and 132B are provided over the protective layer 131 after the above step. Then, the substrate 120 is attached onto the protective layer 131 with the resin layer 122, whereby the display device can be manufactured (FIG. 1B). In the case of employing the structure including the coloring layers on the substrate 120 side (FIG. 11A and the like), the coloring layers 132R, 132G, and 132B are provided over the substrate 120 in advance and then the substrate 120 is attached, whereby the display device can be manufactured.

The common layer 114 can be formed by an evaporation method (including a vacuum evaporation method), a transfer method, a printing method, an inkjet method, or a coating method, for example.

The common electrode 115 can be formed by a sputtering method or a vacuum evaporation method, for example. Alternatively, a film formed by an evaporation method and a film formed by a sputtering method may be stacked.

Examples of a method for forming the protective layer 131 include a vacuum evaporation method, a sputtering method, a CVD method, and an ALD method.

As described above, in the method for manufacturing a display device of this embodiment, the island-shaped first layer 113 is formed without using a fine metal mask, so that the island-shaped first layer 113 can be formed to have a uniform thickness. Accordingly, a high-resolution display device or a display device with a high aperture ratio can be obtained. Furthermore, even when the resolution or the aperture ratio is high and the distance between subpixels is extremely short, the first layers 113 of adjacent subpixels can be inhibited from being in contact with each other. Accordingly, generation of leakage current between subpixels can be inhibited. This can prevent crosstalk-induced unintended light emission, so that a display device with extremely high contrast can be obtained.

Furthermore, in the method for manufacturing a display device of this embodiment, subpixels of three colors can be separately formed by forming only one type of EL layer. This can reduce the number of manufacturing steps, so that a display device can be manufactured with high yield.

In the method for manufacturing a display device of this embodiment, the light-emitting device can be formed over the insulating layer 102 having a flat top surface. Furthermore, the lower electrode (pixel electrode) of the light-emitting device can be electrically connected to a pixel circuit or the like provided in the layer 101 including transistors through the plug 103, so that an extremely minute pixel can be formed and accordingly a display device with extremely high resolution can be achieved. Since the light-emitting device can be placed to overlap with a pixel circuit or a driver circuit, a display device with a high aperture ratio (effective light-emitting area ratio) can be achieved.

Providing the insulating layer 127 with a tapered end portion between the island-shaped first layers 113 adjacent to each other can inhibit the common electrode 115 from being disconnected and inhibit the common electrode 115 from being locally thinned at the time of forming the common electrode 115. This can inhibit the common layer 114 and the common electrode 115 from having a connection defect due to a divided portion and an increased electric resistance due to a locally thinned portion. Thus, the display device of one embodiment of the present invention can have both high resolution and high display quality.

This embodiment can be combined with any of the other embodiments as appropriate.

### Embodiment 3

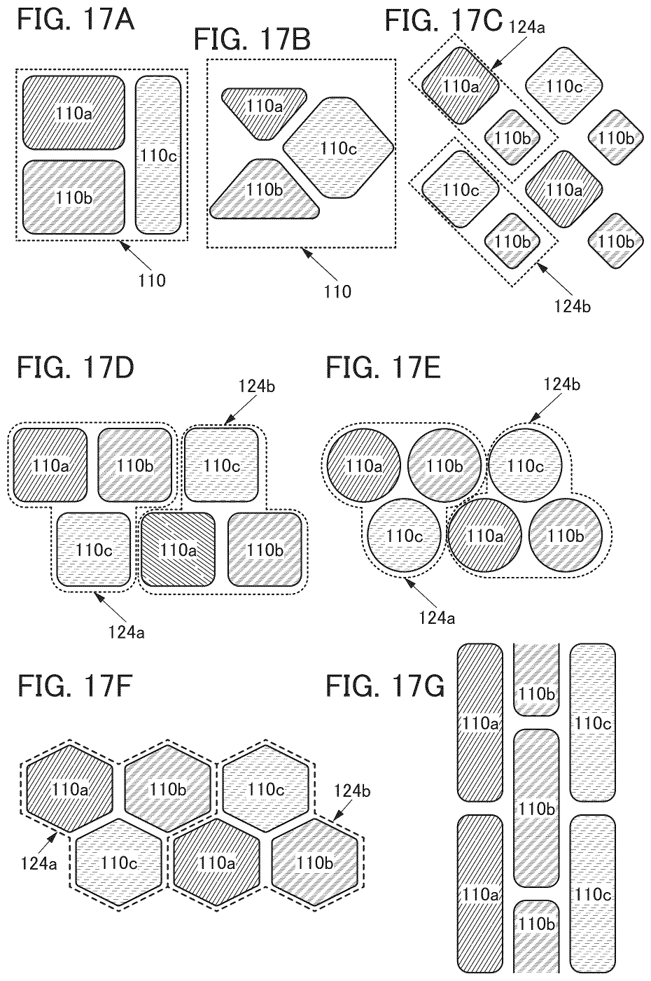

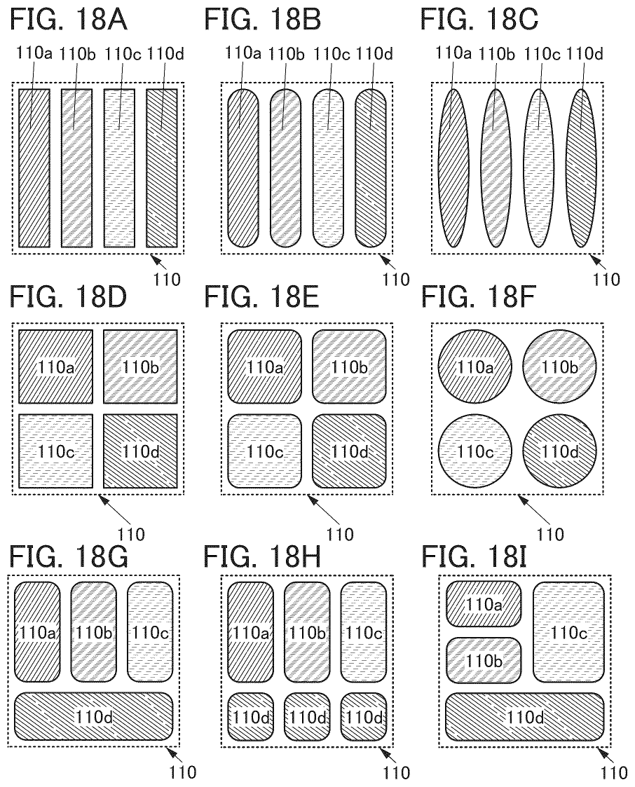

In this embodiment, a display device of one embodiment of the present invention will be described with reference to FIG. 17 and FIG. 18.

### [Pixel Layout]

In this embodiment, pixel layouts different from that in FIG. 1A will be mainly described. There is no particular limitation on the arrangement of subpixels, and a variety of methods can be employed. Examples of the arrangement of subpixels include stripe arrangement, S-stripe arrangement, matrix arrangement, delta arrangement, Bayer arrangement, and PenTile arrangement.

The top surface shape of a subpixel shown in a diagram in this embodiment corresponds to the top surface shape of a light-emitting region. Examples of the top surface shape of the subpixel include polygons such as a triangle, a tetragon (including a rectangle, a rhombus, and a square), and a pentagon; polygons with rounded corners; an ellipse; and a circle.

The range of the circuit layout for forming the subpixels is not limited to the range of the subpixels illustrated in a diagram, and the components of the circuit may be placed outside the subpixels. The arrangement of the circuits and the arrangement of the light-emitting devices are not necessarily the same, and different arrangement methods may be employed. For example, the arrangement of the circuits may be stripe arrangement, and the arrangement of the light-emitting devices may be S-stripe arrangement.

The pixel 110 illustrated in FIG. 17A employs S-stripe arrangement. The pixel 110 illustrated in FIG. 17A is composed of three subpixels: subpixels 110a, 110b, and 110c.

The pixel 110 illustrated in FIG. 17B includes the subpixel 110a whose top surface has a rough triangle or rough trapezoidal shape with rounded corners, the subpixel 110b whose top surface has a rough triangle or rough trapezoidal shape with rounded corners, and the subpixel 110c whose top surface has a rough tetragonal or rough hexagonal shape with rounded corners. The subpixel 110b has a larger light-emitting area than the subpixel 110a. In this manner, the shapes and sizes of the subpixels can be determined independently. For example, the size of a subpixel including a light-emitting device with higher reliability can be smaller.

Pixels 124a and 124b illustrated in FIG. 17C employ PenTile arrangement. FIG. 17C illustrates an example in which the pixels 124a each including the subpixel 110a and the subpixel 110b and the pixels 124b each including the subpixel 110b and the subpixel 110c are alternately arranged.

The pixels 124a and 124b illustrated in FIG. 17D to FIG. 17F employ delta arrangement. The pixel 124a includes two subpixels (the subpixels 110a and 110b) in the upper row (first row) and one subpixel (the subpixel 110c) in the lower row (second row). The pixel 124b includes one subpixel (the subpixel 110c) in the upper row (first row) and two subpixels (the subpixels 110a and 110b) in the lower row (second row).

FIG. 17D illustrates an example in which each subpixel has a rough tetragonal top surface shape with rounded corners, FIG. 17E illustrates an example in which each subpixel has a circular top surface shape, and FIG. 17F illustrates an example in which each subpixel has a rough hexagonal top surface shape with rounded corners.

In FIG. 17F, subpixels are placed inside the closest-packed hexagonal regions. Focusing on one of the subpixels, the subpixel is placed so as to be surrounded by six subpixels. The subpixels are arranged such that subpixels that emit light of the same color are not adjacent to each other. For example, focusing on the subpixel 110a, the subpixel 110a is surrounded by three subpixels 110b and three subpixels 110c that are alternately arranged.

FIG. 17G illustrates an example in which subpixels of different colors are arranged in a zigzag manner. Specifically, the positions of the top sides of two subpixels arranged in the column direction (e.g., the subpixel 110a and the subpixel 110b or the subpixel 110b and the subpixel 110c) are not aligned in the top view.

In the pixels illustrated in FIG. 17A to FIG. 17G, for example, the subpixel 110a is preferably a subpixel R emitting red light, the subpixel 110b is preferably a subpixel G emitting green light, and the subpixel 110c is preferably a subpixel B emitting blue light. Note that the structures of the subpixels are not limited thereto, and the colors and arrangement order of the subpixels can be determined as appropriate. For example, the subpixel 110b may be a subpixel R emitting red light and the subpixel 110a may be a subpixel G emitting green light.

In a photolithography method, as a pattern to be formed by processing becomes finer, the influence of light diffraction becomes more difficult to ignore; therefore, the fidelity in transferring a photomask pattern by light exposure is degraded, and it becomes difficult to process a resist mask into a desired shape. Thus, a pattern with rounded corners is likely to be formed even with a rectangular photomask pattern. Consequently, the top surface of a pixel electrode may have a polygonal shape with rounded corners, an elliptical shape, or a circular shape, for example. In the display device of one embodiment of the present invention, the top surface shape of the EL layer and the top surface shape of the light-emitting device are affected by the top surface shape of the pixel electrode to be, for example, a polygonal shape with rounded corners, an elliptical shape, or a circular shape in some cases.

Note that to obtain a desired top surface shape of the pixel electrode, a technique of correcting a mask pattern in advance so that a transferred pattern agrees with a design pattern (OPC (Optical Proximity Correction) technique) may be used. Specifically, with the OPC technique, a pattern for correction is added to a corner portion or the like of a figure on a mask pattern.

As illustrated in FIG. 18A to FIG. 18I, the pixel can include four types of subpixels.

The pixels 110 illustrated in FIG. 18A to FIG. 18C employ stripe arrangement.

FIG. 18A illustrates an example in which each subpixel has a rectangular top surface shape, FIG. 18B illustrates an example in which each subpixel has a top surface shape formed by combining two half circles and a rectangle, and FIG. 18C illustrates an example in which each subpixel has an elliptical top surface shape.

The pixels 110 illustrated in FIG. 18D to FIG. 18F employ matrix arrangement.

FIG. 18D illustrates an example in which each subpixel has a square top surface shape, FIG. 18E illustrates an example in which each subpixel has a substantially square top surface shape with rounded corners, and FIG. 18F illustrates an example in which each subpixel has a circular top surface shape.

FIG. 18G and FIG. 18H each illustrate an example in which one pixel 110 is composed of two rows and three columns.

The pixel 110 illustrated in FIG. 18G includes three subpixels (the subpixels 110a, 110b, and 110c) in the upper row (first row) and one subpixel (a subpixel 110d) in the lower row (second row). In other words, the pixel 110 includes the subpixel 110a in the left column (first column), the subpixel 110b in the center column (second column), the subpixel 110c in the right column (third column), and the subpixel 110d across these three columns.

The pixel 110 illustrated in FIG. 18H includes three subpixels (the subpixels 110a, 110b, and 110c) in the upper row (first row) and three subpixels 110d in the lower row (second row). In other words, the pixel 110 includes the subpixel 110a and the subpixel 110d in the left column (first column), the subpixel 110b and the subpixel 110d in the center column (second column), and the subpixel 110c and the subpixel 110d in the right column (third column). Aligning the positions of the subpixels in the upper row and the lower row as illustrated in FIG. 18H enables efficient removal of dust and the like that would be produced in the manufacturing process. Thus, a display device with high display quality can be provided.

FIG. 18I illustrates an example in which one pixel 110 is composed of three rows and two columns.

The pixel 110 illustrated in FIG. 18I includes the subpixel 110a in the upper row (first row), the subpixel 110b in the center row (second row), the subpixel 110c across the first and second rows, and one subpixel (the subpixel 110d) in the lower row (third row). In other words, the pixel 110 includes the subpixels 110a and 110b in the left column (first column), the subpixel 110c in the right column (second column), and the subpixel 110d across these two columns.

The pixels 110 illustrated in FIG. 18A to FIG. 18I are each composed of four subpixels: the subpixels 110a, 110b, 110c, and 110d.

The subpixels 110a, 110b, 110c, and 110d can include light-emitting devices that emit light of different colors. The subpixels 110a, 110b, 110c, and 110d can be subpixels of four colors of R, G, B, and white (W), subpixels of four colors of R, G, B, and Y, or subpixels of R, G, B, and infrared light (IR), for example.

In the pixels 110 illustrated in FIG. 18A to FIG. 18I, the subpixel 110a is preferably a subpixel R emitting red light, the subpixel 110b is preferably a subpixel G emitting green light, the subpixel 110c is preferably a subpixel B emitting blue light, and the subpixel 110d is preferably any of a subpixel W emitting white light, a subpixel Y emitting yellow light, and a subpixel IR emitting near-infrared light, for example. In the case of such a structure, stripe arrangement is employed as the layout of R, G, and B in the pixels 110 illustrated in FIG. 18G and FIG. 18H, leading to higher display quality. In addition, what is called S-stripe arrangement is employed as the layout of R, G, and B in the pixel 110 illustrated in FIG. 18I, leading to higher display quality.

As described above, the pixel composed of the subpixels each including the light-emitting device can employ any of a variety of layouts in the display device of one embodiment of the present invention.

This embodiment can be combined with any of the other embodiments as appropriate.

### Embodiment 4

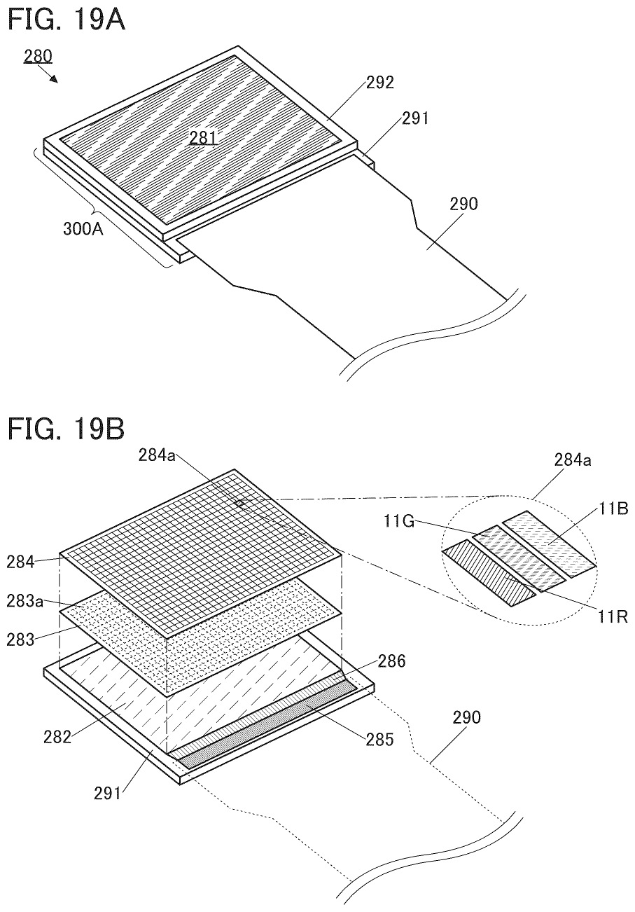

In this embodiment, display devices of one embodiment of the present invention will be described with reference to FIG. 19 to FIG. 25.

The display device of this embodiment can be a high-resolution display device. Accordingly, the display device of this embodiment can be used for display portions of information terminals (wearable devices) such as watch-type and bracelet-type information terminals and display portions of wearable devices that can be worn on the head, such as a VR device like a head-mounted display (HMD) and a glasses-type AR device.

### [Display Module]

FIG. 19A illustrates a perspective view of a display module 280. The display module 280 includes a display device 300A and an FPC 290. Note that the display device included in the display module 280 is not limited to the display device 300A and may be any of display device 300B to a display device 300F described later.

The display module 280 includes a substrate 291 and a substrate 292. The display module 280 includes a display portion 281. The display portion 281 is a region of the display module 280 where an image is displayed, and is a region where light emitted from pixels provided in a pixel portion 284 described later can be seen.

FIG. 19B illustrates a perspective view schematically illustrating a structure on the substrate 291 side. Over the substrate 291, a circuit portion 282, a pixel circuit portion 283 over the circuit portion 282, and the pixel portion 284 over the pixel circuit portion 283 are stacked. A terminal portion 285 to be connected to the FPC 290 is provided in a portion over the substrate 291 that does not overlap with the pixel portion 284. The terminal portion 285 and the circuit portion 282 are electrically connected to each other through a wiring portion 286 formed of a plurality of wirings.

The pixel portion 284 includes a plurality of pixels 284a arranged periodically. An enlarged view of one pixel 284a is illustrated on the right side in FIG. 19B. The pixel 284a includes a subpixel 11R emitting red light, a subpixel 11G emitting green light, and a subpixel 11B emitting blue light.

The pixel circuit portion 283 includes a plurality of pixel circuits 283a arranged periodically.

One pixel circuit 283a is a circuit that controls light emission of three light-emitting devices included in one pixel 284a. One pixel circuit 283a can be provided with three circuits each controlling light emission of one light-emitting device. For example, the pixel circuit 283a can include at least one selection transistor, one current control transistor (driving transistor), and a capacitor for one light-emitting device. In that case, a gate signal is input to a gate of the selection transistor, and a source signal is input to a source of the selection transistor. Thus, an active-matrix display device is achieved.

The circuit portion 282 includes a circuit for driving the pixel circuits 283a in the pixel circuit portion 283. For example, one or both of a gate line driver circuit and a source line driver circuit are preferably included. In addition, one or more of an arithmetic circuit, a memory circuit, and a power supply circuit may be included. In addition, a transistor provided in the circuit portion 282 may constitute part of the pixel circuit 283a. That is, the pixel circuit 283a may be constituted by a transistor included in the pixel circuit portion 283 and a transistor included in the circuit portion 282.

The FPC 290 functions as a wiring for supplying a video signal and a power supply potential to the circuit portion 282 from the outside. An IC may be mounted on the FPC 290.

The display module 280 can have a structure in which one or both of the pixel circuit portion 283 and the circuit portion 282 are stacked below the pixel portion 284; hence, the aperture ratio (the effective display area ratio) of the display portion 281 can be significantly high. For example, the aperture ratio of the display portion 281 can be greater than or equal to 40% and less than 100%, preferably greater than or equal to 50% and less than or equal to 95%, further preferably greater than or equal to 60% and less than or equal to 95%. Furthermore, the pixels 284a can be arranged extremely densely and thus the display portion 281 can have extremely high resolution. For example, the pixels 284a are preferably arranged in the display portion 281 with a resolution higher than or equal to 2000 ppi, preferably higher than or equal to 3000 ppi, further preferably higher than or equal to 5000 ppi, still further preferably higher than or equal to 6000 ppi, and lower than or equal to 20000 ppi or lower than or equal to 30000 ppi.

Such a display module 280 has extremely high resolution, and thus can be suitably used for a VR device such as an HMD or a glasses-type AR device. For example, even with a structure in which the display portion of the display module 280 is seen through a lens, pixels of the extremely-high-resolution display portion 281 included in the display module 280 are not perceived even when the display portion is enlarged by the lens, so that display providing a high sense of immersion can be performed. Without being limited thereto, the display module 280 can be suitably used for electronic devices including a relatively small display portion. For example, the display module 280 can be suitably used in a display portion of a wearable electronic device, such as a wristwatch.

### [Display Device 300A]

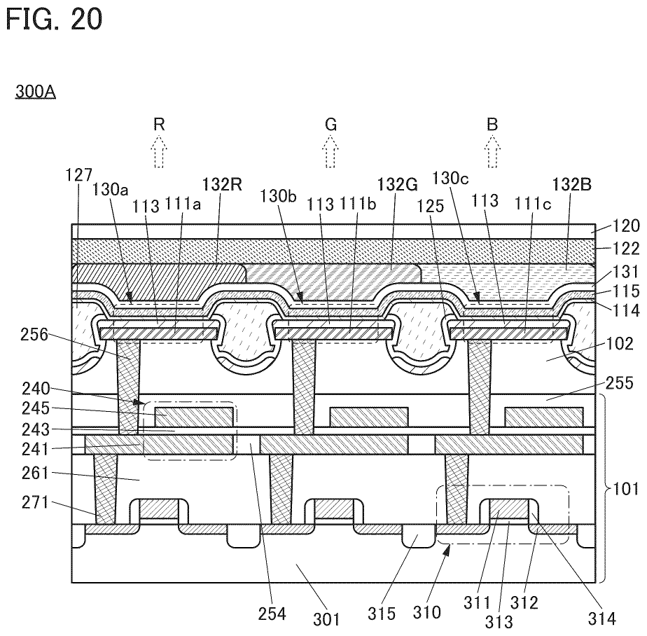

The display device 300A illustrated in FIG. 20 includes a substrate 301, the light-emitting device 130a, the light-emitting device 130b, the light-emitting device 130c, the coloring layer 132R, the coloring layer 132G, the coloring layer 132B, a capacitor 240, and a transistor 310.

The subpixel 11R illustrated in FIG. 19B includes the light-emitting device 130a and the coloring layer 132R, the subpixel 11G includes the light-emitting device 130b and the coloring layer 132G, and the subpixel 11B includes the light-emitting device 130c and the coloring layer 132B. In the subpixel 11R, light emitted from the light-emitting device 130a is extracted as red light (R) to the outside of the display device 300A through the coloring layer 132R. Similarly, in the subpixel 11G, light emitted from the light-emitting device 130b is extracted as green light (G) to the outside of the display device 300A through the coloring layer 132G. In the subpixel 11B, light emitted from the light-emitting device 130c is extracted as blue light (B) to the outside of the display device 300A through the coloring layer 132B.

The substrate 301 corresponds to the substrate 291 in FIG. 19A and FIG. 19B. A stacked-layer structure including the substrate 301 and the components thereover up to the insulating layer 255 corresponds to the layer 101 including transistors in Embodiment 1.

The transistor 310 is a transistor including a channel formation region in the substrate 301. As the substrate 301, a semiconductor substrate such as a single crystal silicon substrate can be used, for example. The transistor 310 includes part of the substrate 301, a conductive layer 311, low-resistance regions 312, an insulating layer 313, and an insulating layer 314. The conductive layer 311 functions as a gate electrode. The insulating layer 313 is positioned between the substrate 301 and the conductive layer 311 and functions as a gate insulating layer. The low-resistance region 312 is a region where the substrate 301 is doped with an impurity, and functions as one of a source and a drain. The insulating layer 314 is provided to cover the side surface of the conductive layer 311.

An element isolation layer 315 is provided between two adjacent transistors 310 to be embedded in the substrate 301.

An insulating layer 261 is provided to cover the transistor 310, and the capacitor 240 is provided over the insulating layer 261.

The capacitor 240 includes a conductive layer 241, a conductive layer 245, and an insulating layer 243 positioned therebetween. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 261 and is embedded in an insulating layer 254. The conductive layer 241 is electrically connected to one of a source and a drain of the transistor 310 through a plug 271 embedded in the insulating layer 261. The insulating layer 243 is provided to cover the conductive layer 241. The conductive layer 245 is provided in a region overlapping with the conductive layer 241 with the insulating layer 243 therebetween.

Note that a conductive layer surrounding the outer surface of the display portion 281 (or the pixel portion 284) is preferably provided in at least one layer of the conductive layers included in the layer 101 including transistors. The conductive layer can be referred to as a guard ring. By providing the conductive layer, elements such as a transistor and a light-emitting device can be inhibited from being broken by high voltage application due to ESD (electrostatic discharge) or charging caused by a step using plasma.

The insulating layer 255 is provided to cover the capacitor 240. The insulating layer 102 is provided over the insulating layer 255, and the light-emitting device 130a, the light-emitting device 130b, and the light-emitting device 130c are provided over the insulating layer 102. FIG. 20 illustrates an example in which the insulating layer 102, the light-emitting device 130a, the light-emitting device 130b, and the light-emitting device 130c each have the structure illustrated in FIG. 1B.

The pixel electrode 111a, the pixel electrode 111b, and the pixel electrode 111c are each electrically connected to one of the source and the drain of the transistor 310 through a plug 256 embedded in the insulating layer 243, the insulating layer 255, and the insulating layer 102, the conductive layer 241 embedded in the insulating layer 254, and the plug 271 embedded in the insulating layer 261. The surface of the insulating layer 102 in contact with the pixel electrode and the surface of the plug 256 in contact with the pixel electrode are level or substantially level with each other. A variety of conductive materials can be used for the plugs.

The protective layer 131 is provided over the light-emitting device 130a, the light-emitting device 130b, and the light-emitting device 130c. Over the protective layer 131, the coloring layer 132R is provided in a position overlapping with the light-emitting device 130a, the coloring layer 132G is provided in a position overlapping with the light-emitting device 130b, and the coloring layer 132B is provided in a position overlapping with the light-emitting device 130c. The substrate 120 is attached onto the coloring layers 132R, 132G, and 132B with the resin layer 122. Embodiment 1 can be referred to for the details of the light-emitting devices and the components thereover up to the substrate 120. The substrate 120 corresponds to the substrate 292 in FIG. 19A.

### [Display Device 300B]

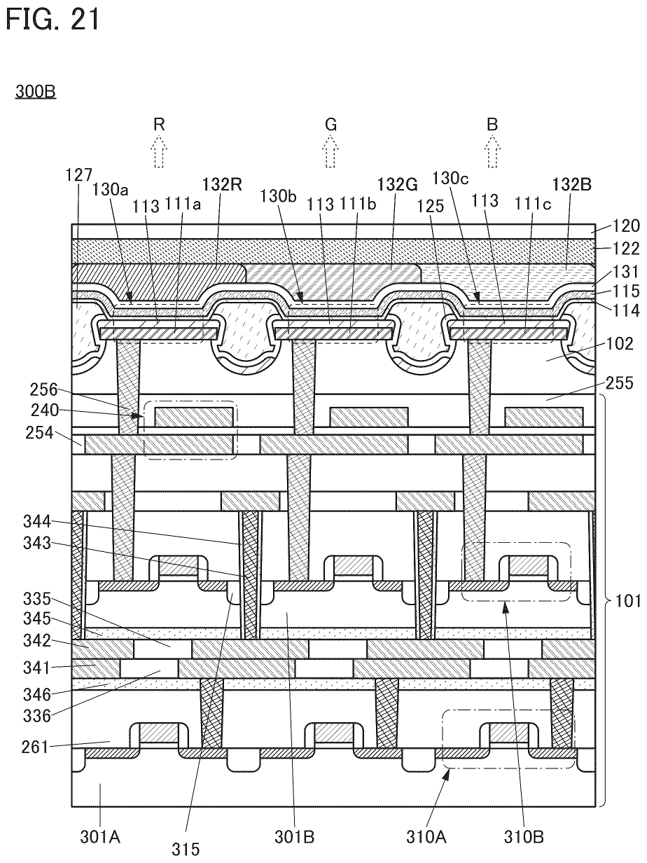

The display device 300B illustrated in FIG. 21 has a structure in which a transistor 310A and a transistor 310B in each of which a channel is formed in a semiconductor substrate are stacked.

Note that in the following description of display devices, the description of portions similar to those of the above-described display device may be omitted.

In the display device 300B, a substrate 301B provided with the transistor 310B, the capacitor 240, and the light-emitting devices is attached to a substrate 301A provided with the transistor 310A.

Here, an insulating layer 345 is preferably provided on the bottom surface of the substrate 301B. An insulating layer 346 is preferably provided over the insulating layer 261 provided over the substrate 301A. The insulating layers 345 and 346 are insulating layers functioning as protective layers and can inhibit diffusion of impurities into the substrate 301B and the substrate 301A. As the insulating layers 345 and 346, an inorganic insulating film that can be used as the protective layer 131 or the insulating layer 332 can be used.

The substrate 301B is provided with a plug 343 that penetrates the substrate 301B and the insulating layer 345. An insulating layer 344 is preferably provided to cover the side surface of the plug 343. The insulating layer 344 is an insulating layer functioning as a protective layer and can inhibit diffusion of impurities into the substrate 301B. As the insulating layer 344, an inorganic insulating film that can be used as the protective layer 131 can be used.

A conductive layer 342 is provided under the insulating layer 345 on the rear surface of the substrate 301B (the surface opposite to the substrate 120). The conductive layer 342 is preferably provided to be embedded in an insulating layer 335. The bottom surfaces of the conductive layer 342 and the insulating layer 335 are preferably planarized. Here, the conductive layer 342 is electrically connected to the plug 343.

Over the substrate 301A, a conductive layer 341 is provided over the insulating layer 346. The conductive layer 341 is preferably provided to be embedded in an insulating layer 336. The top surfaces of the conductive layer 341 and the insulating layer 336 are preferably planarized.

The conductive layer 341 and the conductive layer 342 are bonded to each other, whereby the substrate 301A and the substrate 301B are electrically connected to each other. Here, improving the flatness of a plane formed by the conductive layer 342 and the insulating layer 335 and a plane formed by the conductive layer 341 and the insulating layer 336 allows the conductive layer 341 and the conductive layer 342 to be attached to each other favorably.

The conductive layer 341 and the conductive layer 342 are preferably formed using the same conductive material. For example, it is possible to use a metal film containing an element selected from Al, Cr, Cu, Ta, Ti, Mo, and W, or a metal nitride film containing any of the above elements as a component (a titanium nitride film, a molybdenum nitride film, or a tungsten nitride film). Copper is particularly preferably used for the conductive layer 341 and the conductive layer 342. In that case, it is possible to employ a Cu—Cu (copper-copper) direct bonding technique (a technique for achieving electrical continuity by connecting Cu (copper) pads).

### [Display Device 300C]

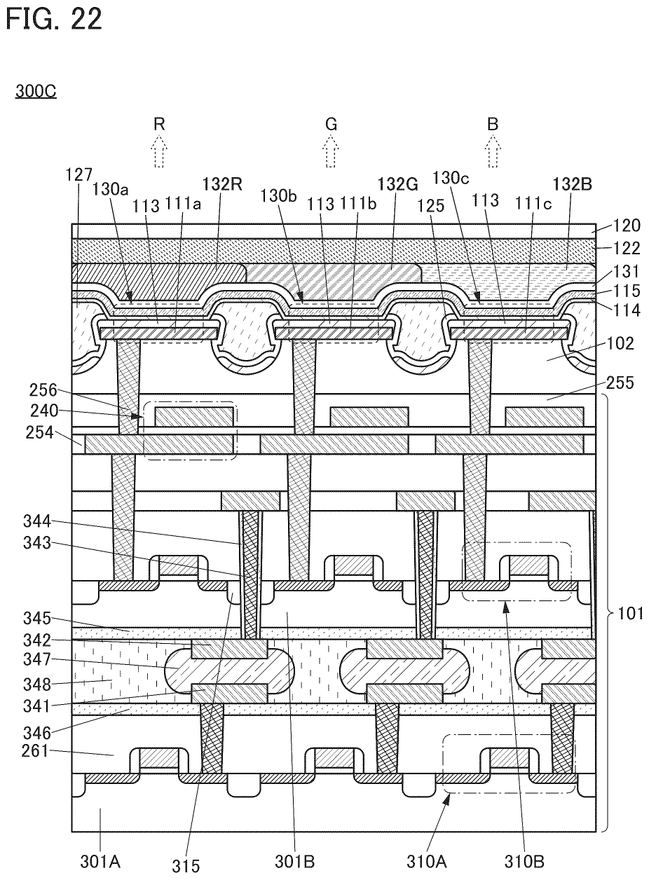

In the display device 300C illustrated in FIG. 22, the conductive layer 341 and the conductive layer 342 are bonded to each other with a bump 347.

As illustrated in FIG. 22, providing the bump 347 between the conductive layer 341 and the conductive layer 342 enables the conductive layer 341 and the conductive layer 342 to be electrically connected to each other. The bump 347 can be formed using a conductive material containing at least one of gold (Au), nickel (Ni), indium (In), and tin (Sn), for example. For another example, solder may be used for the bump 347. An adhesive layer 348 may be provided between the insulating layer 345 and the insulating layer 346. In the case where the bump 347 is provided, the insulating layer 335 and the insulating layer 336 may be omitted.

### [Display Device 300D]

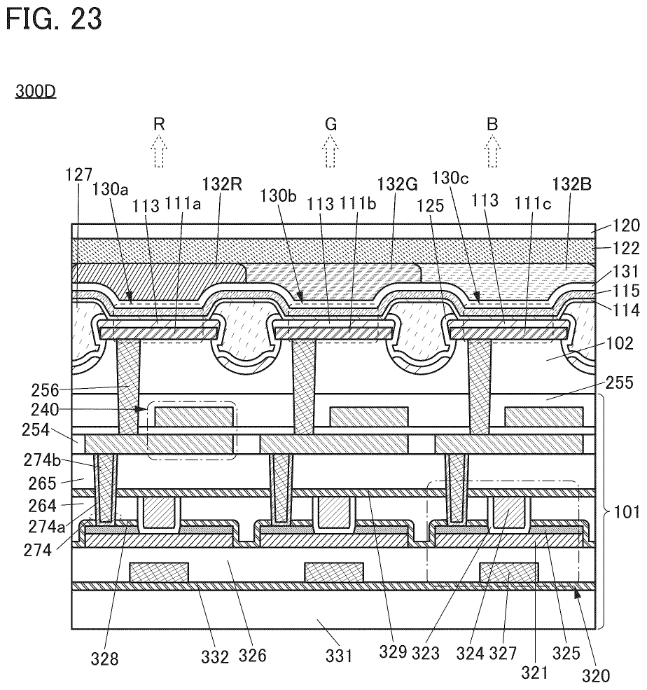

The display device 300D illustrated in FIG. 23 differs from the display device 300A mainly in a structure of a transistor.

A transistor 320 is a transistor (an OS transistor) that contains a metal oxide (also referred to as an oxide semiconductor) in its semiconductor layer where a channel is formed.

The transistor 320 includes a semiconductor layer 321, an insulating layer 323, a conductive layer 324, a pair of conductive layers 325, an insulating layer 326, and a conductive layer 327.

A substrate 331 corresponds to the substrate 291 in FIG. 19A and FIG. 19B. A stacked-layer structure including the substrate 331 and the components thereover up to the insulating layer 255 corresponds to the layer 101 including transistors in Embodiment 1. As the substrate 331, an insulating substrate or a semiconductor substrate can be used.

The insulating layer 332 is provided over the substrate 331. The insulating layer 332 functions as a barrier layer that prevents diffusion of impurities such as water and hydrogen from the substrate 331 into the transistor 320 and release of oxygen from the semiconductor layer 321 to the insulating layer 332 side. As the insulating layer 332, for example, a film in which hydrogen or oxygen is less likely to diffuse than in a silicon oxide film, such as an aluminum oxide film, a hafnium oxide film, or a silicon nitride film, can be used.

The conductive layer 327 is provided over the insulating layer 332, and the insulating layer 326 is provided to cover the conductive layer 327. The conductive layer 327 functions as a first gate electrode of the transistor 320, and part of the insulating layer 326 functions as a first gate insulating layer. An oxide insulating film such as a silicon oxide film is preferably used as at least part of the insulating layer 326 that is in contact with the semiconductor layer 321. The top surface of the insulating layer 326 is preferably planarized.

The semiconductor layer 321 is provided over the insulating layer 326. The semiconductor layer 321 preferably includes a metal oxide (also referred to as an oxide semiconductor) film having semiconductor characteristics. The pair of conductive layers 325 are provided on and in contact with the semiconductor layer 321 and function as a source electrode and a drain electrode.

An insulating layer 328 is provided to cover the top surfaces and the side surfaces of the pair of conductive layers 325, the side surface of the semiconductor layer 321, and the like, and an insulating layer 264 is provided over the insulating layer 328. The insulating layer 328 functions as a barrier layer that prevents diffusion of impurities such as water and hydrogen from the insulating layer 264 and the like into the semiconductor layer 321 and release of oxygen from the semiconductor layer 321. As the insulating layer 328, an insulating film similar to the insulating layer 332 can be used.

An opening reaching the semiconductor layer 321 is provided in the insulating layer 328 and the insulating layer 264. The insulating layer 323 that is in contact with the side surfaces of the insulating layer 264, the insulating layer 328, and the conductive layer 325 and the top surface of the semiconductor layer 321, and the conductive layer 324 are embedded in the opening. The conductive layer 324 functions as a second gate electrode, and the insulating layer 323 functions as a second gate insulating layer.

The top surface of the conductive layer 324, the top surface of the insulating layer 323, and the top surface of the insulating layer 264 are planarized so that they are level or substantially level with each other, and an insulating layer 329 and an insulating layer 265 are provided to cover these layers.

The insulating layer 264 and the insulating layer 265 function as interlayer insulating layers. The insulating layer 329 functions as a barrier layer that prevents diffusion of impurities such as water and hydrogen from the insulating layer 265 and the like into the transistor 320. As the insulating layer 329, an insulating film similar to the insulating layer 328 and the insulating layer 332 can be used.

A plug 274 electrically connected to one of the pair of conductive layers 325 is provided to be embedded in the insulating layer 265, the insulating layer 329, and the insulating layer 264. Here, the plug 274 preferably includes a conductive layer 274a that covers the side surface of an opening formed in the insulating layer 265, the insulating layer 329, the insulating layer 264, and the insulating layer 328 and part of the top surface of the conductive layer 325, and a conductive layer 274b in contact with the top surface of the conductive layer 274a. In that case, a conductive material through which hydrogen and oxygen are less likely to diffuse is preferably used for the conductive layer 274a.

There is no particular limitation on the structure of the transistor included in the display device of this embodiment. For example, a planar transistor, a staggered transistor, an inverted staggered transistor, or the like can be used. A top-gate or a bottom-gate transistor structure may be employed. Alternatively, gates may be provided above and below the semiconductor layer where a channel is formed.

The transistor 320 has a structure in which the semiconductor layer where a channel is formed is provided between two gates. The two gates may be connected to each other and supplied with the same signal to drive the transistor. Alternatively, a potential for controlling the threshold voltage may be supplied to one of the two gates and a potential for driving may be supplied to the other to control the threshold voltage of the transistor.

There is no particular limitation on the crystallinity of a semiconductor material used for the transistors, and any of an amorphous semiconductor, a single crystal semiconductor, and a semiconductor having crystallinity other than single crystal (a microcrystalline semiconductor, a polycrystalline semiconductor, or a semiconductor partly including crystal regions) may be used. A single crystal semiconductor or a semiconductor having crystallinity is preferably used, in which case deterioration of the transistor characteristics can be inhibited.

The semiconductor layer of the transistor preferably includes a metal oxide. That is, a transistor including a metal oxide in its channel formation region (an OS transistor) is preferably used for the display device of this embodiment.

Examples of the metal oxide that can be used for the semiconductor layer include indium oxide, gallium oxide, and zinc oxide. The metal oxide used for the semiconductor layer preferably contains two or three selected from indium, an element M, and zinc. Note that the element M is one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, cobalt, and magnesium. In particular, the element M is preferably one or more kinds selected from aluminum, gallium, yttrium, and tin.

It is particularly preferable that an oxide containing indium (In), gallium (Ga), and zinc (Zn) (also referred to as IGZO) be used as the metal oxide used for the semiconductor layer. Alternatively, it is preferable to use an oxide containing indium, tin, and zinc (also referred to as ITZO (registered trademark)). Alternatively, it is preferable to use an oxide containing indium, gallium, tin, and zinc. Alternatively, it is preferable to use an oxide containing indium (In), aluminum (Al), and zinc (Zn) (also referred to as IAZO). Alternatively, it is preferable to use an oxide containing indium (In), aluminum (Al), gallium (Ga), and zinc (Zn) (also referred to as IAGZO).

In the case where the metal oxide used for the semiconductor layer is an In-M-Zn oxide, the atomic proportion of In is preferably greater than or equal to the atomic proportion of M in the In-M-Zn oxide. Examples of the atomic ratio of the metal elements in such an In-M-Zn oxide include In:M:Zn=1:1:1 or a composition in the neighborhood thereof, In:M:Zn=1:1:1.2 or a composition in the neighborhood thereof, In:M:Zn=1:3:2 or a composition in the neighborhood thereof, In:M:Zn=1:3:4 or a composition in the neighborhood thereof, In:M:Zn=2:1:3 or a composition in the neighborhood thereof, In:M:Zn=3:1:2 or a composition in the neighborhood thereof, In:M:Zn=4:2:3 or a composition in the neighborhood thereof, In:M:Zn=4:2:4.1 or a composition in the neighborhood thereof, In:M:Zn=5:1:3 or a composition in the neighborhood thereof, In:M:Zn=5:1:6 or a composition in the neighborhood thereof, In:M:Zn=5:1:7 or a composition in the neighborhood thereof, In:M:Zn=5:1:8 or a composition in the neighborhood thereof, In:M:Zn=6:1:6 or a composition in the neighborhood thereof, and In:M:Zn=5:2:5 or a composition in the neighborhood thereof. Note that a composition in the neighborhood includes the range of +30% of an intended atomic ratio.

For example, when the atomic ratio is described as In:Ga:Zn=4:2:3 or a composition in the neighborhood thereof, the case is included where Ga is greater than or equal to 1 and less than or equal to 3 and Zn is greater than or equal to 2 and less than or equal to 4 with In being 4. When the atomic ratio is described as In:Ga:Zn=5:1:6 or a composition in the neighborhood thereof, the case is included where Ga is greater than 0.1 and less than or equal to 2 and Zn is greater than or equal to 5 and less than or equal to 7 with In being 5. When the atomic ratio is described as In:Ga:Zn=1:1:1 or a composition in the neighborhood thereof, the case is included where Ga is greater than 0.1 and less than or equal to 2 and Zn is greater than 0.1 and less than or equal to 2 with In being 1.

The semiconductor layer may include two or more metal oxide layers having different compositions. For example, a stacked-layer structure of a first metal oxide layer having In:M:Zn=1:3:4 [atomic ratio] or a composition in the neighborhood thereof and a second metal oxide layer having In:M:Zn=1:1:1 [atomic ratio] or a composition in the neighborhood thereof and being provided over the first metal oxide layer can be favorably employed. In particular, gallium or aluminum is preferably used as the element M.

For another example, a stacked-layer structure of one selected from indium oxide, indium gallium oxide, and IGZO, and one selected from IAZO, IAGZO, and ITZO (registered trademark) may be employed.

Examples of the oxide semiconductor having crystallinity include a CAAC (c-axis-aligned crystalline)-OS and an nc (nanocrystalline)-OS.

Alternatively, a transistor containing silicon in its channel formation region (a Si transistor) may be used. Examples of silicon include single crystal silicon, polycrystalline silicon, low-temperature polysilicon (LTPS), and amorphous silicon.

With the use of a Si transistor, a circuit required to be driven at a high frequency (e.g., a source driver circuit) can be formed on the same substrate as the display portion. This allows simplification of an external circuit mounted on the display device and a reduction in component cost and mounting cost.

The OS transistor has much higher field-effect mobility than a transistor containing amorphous silicon. In addition, the OS transistor has an extremely low leakage current flowing between a source and a drain in an off state (also referred to as an off-state current), and charge accumulated in a capacitor that is connected in series to the transistor can be retained for a long period. Furthermore, power consumption of the display device can be reduced with the OS transistor.

To increase the emission luminance of the light-emitting device included in the pixel circuit, the amount of current fed through the light-emitting device needs to be increased. For that purpose, the source-drain voltage of a driving transistor included in the pixel circuit needs to be increased. An OS transistor has higher withstand voltage between a source and a drain than a Si transistor; hence, high voltage can be applied between the source and the drain of the OS transistor. Thus, by using an OS transistor as a driving transistor included in the pixel circuit, the amount of current flowing through the light-emitting device can be increased, resulting in an increase in emission luminance of the light-emitting device.

When transistors operate in a saturation region, a change in source-drain current relative to a change in gate-source voltage can be smaller in an OS transistor than in a Si transistor. Accordingly, when an OS transistor is used as the driving transistor included in the pixel circuit, current flowing between the source and the drain can be set minutely by a change in gate-source voltage; hence, the amount of current flowing through the light-emitting device can be controlled. Consequently, the number of gray levels in the pixel circuit can be increased.

Regarding saturation characteristics of current flowing when transistors operate in a saturation region, even in the case where the source-drain voltage of an OS transistor increases gradually, more stable current (saturation current) can be fed through the OS transistor than through a Si transistor. Thus, by using an OS transistor as the driving transistor, stable current can be fed through light-emitting devices even when the current-voltage characteristics of the EL devices vary, for example. In other words, when the OS transistor operates in the saturation region, the source-drain current hardly changes with an increase in the source-drain voltage; hence, the emission luminance of the light-emitting device can be stable.

As described above, by using an OS transistor as the driving transistor included in the pixel circuit, it is possible to achieve “inhibition of black-level degradation”, “increase in emission luminance”, “increase in gray level”, and “inhibition of variation in light-emitting devices”, for example.

### [Display Device 300E]

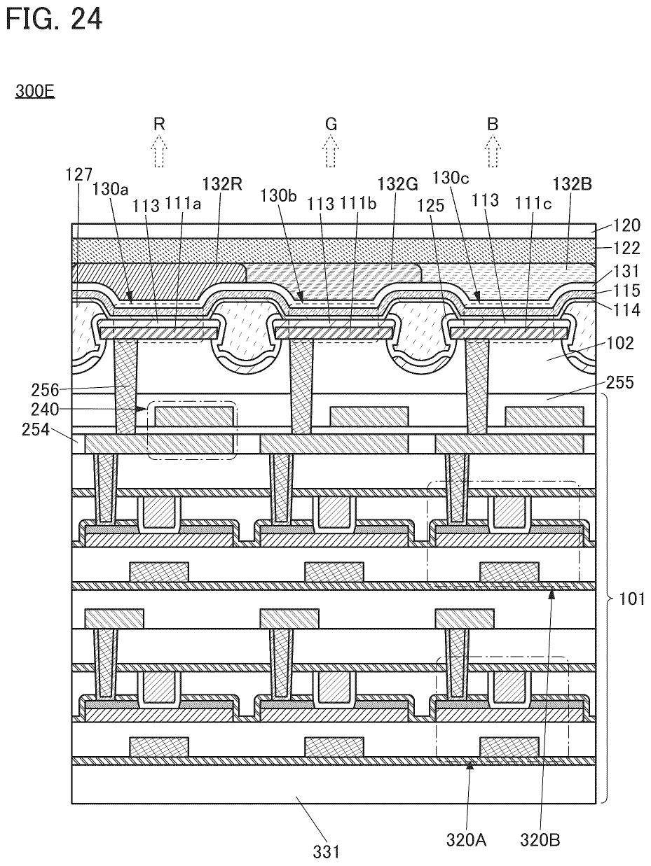

The display device 300E illustrated in FIG. 24 has a structure in which a transistor 320A and a transistor 320B each including an oxide semiconductor in a semiconductor where a channel is formed are stacked.

The display device 300D can be referred to for the transistor 320A, the transistor 320B, and the components around them.

Although the structure in which two transistors each including an oxide semiconductor are stacked is described here, one embodiment of the present invention is not limited thereto. For example, three or more transistors may be stacked.

### [Display Device 300F]

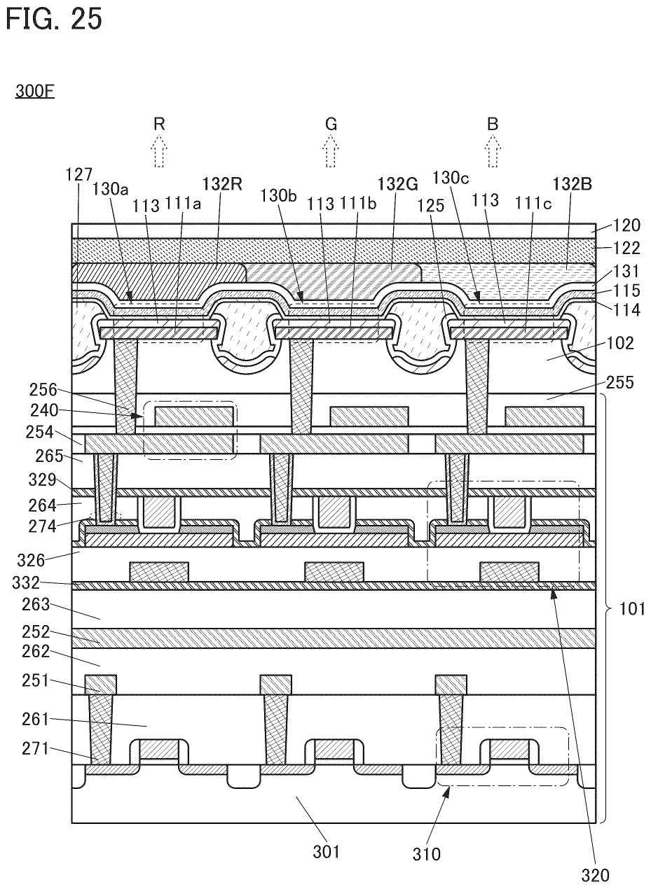

The display device 300F illustrated in FIG. 25 has a structure in which the transistor 310 whose channel is formed in the substrate 301 and the transistor 320 including a metal oxide in a semiconductor layer where a channel is formed are stacked.

The insulating layer 261 is provided to cover the transistor 310, and a conductive layer 251 is provided over the insulating layer 261. An insulating layer 262 is provided to cover the conductive layer 251, and a conductive layer 252 is provided over the insulating layer 262. The conductive layer 251 and the conductive layer 252 each function as a wiring. An insulating layer 263 and the insulating layer 332 are provided to cover the conductive layer 252, and the transistor 320 is provided over the insulating layer 332. The insulating layer 265 is provided to cover the transistor 320, and the capacitor 240 is provided over the insulating layer 265. The capacitor 240 and the transistor 320 are electrically connected to each other through the plug 274.

The transistor 320 can be used as a transistor included in the pixel circuit. The transistor 310 can be used as a transistor included in the pixel circuit or a transistor included in a driver circuit (a gate line driver circuit or a source line driver circuit) for driving the pixel circuit. The transistor 310 and the transistor 320 can also be used as transistors included in a variety of circuits such as an arithmetic circuit and a memory circuit.

Although the structure in which one transistor including an oxide semiconductor is stacked over the transistor 310 is described here, one embodiment of the present invention is not limited thereto. For example, a structure in which two or more transistors are stacked over the transistor 310 (for example, a structure in which the transistor 320A illustrated in FIG. 24 is provided over the transistor 310 and the transistor 320B is provided over the transistor 320A) may be employed.

With such a structure, not only the pixel circuit but also the driver circuit and the like can be formed directly under the light-emitting devices; thus, the display device can be downsized as compared with the case where a driver circuit is provided around a display region.

This embodiment can be combined with any of the other embodiments as appropriate.

### Embodiment 5

In this embodiment, light-emitting devices that can be used in the display device of one embodiment of the present invention will be described.

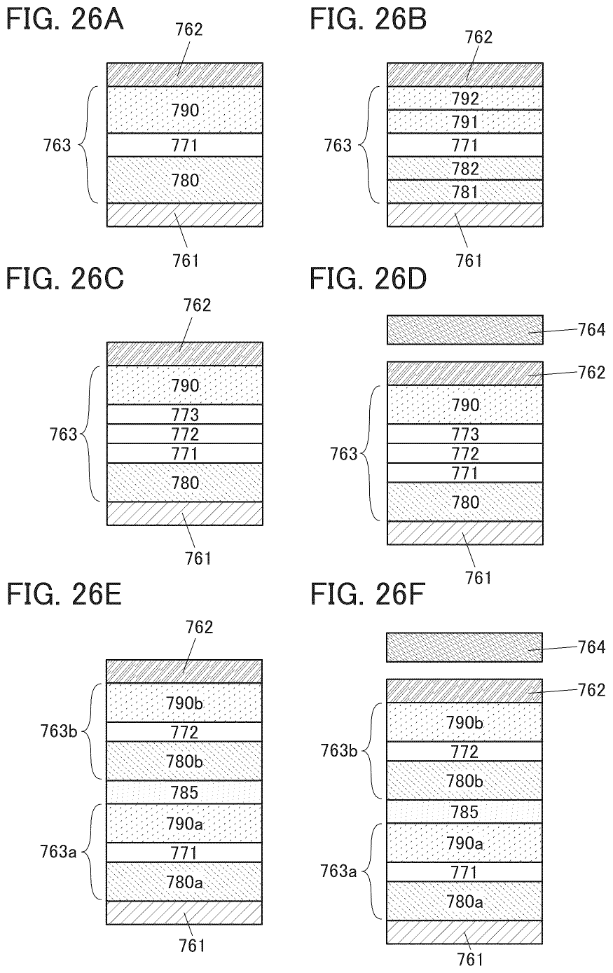

As illustrated in FIG. 26A, the light-emitting device includes an EL layer 763 between a pair of electrodes (a lower electrode 761 and an upper electrode 762). The EL layer 763 can be formed of a plurality of layers such as a layer 780, a light-emitting layer 771, and a layer 790.

The light-emitting layer 771 contains at least a light-emitting substance (also referred to as a light-emitting material).

In the case where the lower electrode 761 is an anode and the upper electrode 762 is a cathode, the layer 780 includes one or more of a layer containing a substance with a high hole-injection property (a hole-injection layer), a layer containing a substance with a high hole-transport property (a hole-transport layer), and a layer containing a substance with a high electron-blocking property (an electron-blocking layer). The layer 790 includes one or more of a layer containing a substance with a high electron-injection property (an electron-injection layer), a layer containing a substance with a high electron-transport property (an electron-transport layer), and a layer containing a substance with a high hole-blocking property (a hole-blocking layer). In the case where the lower electrode 761 is a cathode and the upper electrode 762 is an anode, the above structures of the layer 780 and the layer 790 are replaced with each other.

The structure including the layer 780, the light-emitting layer 771, and the layer 790, which is provided between the pair of electrodes, can function as a single light-emitting unit, and the structure in FIG. 26A is referred to as a single structure in this specification.

FIG. 26B is a variation example of the EL layer 763 included in the light-emitting device illustrated in FIG. 26A. Specifically, the light-emitting device illustrated in FIG. 26B includes a layer 781 over the lower electrode 761, a layer 782 over the layer 781, the light-emitting layer 771 over the layer 782, a layer 791 over the light-emitting layer 771, a layer 792 over the layer 791, and the upper electrode 762 over the layer 792.

In the case where the lower electrode 761 is an anode and the upper electrode 762 is a cathode, the layer 781 can be a hole-injection layer, the layer 782 can be a hole-transport layer, the layer 791 can be an electron-transport layer, and the layer 792 can be an electron-injection layer, for example. In the case where the lower electrode 761 is a cathode and the upper electrode 762 is an anode, the layer 781 can be an electron-injection layer, the layer 782 can be an electron-transport layer, the layer 791 can be a hole-transport layer, and the layer 792 can be a hole-injection layer. With such a layer structure, carriers can be efficiently injected to the light-emitting layer 771, and the efficiency of the recombination of carriers in the light-emitting layer 771 can be increased.

Note that structures in which a plurality of light-emitting layers (the light-emitting layer 771, a light-emitting layer 772, and a light-emitting layer 773) are provided between the layer 780 and the layer 790 as illustrated in FIG. 26C and FIG. 26D are variations of the single structure. Although FIG. 26C and FIG. 26D illustrate the examples where three light-emitting layers are included, the light-emitting device having a single structure may include two or four or more light-emitting layers. In addition, the light-emitting device having a single structure may include a buffer layer between two light-emitting layers. The buffer layer can be formed using a material that can be used for the hole-transport layer or the electron-transport layer, for example.

A structure in which a plurality of light-emitting units (a light-emitting unit 763a and a light-emitting unit 763b) are connected in series with a charge-generation layer 785 (also referred to as an intermediate layer) therebetween as illustrated in FIG. 26E and FIG. 26F is referred to as a tandem structure in this specification. Note that the tandem structure may be referred to as a stack structure. The tandem structure enables a light-emitting device capable of high-luminance light emission. Furthermore, the tandem structure allows the amount of current needed for obtaining the same luminance to be reduced as compared with a single structure, and thus can improve the reliability.

Note that FIG. 26D and FIG. 26F illustrate examples where the display device includes a layer 764 overlapping with the light-emitting device. FIG. 26D illustrates an example in which the layer 764 overlaps with the light-emitting device illustrated in FIG. 26C, and FIG. 26F illustrates an example in which the layer 764 overlaps with the light-emitting device illustrated in FIG. 26E. In FIG. 26D and FIG. 26F, a conductive film transmitting visible light is used for the upper electrode 762 to extract light to the upper electrode 762 side.

One or both of a color conversion layer and a color filter (coloring layer) can be used as the layer 764.

In FIG. 26C and FIG. 26D, light-emitting substances that emit light of the same color, or moreover, the same light-emitting substance may be used for the light-emitting layer 771, the light-emitting layer 772, and the light-emitting layer 773. For example, a light-emitting substance emitting blue light may be used for each of the light-emitting layer 771, the light-emitting layer 772, and the light-emitting layer 773. In a subpixel that emits blue light, blue light emitted from the light-emitting device can be extracted. In a subpixel that emits red light and a subpixel that emits green light, when a color conversion layer is provided as the layer 764 illustrated in FIG. 26D, blue light emitted from the light-emitting device can be converted into light having a longer wavelength and red or green light can be extracted. As the layer 764, both a color conversion layer and a coloring layer are preferably used. In some cases, part of light emitted from the light-emitting device is transmitted through the color conversion layer without being converted. When light transmitted through the color conversion layer is extracted through the coloring layer, the coloring layer absorbs light other than light of the intended color, and the color purity of light emitted from the subpixel can be improved.

In FIG. 26C and FIG. 26D, light-emitting substances that emit light of different colors may be used for the light-emitting layer 771, the light-emitting layer 772, and the light-emitting layer 773. In the case where the light-emitting layer 771, the light-emitting layer 772, and the light-emitting layer 773 emit light of complementary colors, white light emission can be obtained. The light-emitting element having a single structure preferably includes a light-emitting layer containing a light-emitting substance emitting blue light and a light-emitting layer containing a light-emitting substance emitting visible light having a longer wavelength than blue light, for example.

A color filter is preferably provided as the layer 764 illustrated in FIG. 26D. When white light passes through the color filter, light of a desired color can be obtained.

In the case where the light-emitting device having a single structure includes three light-emitting layers, for example, a light-emitting layer containing a light-emitting substance emitting red (R) light, a light-emitting layer containing a light-emitting substance emitting green (G) light, and a light-emitting layer containing a light-emitting substance emitting blue (B) light are preferably included. The stacking order of the light-emitting layers can be R, G, and B or R, B, and G from the anode side, for example. In that case, a buffer layer may be provided between R and G or between R and B.

For example, in the case where the light-emitting device having a single structure includes two light-emitting layers, a structure including the light-emitting device preferably includes a light-emitting layer containing a light-emitting substance emitting blue (B) light and a light-emitting layer containing a light-emitting substance emitting yellow (Y) light is preferable. Such a structure may be referred to as a BY single structure.

The light-emitting device emitting white light preferably contains two or more kinds of light-emitting substances. When white light emission is obtained using two light-emitting layers, light-emitting substances are selected such that emission colors of the two light-emitting layers are complementary colors. For example, when an emission color of a first light-emitting layer and an emission color of a second light-emitting layer are complementary colors, the light-emitting device can be configured to emit white light as a whole. In the case where three or more light-emitting layers are used to obtain white light emission, a light-emitting device is configured to emit white light as a whole by combining emission colors of the three or more light-emitting layers.

Also in FIG. 26C and FIG. 26D, the layer 780 and the layer 790 may each independently have a stacked-layer structure of two or more layers as illustrated in FIG. 26B.

In FIG. 26E and FIG. 26F, light-emitting substances that emit light of the same color, or moreover, the same light-emitting substance may be used for the light-emitting layer 771 and the light-emitting layer 772. For example, in light-emitting devices included in subpixels emitting light of different colors, a light-emitting substance emitting blue light may be used for each of the light-emitting layer 771 and the light-emitting layer 772. In a subpixel that emits red light and a subpixel that emits green light, when a color conversion layer is provided as the layer 764 illustrated in FIG. 26F, blue light emitted from the light-emitting device can be converted into light having a longer wavelength and red or green light can be extracted. As the layer 764, both a color conversion layer and a coloring layer are preferably used.

In FIG. 26E and FIG. 26F, light-emitting substances that emit light of different colors may be used for the light-emitting layer 771 and the light-emitting layer 772. In the case where the light-emitting layer 771 and the light-emitting layer 772 emit light of complementary colors, white light emission can be obtained. A color filter is preferably provided as the layer 764 illustrated in FIG. 26F. When white light passes through the color filter, light of a desired color can be obtained.

Although FIG. 26E and FIG. 26F illustrate examples where the light-emitting unit 763a includes one light-emitting layer 771 and the light-emitting unit 763b includes one light-emitting layer 772, one embodiment of the present invention is not limited thereto. Each of the light-emitting unit 763a and the light-emitting unit 763b may include two or more light-emitting layers.

Although FIG. 26E and FIG. 26F each illustrate the light-emitting device including two light-emitting units as an example, one embodiment of the present invention is not limited thereto. The light-emitting device may include three or more light-emitting units. Note that a structure including two light-emitting units and a structure including three light-emitting units may be referred to as a two-unit tandem structure and a three-unit tandem structure, respectively.

In FIG. 26E and FIG. 26F, the light-emitting unit 763a includes a layer 780a, the light-emitting layer 771, and a layer 790a, and the light-emitting unit 763b includes a layer 780b, the light-emitting layer 772, and a layer 790b.

In the case where the lower electrode 761 is an anode and the upper electrode 762 is a cathode, the layer 780a and the layer 780b each include one or more of a hole-injection layer, a hole-transport layer, and an electron-blocking layer. The layer 790a and the layer 790b each include one or more of an electron-injection layer, an electron-transport layer, and a hole-blocking layer. In the case where the lower electrode 761 is a cathode and the upper electrode 762 is an anode, the above structures of the layer 780a and the layer 790a are replaced with each other, and the above structures of the layer 780b and the layer 790b are also replaced with each other.

In the case where the lower electrode 761 is an anode and the upper electrode 762 is a cathode, for example, the layer 780a includes a hole-injection layer and a hole-transport layer over the hole-injection layer and may further include an electron-blocking layer over the hole-transport layer. The layer 790a includes an electron-transport layer and may further include a hole-blocking layer between the light-emitting layer 771 and the electron-transport layer. The layer 780b includes a hole-transport layer and may further include an electron-blocking layer over the hole-transport layer. The layer 790b includes an electron-transport layer and an electron-injection layer over the electron-transport layer and may further include a hole-blocking layer between the light-emitting layer 772 and the electron-transport layer. In the case where the lower electrode 761 is a cathode and the upper electrode 762 is an anode, for example, the layer 780a includes an electron-injection layer and an electron-transport layer over the electron-injection layer and may further include a hole-blocking layer over the electron-transport layer. The layer 790a includes a hole-transport layer and may further include an electron-blocking layer between the light-emitting layer 771 and the hole-transport layer. The layer 780b includes an electron-transport layer and may further include a hole-blocking layer over the electron-transport layer. The layer 790b includes a hole-transport layer and a hole-injection layer over the hole-transport layer and may further include an electron-blocking layer between the light-emitting layer 772 and the hole-transport layer.

In the case of manufacturing a light-emitting device having a tandem structure, two light-emitting units are stacked with the charge-generation layer 785 therebetween. The charge-generation layer 785 includes at least a charge-generation region. The charge-generation layer 785 has a function of injecting electrons into one of the two light-emitting units and injecting holes into the other when voltage is applied between the pair of electrodes.

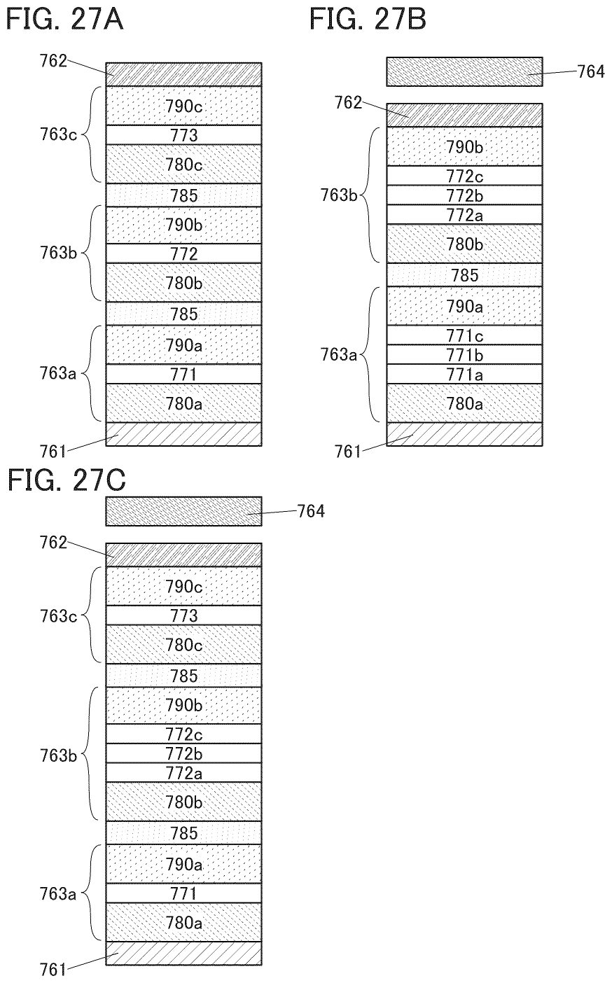

Structures illustrated in FIG. 27A to FIG. 27C can be given as examples of the light-emitting device having a tandem structure.

FIG. 27A illustrates a structure including three light-emitting units. In FIG. 27A, a plurality of light-emitting units (the light-emitting unit 763a, the light-emitting unit 763b, and a light-emitting unit 763c) are connected in series through the charge-generation layers 785. The light-emitting unit 763a includes the layer 780a, the light-emitting layer 771, and the layer 790a. The light-emitting unit 763b includes the layer 780b, the light-emitting layer 772, and the layer 790b. The light-emitting unit 763c includes a layer 780c, the light-emitting layer 773, and a layer 790c. Note that the layer 780c can have a structure applicable to the layer 780a and the layer 780b, and the layer 790c can have a structure applicable to the layer 790a and the layer 790b.

In FIG. 27A, the light-emitting layer 771, the light-emitting layer 772, and the light-emitting layer 773 can contain light-emitting substances that emit light of the same color. Specifically, the light-emitting layer 771, the light-emitting layer 772, and the light-emitting layer 773 can each have a structure containing a blue (B) light-emitting substance (what is called a three-unit tandem structure of B\B\B). Note that “a\b” means that a light-emitting unit containing a light-emitting substance emitting light of b is provided over a light-emitting unit containing a light-emitting substance emitting light of a with a charge-generation layer therebetween, where a and b represent colors.

In FIG. 27A, light-emitting substances that emit light of different colors can be used for some or all of the light-emitting layer 771, the light-emitting layer 772, and the light-emitting layer 773. Examples of a combination of emission colors for the light-emitting layer 771, the light-emitting layer 772, and the light-emitting layer 773 include blue (B) for two of them and yellow (Y) for the other; and red (R) for one of them, green (G) for another, and blue (B) for the other.

FIG. 27B illustrates a tandem light-emitting device in which light-emitting units each including a plurality of light-emitting layers are stacked. FIG. 27B illustrates a structure in which two light-emitting units (the light-emitting unit 763a and the light-emitting unit 763b) are connected in series with the charge-generation layer 785 therebetween. The light-emitting unit 763a includes the layer 780a, a light-emitting layer 771a, a light-emitting layer 771b, a light-emitting layer 771c, and the layer 790a. The light-emitting unit 763b includes the layer 780b, a light-emitting layer 772a, a light-emitting layer 772b, a light-emitting layer 772c, and the layer 790b.

In FIG. 27B, the light-emitting unit 763a is configured to emit white (W) light by selecting light-emitting substances for the light-emitting layer 771a, the light-emitting layer 771b, and the light-emitting layer 771c so that their emission colors are complementary colors. Furthermore, the light-emitting unit 763b is configured to emit white (W) light by selecting light-emitting substances for the light-emitting layer 772a, the light-emitting layer 772b, and the light-emitting layer 772c so that their emission colors are complementary colors. That is, the structure illustrated in FIG. 27B is a WWW two-unit tandem structure. Note that there is no particular limitation on the stacking order of the light-emitting substances that emit light of complementary colors. The practitioner can select the optimal stacking order as appropriate. Although not illustrated, a W\W\W\W three-unit tandem structure or a tandem structure with four or more units may be employed.

Other examples of the structure of a light-emitting device having a tandem structure include: a B\Y or Y\B two-unit tandem structure including a light-emitting unit that emits yellow (Y) light and a light-emitting unit that emits blue (B) light; an R·G\B or B\R·G two-unit tandem structure including a light-emitting unit that emits red (R) light and green (G) light and a light-emitting unit that emits blue (B) light; a B\Y\B three-unit tandem structure including a light-emitting unit that emits blue (B) light, a light-emitting unit that emits yellow (Y) light, and a light-emitting unit that emits blue (B) light in this order; a B\Y\G\B three-unit tandem structure including a light-emitting unit that emits blue (B) light, a light-emitting unit that emits yellowish green (YG) light, and a light-emitting unit that emits blue (B) light in this order; and a B\G\B three-unit tandem structure including a light-emitting unit that emits blue (B) light, a light-emitting unit that emits green (G) light, and a light-emitting unit that emits blue (B) light in this order. Note that “a·b” means that one light-emitting unit contains a light-emitting substance emitting light of a and a light-emitting substance emitting light of b.

As illustrated in FIG. 27C, a light-emitting unit including one light-emitting layer and a light-emitting unit including a plurality of light-emitting layers may be combined.

Specifically, in the structure illustrated in FIG. 27C, a plurality of light-emitting units (the light-emitting unit 763a, the light-emitting unit 763b, and the light-emitting unit 763c) are connected in series through the charge-generation layers 785. The light-emitting unit 763a includes the layer 780a, the light-emitting layer 771, and the layer 790a. The light-emitting unit 763b includes the layer 780b, the light-emitting layer 772a, the light-emitting layer 772b, the light-emitting layer 772c, and the layer 790b. The light-emitting unit 763c includes the layer 780c, the light-emitting layer 773, and the layer 790c.

As the structure illustrated in FIG. 27C, for example, a B\R·G·YG\B three-unit tandem structure in which the light-emitting unit 763a is a light-emitting unit that emits blue (B) light, the light-emitting unit 763b is a light-emitting unit that emits red (R), green (G), and yellow-green (YG) light, and the light-emitting unit 763c is a light-emitting unit that emits blue (B) light can be employed.

Examples of the number of stacked light-emitting units and the order of colors from the anode side include a two-unit structure of B and Y, a two-unit structure of B and a light-emitting unit X, a three-unit structure of B, Y, and B, and a three-unit structure of B, X, and B. Examples of the number of light-emitting layers stacked in the light-emitting unit X and the order of colors from the anode side include a two-layer structure of R and Y, a two-layer structure of R and G, a two-layer structure of G and R, a three-layer structure of G, R, and G, and a three-layer structure of R, G, and R. Another layer may be provided between two light-emitting layers.

Next, materials that can be used for the light-emitting device will be described.

A conductive film transmitting visible light is used as the electrode through which light is extracted, which is either the lower electrode 761 or the upper electrode 762. A conductive film reflecting visible light is preferably used as the electrode through which light is not extracted. In the case where a display device includes a light-emitting device emitting infrared light, a conductive film transmitting visible light and infrared light is preferably used as the electrode through which light is extracted, and a conductive film reflecting visible light and infrared light is preferably used as the electrode through which light is not extracted.

A conductive film transmitting visible light may be used also as the electrode through which light is not extracted. In that case, the electrode is preferably provided between the reflective layer and the EL layer 763. In other words, light emitted from the EL layer 763 may be reflected by the reflective layer to be extracted from the display device.

For each of the lower electrode 761 and the upper electrode 762, the material that can be used for the pair of electrodes of the light-emitting device described in Embodiment 1 can be used.

The light-emitting device includes at least a light-emitting layer. The light-emitting device may further include, as a layer other than the light-emitting layer, a layer containing a substance with a high hole-injection property, a substance with a high hole-transport property, a hole-blocking material, a substance with a high electron-transport property, an electron-blocking material, a substance with a high electron-injection property, a substance with a bipolar property (also referred to as a substance with a high electron-transport property and a high hole-transport property or a bipolar material), or the like. For example, the light-emitting device can include one or more of a hole-injection layer, a hole-transport layer, a hole-blocking layer, a charge-generation layer, an electron-blocking layer, an electron-transport layer, and an electron-injection layer in addition to the light-emitting layer.

Either a low molecular compound or a high molecular compound can be used in the light-emitting device, and an inorganic compound may also be contained. Each layer included in the light-emitting device can be formed by a method such as an evaporation method (including a vacuum evaporation method), a transfer method, a printing method, an inkjet method, or a coating method.

The light-emitting layer contains one or more kinds of light-emitting substances. As the light-emitting substance, a substance that exhibits an emission color of blue, violet, bluish violet, green, yellowish green, yellow, orange, red, or the like is used as appropriate. Alternatively, as the light-emitting substance, a substance emitting near-infrared light can be used.

Examples of the light-emitting substance include a fluorescent material, a phosphorescent material, a TADF material, and a quantum dot material.

Examples of the fluorescent material include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative.

Examples of the phosphorescent material include an organometallic complex (particularly an iridium complex) having a 4H-triazole skeleton, a 1H-triazole skeleton, an imidazole skeleton, a pyrimidine skeleton, a pyrazine skeleton, or a pyridine skeleton; an organometallic complex (particularly an iridium complex) having a phenylpyridine derivative including an electron-withdrawing group as a ligand; a platinum complex; and a rare earth metal complex.

The light-emitting layer may contain one or more kinds of organic compounds (a host material, an assist material, and the like) in addition to the light-emitting substance (a guest material). As one or more kinds of organic compounds, one or both of a substance with a high hole-transport property (a hole-transport material) and a substance with a high electron-transport property (an electron-transport material) can be used. As the hole-transport material, it is possible to use a substance with a high hole-transport property that can be used for the hole-transport layer and will be described later. As the electron-transport material, it is possible to use a substance with a high electron-transport property that can be used for the electron-transport layer and will be described later. Alternatively, as one or more kinds of organic compounds, a bipolar material or a TADF material may be used.

The light-emitting layer preferably includes, for example, a phosphorescent material and a combination of a hole-transport material and an electron-transport material that easily forms an exciplex. With such a structure, light emission can be efficiently obtained by ExTET (Exciplex-Triplet Energy Transfer), which is energy transfer from an exciplex to a light-emitting substance (a phosphorescent material). When a combination is selected so as to form an exciplex that exhibits light emission whose wavelength overlaps with the wavelength of a lowest-energy-side absorption band of the light-emitting substance, energy can be transferred smoothly and light emission can be obtained efficiently. With the above structure, high efficiency, low-voltage driving, and a long lifetime of a light-emitting device can be achieved at the same time.

The hole-injection layer is a layer that injects holes from an anode to the hole-transport layer and contains a substance with a high hole-injection property. Examples of the substance with a high hole-injection property include an aromatic amine compound and a composite material containing a hole-transport material and an acceptor material (electron-accepting material).

As the hole-transport material, it is possible to use a substance with a high hole-transport property that can be used for the hole-transport layer and will be described later.

As the acceptor material, an oxide of a metal belonging to any of Group 4 to Group 8 of the periodic table can be used, for example. Specific examples include molybdenum oxide, vanadium oxide, niobium oxide, tantalum oxide, chromium oxide, tungsten oxide, manganese oxide, and rhenium oxide. Among these, molybdenum oxide is especially preferable because it is stable in the air, has a low hygroscopic property, and is easy to handle. An organic acceptor material containing fluorine can also be used. An organic acceptor material such as a quinodimethane derivative, a chloranil derivative, or a hexaazatriphenylene derivative can also be used.

As the substance with a high hole-injection property, a material that contains a hole-transport material and the above-described oxide of a metal belonging to Group 4 to Group 8 of the periodic table (typically, molybdenum oxide) may be used, for example.

The hole-transport layer is a layer transporting holes, which are injected from the anode by the hole-injection layer, to a light-emitting layer. The hole-transport layer is a layer that contains a hole-transport material. As the hole-transport material, a substance having a hole mobility greater than or equal to 1×10⁻⁶ cm²/Vs is preferable. Note that other substances can also be used as long as they have a property of transporting more holes than electrons. As the hole-transport material, substances with a high hole-transport property, such as a T-electron rich heteroaromatic compound (e.g., a carbazole derivative, a thiophene derivative, and a furan derivative) and an aromatic amine (a compound having an aromatic amine skeleton), are preferable.

The electron-blocking layer is provided in contact with the light-emitting layer. The electron-blocking layer has a hole-transport property and contains a material capable of blocking electrons. Any of the materials having an electron-blocking property among the above hole-transport materials can be used for the electron-blocking layer.

The electron-blocking layer has a hole-transport property and thus can also be referred to as a hole-transport layer. A layer having an electron-blocking property among the hole-transport layers can also be referred to as an electron-blocking layer.

The electron-transport layer is a layer transporting electrons, which are injected from the cathode by the electron-injection layer, to the light-emitting layer. The electron-transport layer is a layer that contains an electron-transport material. As the electron-transport material, a substance having an electron mobility greater than or equal to 1×10⁻⁶ cm²/Vs is preferable. Note that other substances can also be used as long as they have a property of transporting more electrons than holes. As the electron-transport material, it is possible to use a substance with a high electron-transport property, such as a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, or a π-electron deficient heteroaromatic compound such as a nitrogen-containing heteroaromatic compound.

The hole-blocking layer is provided in contact with the light-emitting layer. The hole-blocking layer has an electron-transport property and contains a material capable of blocking holes. Any of the materials having a hole-blocking property among the above electron-transport materials can be used for the hole-blocking layer.

The hole-blocking layer has an electron-transport property and thus can also be referred to as an electron-transport layer. A layer having a hole-blocking property among the electron-transport layers can also be referred to as a hole-blocking layer.

The electron-injection layer is a layer that injects electrons from the cathode to the electron-transport layer and contains a substance with a high electron-injection property. As the substance with a high electron-injection property, an alkali metal, an alkaline earth metal, or a compound thereof can be used. As the substance with a high electron-injection property, a composite material containing an electron-transport material and a donor material (electron-donating material) can also be used.

The difference between the LUMO level of the substance with a high electron-injection property and the work function value of the material used for the cathode is preferably small (specifically, smaller than or equal to 0.5 eV).

The electron-injection layer can be formed using an alkali metal, an alkaline earth metal, or a compound thereof, such as lithium, cesium, ytterbium, lithium fluoride (LiF), cesium fluoride (CsF), calcium fluoride (CaFₓ, where x is a given number), 8-(quinolinolato) lithium (abbreviation: Liq), 2-(2-pyridyl) phenolatolithium (abbreviation: LiPP), 2-(2-pyridyl)-3-pyridinolato lithium (abbreviation: LiPPy), 4-phenyl-2-(2-pyridyl) phenolatolithium (abbreviation: LiPPP), lithium oxide (LiOₓ), or cesium carbonate, for example. The electron-injection layer may have a stacked-layer structure of two or more layers. The stacked-layer structure can be, for example, a structure in which lithium fluoride is used for the first layer and ytterbium is provided for the second layer.

The electron-injection layer may contain an electron-transport material. For example, a compound having an unshared electron pair and an electron deficient heteroaromatic ring can be used as the electron-transport material. Specifically, it is possible to use a compound having at least one of a pyridine ring, a diazine ring (a pyrimidine ring, a pyrazine ring, or a pyridazine ring), and a triazine ring.

Note that the lowest unoccupied molecular orbital (LUMO) level of the organic compound having an unshared electron pair is preferably greater than or equal to-3.6 eV and less than or equal to-2.3 eV. In general, the highest occupied molecular orbital (HOMO) level and the LUMO level of an organic compound can be estimated by CV (cyclic voltammetry), photoelectron spectroscopy, optical absorption spectroscopy, inverse photoelectron spectroscopy, or the like.

For example, 4,7-diphenyl-1,10-phenanthroline (abbreviation: BPhen), 2,9-di (naphthalen-2-yl)-4,7-diphenyl-1,10-phenanthroline (abbreviation: NBPhen), 2,2′-(1,3-phenylene) bis(9-phenyl-1,10-phenanthroline) (abbreviation: mPPhen2P), diquinoxalino [2,3-a: 2′, 3′-c] phenazine (abbreviation: HATNA), 2,4,6-tris [3′-(pyridin-3-yl) biphenyl-3-yl]-1,3,5-triazine (abbreviation: TmPPPyTz), or the like can be used as the organic compound having an unshared electron pair. Note that NBPhen has a higher glass transition point (Tg) than BPhen and thus has high heat resistance.

As described above, the charge-generation layer includes at least a charge-generation region. The charge-generation region preferably contains an acceptor material, and for example, preferably contains a hole-transport material and an acceptor material which can be used for the above-described hole-injection layer.

The charge-generation layer preferably includes a layer containing a substance with a high electron-injection property. The layer can also be referred to as an electron-injection buffer layer. The electron-injection buffer layer is preferably provided between the charge-generation region and the electron-transport layer. By provision of the electron-injection buffer layer, an injection barrier between the charge-generation region and the electron-transport layer can be lowered; thus, electrons generated in the charge-generation region can be easily injected into the electron-transport layer.

The electron-injection buffer layer preferably contains an alkali metal or an alkaline earth metal, and for example, can contain an alkali metal compound or an alkaline earth metal compound. Specifically, the electron-injection buffer layer preferably contains an inorganic compound containing an alkali metal and oxygen or an inorganic compound containing an alkaline earth metal and oxygen, further preferably contains an inorganic compound containing lithium and oxygen (e.g., lithium oxide (Li₂O)). Alternatively, a material that can be used for the electron-injection layer can be suitably used for the electron-injection buffer layer.

The charge-generation layer preferably includes a layer containing a substance with a high electron-transport property. The layer can also be referred to as an electron-relay layer. The electron-relay layer is preferably provided between the charge-generation region and the electron-injection buffer layer. In the case where the charge-generation layer does not include an electron-injection buffer layer, the electron-relay layer is preferably provided between the charge-generation region and the electron-transport layer. The electron-relay layer has a function of preventing interaction between the charge-generation region and the electron-injection buffer layer (or the electron-transport layer) and smoothly transferring electrons.

A phthalocyanine-based material such as copper (II) phthalocyanine (abbreviation: CuPc) or a metal complex having a metal-oxygen bond and an aromatic ligand is preferably used for the electron-relay layer.

Note that the charge-generation region, the electron-injection buffer layer, and the electron-relay layer cannot be clearly distinguished from one another in some cases on the basis of the cross-sectional shapes, the characteristics, or the like.

Note that the charge-generation layer may contain a donor material instead of an acceptor material. For example, the charge-generation layer may include a layer containing an electron-transport material and a donor material, which can be used for the electron-injection layer.

When two light-emitting units are stacked, provision of the charge-generation layer between the light-emitting units can suppress an increase in driving voltage.

This embodiment can be combined with any of the other embodiments as appropriate.

### Embodiment 6

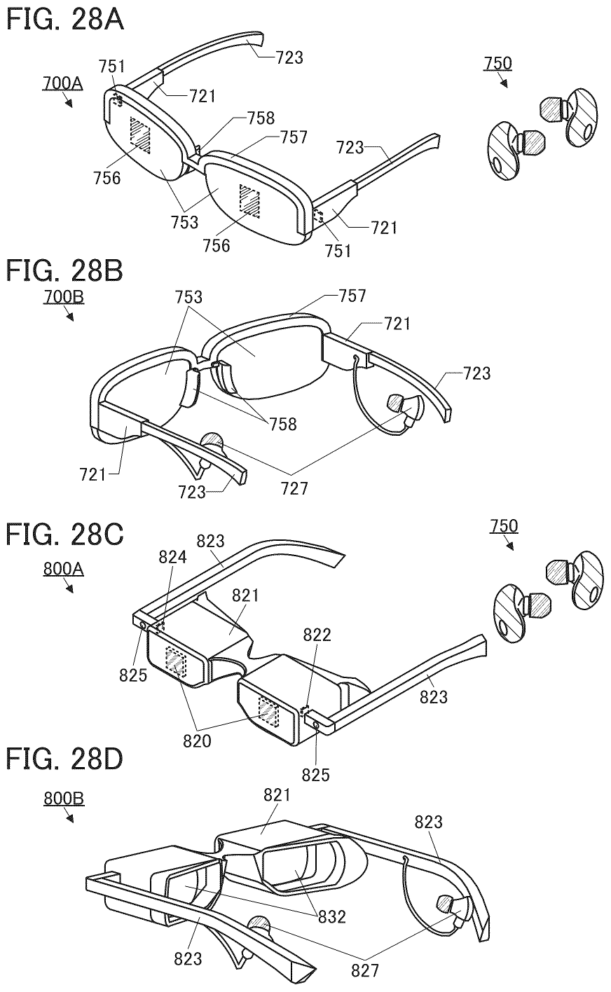

In this embodiment, electronic devices of one embodiment of the present invention will be described with reference to FIG. 28 to FIG. 30.

Electronic devices of this embodiment each include the display device of one embodiment of the present invention in a display portion. The display device of one embodiment of the present invention can be easily increased in resolution and definition. Thus, the display device of one embodiment of the present invention can be used for a display portion of a variety of electronic devices.

Examples of the electronic devices include a digital camera, a digital video camera, a digital photo frame, a mobile phone, a portable game console, a portable information terminal, and an audio reproducing device, in addition to electronic devices with a relatively large screen, such as a television device, a desktop or laptop personal computer, a monitor of a computer or the like, digital signage, and a large game machine such as a pachinko machine.

In particular, the display device of one embodiment of the present invention can have high resolution and thus can be suitably used for an electronic device including a relatively small display portion. Examples of such an electronic device include watch-type and bracelet-type information terminals (wearable devices) and wearable devices that can be worn on the head, such as a VR device like a head-mounted display, a glasses-type AR device, and an MR device.

The definition of the display device of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, the definition is preferably 4K, 8K, or higher. The pixel density (resolution) of the display device of one embodiment of the present invention is preferably higher than or equal to 100 ppi, further preferably higher than or equal to 300 ppi, still further preferably higher than or equal to 500 ppi, still further preferably higher than or equal to 1000 ppi, still further preferably higher than or equal to 2000 ppi, still further preferably higher than or equal to 3000 ppi, still further preferably higher than or equal to 5000 ppi, yet further preferably higher than or equal to 7000 ppi. The use of the display device having one or both of such high definition and high resolution can further increase realistic sensation, sense of depth, and the like. There is no particular limitation on the screen ratio (aspect ratio) of the display device of one embodiment of the present invention. For example, the display device is compatible with a variety of screen ratios such as 1:1 (square), 4:3, 16:9, and 16:10.

The electronic device of this embodiment may include a sensor (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, smell, or infrared rays).

The electronic device of this embodiment can have a variety of functions. For example, the electronic device can have a function of displaying a variety of information (e.g., a still image, a moving image, and a text image) on the display portion, a touch panel function, a function of displaying a calendar, date, time, and the like, a function of executing a variety of software (programs), a wireless communication function, and a function of reading out a program or data stored in a recording medium.

Examples of wearable devices that can be worn on the head are described with reference to FIG. 28A to FIG. 28D. The wearable devices have at least one of a function of displaying AR contents, a function of displaying VR contents, a function of displaying SR contents, and a function of displaying MR contents. The electronic device having a function of displaying contents of at least one of AR, VR, SR, MR, and the like enables a user to feel a higher sense of immersion.

An electronic device 700A illustrated in FIG. 28A and an electronic device 700B illustrated in FIG. 28B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display device of one embodiment of the present invention can be used for the display panels 751. Thus, the electronic device can perform display with extremely high resolution.

The electronic device 700A and the electronic device 700B can each project images displayed on the display panels 751 onto display regions 756 of the optical members 753. Since the optical members 753 have a light-transmitting property, the user can see images displayed on the display regions, which are superimposed on transmission images seen through the optical members 753. Accordingly, the electronic device 700A and the electronic device 700B are electronic devices capable of AR display.

In each of the electronic device 700A and the electronic device 700B, a camera capable of capturing images of the front side may be provided as the image capturing portion. Furthermore, when the electronic device 700A and the electronic device 700B are each provided with an acceleration sensor such as a gyroscope sensor, the orientation of the user's head can be sensed and an image corresponding to the orientation can be displayed on the display regions 756.

The communication portion includes a wireless communication device, and a video signal and the like can be supplied by the wireless communication device. Instead of or in addition to the wireless communication device, a connector that can be connected to a cable for supplying a video signal and a power supply potential may be provided.

The electronic device 700A and the electronic device 700B are provided with a battery so that they can be charged wirelessly and/or by wire.

A touch sensor module may be provided in the housing 721. The touch sensor module has a function of detecting a touch on the outer surface of the housing 721. Detecting a tap operation, a slide operation, or the like by the user with the touch sensor module enables various types of processing to be executed. For example, processing such as a pause or a restart of a moving image can be executed by a tap operation, and processing such as fast forward and fast rewind can be executed by a slide operation. When the touch sensor module is provided in each of the two housings 721, the range of the operation can be increased.

Various touch sensors can be applied to the touch sensor module. For example, any of touch sensors of various types such as a capacitive type, a resistive type, an infrared type, an electromagnetic induction type, a surface acoustic wave type, and an optical type can be employed. In particular, a capacitive sensor or an optical sensor is preferably used for the touch sensor module.

In the case of using an optical touch sensor, a photoelectric conversion device (also referred to as a photoelectric conversion element) can be used as a light-receiving device. One or both of an inorganic semiconductor and an organic semiconductor can be used for an active layer of the photoelectric conversion device.

An electronic device 800A illustrated in FIG. 28C and an electronic device 800B illustrated in FIG. 28D each include a pair of display portions 820, a housing 821, a communication portion 822, a pair of wearing portions 823, a control portion 824, a pair of image capturing portions 825, and a pair of lenses 832.

The display device of one embodiment of the present invention can be used in the display portions 820. Thus, the electronic device with extremely high resolution can be achieved. This enables a user to feel a high sense of immersion.

The display portions 820 are positioned inside the housing 821 so as to be seen through the lenses 832. When the pair of display portions 820 display different images, three-dimensional display using parallax can be performed.

The electronic device 800A and the electronic device 800B can be regarded as electronic devices for VR. The user who wears the electronic device 800A or the electronic device 800B can see images displayed on the display portions 820 through the lenses 832.

The electronic device 800A and the electronic device 800B each preferably include a mechanism for adjusting the lateral positions of the lenses 832 and the display portions 820 so that the lenses 832 and the display portions 820 are positioned optimally in accordance with the positions of the user's eyes. Moreover, the electronic device 800A and the electronic device 800B each preferably include a mechanism for adjusting focus by changing the distance between the lenses 832 and the display portions 820.

The electronic device 800A or the electronic device 800B can be worn on the user's head with the wearing portions 823. FIG. 28C and the like illustrate examples where the wearing portion 823 has a shape like a temple of glasses; however, one embodiment of the present invention is not limited thereto. The wearing portion 823 can have any shape with which the user can wear the electronic device, for example, a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to support a plurality of fields of view, such as a telescope field of view and a wide field of view.

Note that although an example in which the image capturing portion 825 is provided is described here, a range sensor (hereinafter, also referred to as a sensing portion) that is capable of measuring a distance from an object is provided. In other words, the image capturing portion 825 is one embodiment of the sensing portion. As the sensing portion, an image sensor or a range image sensor such as LIDAR (Light Detection and Ranging) can be used, for example. By using images obtained by the camera and images obtained by the range image sensor, more information can be obtained and a gesture operation with higher accuracy is possible.

The electronic device 800A may include a vibration mechanism that functions as bone-conduction earphones. For example, any one or more of the display portion 820, the housing 821, and the wearing portion 823 can employ a structure including the vibration mechanism. Thus, without additionally requiring an audio device such as headphones, earphones, or a speaker, the user can enjoy video and sound only by wearing the electronic device 800A.

The electronic device 800A and the electronic device 800B may each include an input terminal. To the input terminal, a cable for supplying a video signal from a video output device or the like, electric power for charging a battery provided in the electronic device, and the like can be connected.

The electronic device of one embodiment of the present invention may have a function of performing wireless communication with earphones 750. The earphones 750 include a communication portion (not illustrated) and have a wireless communication function. The earphones 750 can receive information (e.g., audio data) from the electronic device with the wireless communication function. For example, the electronic device 700A illustrated in FIG. 28A has a function of transmitting information to the earphones 750 with the wireless communication function. As another example, the electronic device 800A illustrated in FIG. 28C has a function of transmitting information to the earphones 750 with the wireless communication function.

The electronic device may include an earphone portion. The electronic device 700B illustrated in FIG. 28B includes earphone portions 727. For example, the earphone portion 727 can be connected to the control portion by wire. Part of a wiring that connects the earphone portion 727 and the control portion may be positioned inside the housing 721 or the wearing portion 723.

Similarly, the electronic device 800B illustrated in FIG. 28D includes earphone portions 827. For example, the earphone portion 827 can be connected to the control portion 824 by wire. Part of a wiring that connects the earphone portion 827 and the control portion 824 may be positioned inside the housing 821 or the wearing portion 823. The earphone portions 827 and the wearing portions 823 may include magnets. This structure is preferably employed, in which case the earphone portions 827 can be fixed to the wearing portions 823 with magnetic force and thus can be easily housed.

The electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of what is called a headset by including the audio input mechanism.

As described above, both the glasses-type device (e.g., the electronic device 700A and the electronic device 700B) and the goggles-type device (e.g., the electronic device 800A and the electronic device 800B) are preferable as the electronic device of one embodiment of the present invention.

The electronic device of one embodiment of the present invention can transmit information to earphones by wire or wirelessly.

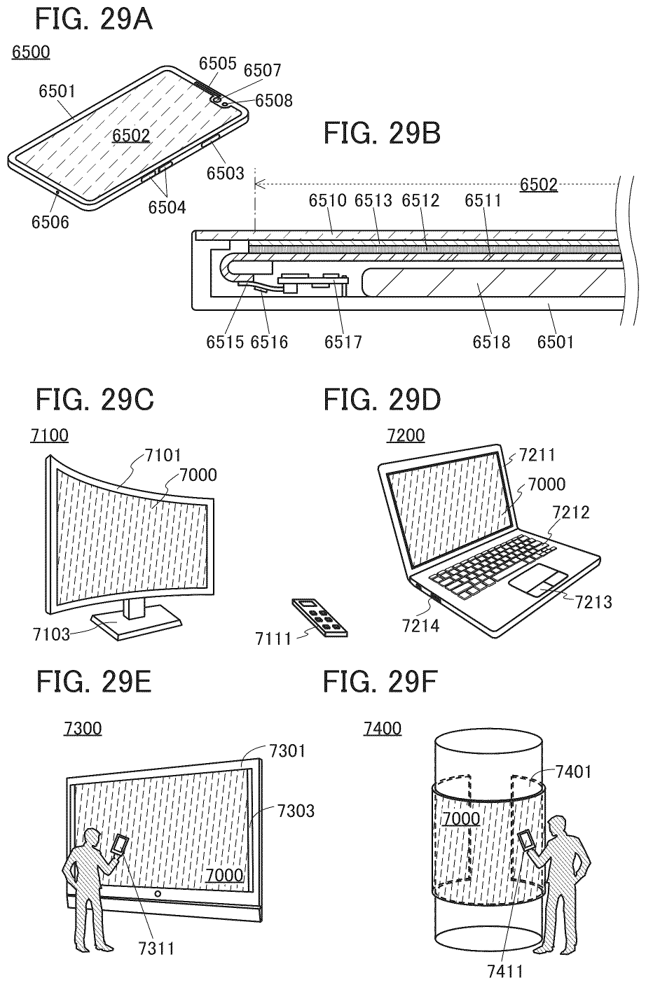

An electronic device 6500 illustrated in FIG. 29A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display device of one embodiment of the present invention can be used in the display portion 6502.

FIG. 29B is a schematic cross-sectional view including an end portion of the housing 6501 on the microphone 6506 side.

A protection member 6510 having a light-transmitting property is provided on the display surface side of the housing 6501, and a display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

The flexible display of one embodiment of the present invention can be used for the display panel 6511. Thus, an extremely lightweight electronic device can be achieved. Since the display panel 6511 is extremely thin, the battery 6518 with high capacity can be mounted while the thickness of the electronic device is reduced. Moreover, part of the display panel 6511 is folded back so that a connection portion with the FPC 6515 is provided on the back side of a pixel portion, whereby an electronic device with a narrow bezel can be obtained.

FIG. 29C illustrates an example of a television device. In a television device 7100, a display portion 7000 is incorporated in a housing 7101. Here, the housing 7101 is supported by a stand 7103.

The display device of one embodiment of the present invention can be used in the display portion 7000.

Operation of the television device 7100 illustrated in FIG. 29C can be performed with an operation switch provided in the housing 7101 and a separate remote control 7111. Alternatively, the display portion 7000 may include a touch sensor, and the television device 7100 may be operated by touch on the display portion 7000 with a finger or the like. The remote control 7111 may be provided with a display portion for displaying information output from the remote control 7111. With operation keys or a touch panel provided in the remote control 7111, channels and volume can be controlled and videos displayed on the display portion 7000 can be operated.

Note that the television device 7100 has a structure in which a receiver, a modem, and the like are provided. A general television broadcast can be received with the receiver. In addition, when the television device is connected to a communication network with or without wires via the modem, one-way (from a sender to a receiver) or two-way (between a sender and a receiver or between receivers) data communication can be performed.

FIG. 29D illustrates an example of a laptop personal computer. A laptop personal computer 7200 includes a housing 7211, a keyboard 7212, a pointing device 7213, an external connection port 7214, and the like. In the housing 7211, the display portion 7000 is incorporated.

The display device of one embodiment of the present invention can be used in the display portion 7000.

FIG. 29E and FIG. 29F illustrate examples of digital signage.

Digital signage 7300 illustrated in FIG. 29E includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 29F illustrates digital signage 7400 attached to a cylindrical pillar 7401. The digital signage 7400 includes the display portion 7000 provided along a curved surface of the pillar 7401.

The display device of one embodiment of the present invention can be used in the display portion 7000 in each of FIG. 29E and FIG. 29F.

A larger area of the display portion 7000 can increase the amount of information that can be provided at a time. The larger display portion 7000 attracts more attention, so that the effectiveness of the advertisement can be increased, for example.

A touch panel is preferably used in the display portion 7000, in which case intuitive operation by a user is possible in addition to display of an image or a moving image on the display portion 7000. Moreover, for an application for providing information such as route information or traffic information, usability can be enhanced by intuitive operation.

As illustrated in FIG. 29E and FIG. 29F, it is preferable that the digital signage 7300 or the digital signage 7400 can work with an information terminal 7311 or an information terminal 7411 such as a smartphone a user has through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with use of the screen of the information terminal 7311 or the information terminal 7411 as an operation means (controller). Thus, an unspecified number of users can join in and enjoy the game concurrently.

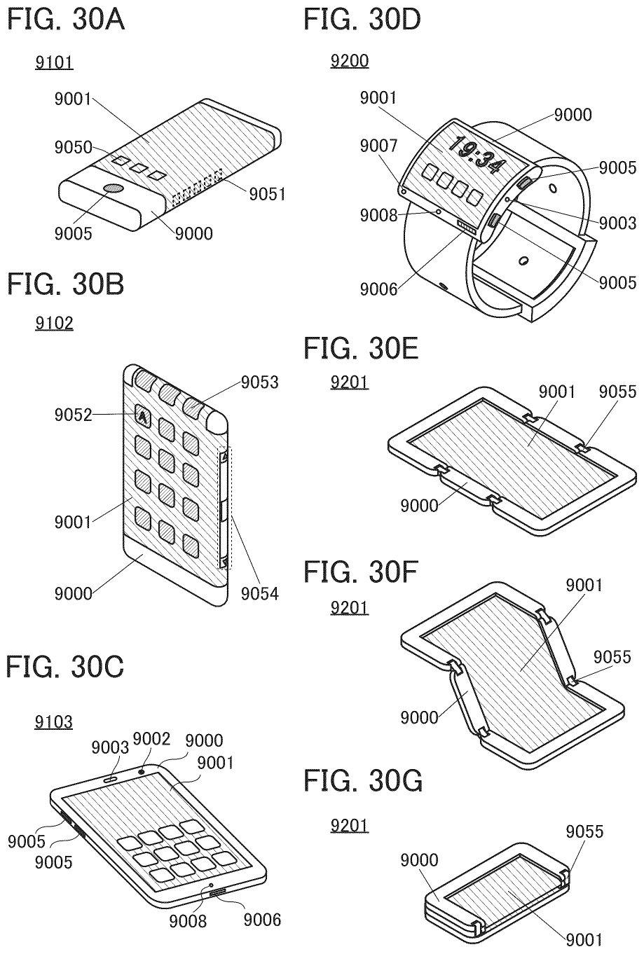

Electronic devices illustrated in FIG. 30A to FIG. 30G each include a housing 9000, a display portion 9001, a speaker 9003, an operation key 9005 (including a power switch or an operation switch), a connection terminal 9006, a sensor 9007 (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, smell, or infrared rays), a microphone 9008, and the like.

In FIG. 30A to FIG. 30G, the display device of one embodiment of the present invention can be used in the display portion 9001.

The electronic devices illustrated in FIG. 30A to FIG. 30G have a variety of functions. For example, the electronic devices can have a function of displaying a variety of data (a still image, a moving image, a text image, and the like) on the display portion, a touch panel function, a function of displaying a calendar, date, time, and the like, a function of controlling processing with the use of a variety of software (programs), a wireless communication function, and a function of reading out and processing a program or data stored in a recording medium. Note that the functions of the electronic devices are not limited thereto, and the electronic devices can have a variety of functions. The electronic devices may each include a plurality of display portions. The electronic devices may each include a camera or the like and have a function of taking a still image or a moving image and storing the taken image in a recording medium (an external recording medium or a recording medium incorporated in the camera), a function of displaying the taken image on the display portion, or the like.

The electronic devices illustrated in FIG. 30A to FIG. 30G will be described in detail below.

FIG. 30A is a perspective view showing a portable information terminal 9101. For example, the portable information terminal 9101 can be used as a smartphone. Note that the portable information terminal 9101 may be provided with the speaker 9003, the connection terminal 9006, the sensor 9007, or the like. The portable information terminal 9101 can display letters and image information on its plurality of surfaces. FIG. 30A illustrates an example in which three icons 9050 are displayed. Information 9051 indicated by dashed rectangles can be displayed on another surface of the display portion 9001. Examples of the information 9051 include notification of reception of an e-mail, an SNS, or an incoming call, the title and sender of an e-mail, an SNS, or the like, the date, the time, remaining battery, and the radio field intensity. Alternatively, the icon 9050 or the like may be displayed in the position where the information 9051 is displayed.

FIG. 30B is a perspective view illustrating a portable information terminal 9102. The portable information terminal 9102 has a function of displaying information on three or more surfaces of the display portion 9001. Here, an example in which information 9052, information 9053, and information 9054 are displayed on different surfaces is illustrated. For example, the user can check the information 9053 displayed in a position that can be observed from above the portable information terminal 9102, with the portable information terminal 9102 put in a breast pocket of his/her clothes. The user can see the display without taking out the portable information terminal 9102 from the pocket and decide whether to answer the call, for example.

FIG. 30C is a perspective view of a tablet terminal 9103. The tablet terminal 9103 is capable of executing a variety of applications such as mobile phone calls, e-mailing, viewing and editing texts, music reproduction, Internet communication, and a computer game. The tablet terminal 9103 includes the display portion 9001, the camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 30D is a perspective view illustrating a watch-type portable information terminal 9200. The portable information terminal 9200 can be used as a smartwatch (registered trademark), for example. The display surface of the display portion 9001 is curved, and an image can be displayed on the curved display surface. Furthermore, intercommunication between the portable information terminal 9200 and, for example, a headset capable of wireless communication enables hands-free calling. With the connection terminal 9006, the portable information terminal 9200 can perform mutual data transmission with another information terminal and can be charged. Note that the charging operation may be performed by wireless power feeding.

FIG. 30E to FIG. 30G are perspective views illustrating a foldable portable information terminal 9201. FIG. 30E is a perspective view of an opened state of the portable information terminal 9201, FIG. 30G is a perspective view of a folded state thereof, and FIG. 30F is a perspective view of a state in the middle of change from one of FIG. 30E and FIG. 30G to the other. The portable information terminal 9201 is highly portable in the folded state and is highly browsable in the opened state because of a seamless large display region. The display portion 9001 of the portable information terminal 9201 is supported by three housings 9000 joined by hinges 9055. For example, the display portion 9001 can be folded with a radius of curvature greater than or equal to 0.1 mm and less than or equal to 150 mm.

This embodiment can be combined with any of the other embodiments as appropriate.

### REFERENCE NUMERALS

11B: pixel electrode, 11G: pixel electrode, 11R: pixel electrode, 100A: display device, 100B: display device, 100C: display device, 100D: display device, 100E: display device, 100F: display device, 101: layer, 102a: insulating layer, 102b: insulating layer, 102c: insulating layer, 102: insulating layer, 103: plug, 104: sidewall insulating layer, 110a: pixel electrode, 110b: pixel electrode, 110c: pixel electrode, 110d: pixel electrode, 110: pixel, 111A: pixel electrode, 111a: pixel electrode, 111c: pixel electrode, 111b: pixel electrode, 111C: pixel electrode, 111c: pixel electrode, 111: pixel electrode, 113s: material layer, 113: first layer, 114: common layer, 115: common electrode, 116B: optical adjustment layer, 116G: optical adjustment layer, 116R: optical adjustment layer, 120: substrate, 122: resin layer, 124a: pixel, 124b: pixel, 125A: insulating film, 125: insulating layer, 127A: insulating film, 127: insulating layer, 130a: light-emitting device, 130b: light-emitting device, 130c: light-emitting device, 130: light-emitting device, 131: protective layer, 132B: coloring layer, 132G: coloring layer, 132R: coloring layer, 133: lens array, 134: insulating layer, 135G: color conversion layer, 135R: color conversion layer, 140: connection portion, 173_1a: groove, 173_1b: groove, 173_2a: groove, 173_2b: groove, 173_3a: groove, 173_3b: groove, 173_4: groove, 173a: groove, 173b: groove, 175_1: groove, 175_2: groove, 175_3: groove, 175: groove, 200A: display device, 200B: display device, 200C: display device, 200D: display device, 200E: display device, 200F: display device, 240: capacitor, 241: conductive layer, 243: insulating layer, 245: conductive layer, 251: conductive layer, 252: conductive layer, 254: insulating layer, 255: insulating layer, 256: plug, 261: insulating layer, 262: insulating layer, 263: insulating layer, 264: insulating layer, 265: insulating layer, 271: plug, 274a: conductive layer, 274b: conductive layer, 274: plug, 280: display module, 281: display portion, 282: circuit portion, 283a: pixel circuit, 283: pixel circuit portion, 284a: pixel, 284: pixel portion, 285: terminal portion, 286: wiring portion, 290: FPC, 291: substrate, 292: substrate, 300A: display device, 300B: display device, 300C: display device, 300D: display device, 300E: display device, 300F: display device, 301A: substrate, 301B: substrate, 301: substrate, 310A: transistor, 310B: transistor, 310: transistor, 311: conductive layer, 312: low-resistance region, 313: insulating layer, 314: insulating layer, 315: element isolation layer, 320A: transistor, 320B: transistor, 320: transistor, 321: semiconductor layer, 323: insulating layer, 324: conductive layer, 325: conductive layer, 326: insulating layer, 327: conductive layer, 328: insulating layer, 329: insulating layer, 331: substrate, 332: insulating layer, 335: insulating layer, 336: insulating layer, 341: conductive layer, 342: conductive layer, 343: plug, 344: insulating layer, 345: insulating layer, 346: insulating layer, 347: bump, 348: adhesive layer, 700A: electronic device, 700B: electronic device, 721: housing, 723: wearing portion, 727: earphone portion, 750: earphone, 751: display panel, 753: optical member, 756: display region, 757: frame, 758: node pad, 761: lower electrode, 762: upper electrode, 763a: light-emitting unit, 763b: light-emitting unit, 763c: light-emitting unit, 763: EL layer, 764: layer, 771a: light-emitting layer, 771b: light-emitting layer, 771c: light-emitting layer, 771: light-emitting layer, 772a: light-emitting layer, 772b: light-emitting layer, 772c: light-emitting layer, 772: light-emitting layer, 773: light-emitting layer, 780a: layer, 780b: layer, 780c: layer, 780: layer, 781: layer, 782: layer, 785: charge-generation layer, 790a: layer, 790b: layer, 790c: layer, 790: layer, 791: layer, 792: layer, 800A: electronic device, 800B: electronic device, 820: display portion, 821: housing, 822: communication portion, 823: wearing portion, 824: control portion, 825: image capturing portion, 827: earphone portion, 832: lens, 6500: electronic device, 6501: housing, 6502: display portion, 6503: power button, 6504: button, 6505: speaker, 6506: microphone, 6507: camera, 6508: light source, 6510: protection member, 6511: display panel, 6512: optical member, 6513: touch sensor panel, 6515: FPC, 6516: IC, 6517: printed circuit board, 6518: battery, 7000: display portion, 7100: television device, 7101: housing, 7103: stand, 7111: remote control, 7200: laptop personal computer, 7211: housing, 7212: keyboard, 7213: pointing device, 7214: external connection port, 7300: digital signage, 7301: housing, 7303: speaker, 7311: information terminal, 7400: digital signage, 7401: pillar, 7411: information terminal, 9000: housing, 9001: display portion, 9002: camera, 9003: speaker, 9005: operation key, 9006: connection terminal, 9007: sensor, 9008: microphone, 9050: icon, 9051: information, 9052: information, 9053: information, 9054: information, 9055: hinge, 9101: portable information terminal, 9102: portable information terminal, 9103: tablet terminal, 9200: portable information terminal, 9201: portable information terminal

1. A display device comprising:
a first light-emitting device, a second light-emitting device, a first insulating layer, a second insulating layer, a first coloring layer and a second coloring layer,
wherein the first light-emitting device comprises a first pixel electrode over the first insulating layer, a first layer over the first pixel electrode, and a common electrode over the first layer,
wherein the second light-emitting device comprises a second pixel electrode over the first insulating layer, a second layer over the second pixel electrode, and the common electrode over the second layer,
wherein the first insulating layer comprises a groove,
wherein the groove comprises a region overlapping with the first pixel electrode and a region overlapping with the second pixel electrode,
wherein the second insulating layer is over the first insulating layer,
wherein the second insulating layer and each of a side surface of the first layer, a side surface of the second layer and the groove,
wherein the common electrode comprises a portion positioned over the second insulating layer,
wherein the first coloring layer and the first light-emitting device overlap each other,
wherein the second coloring layer and the second light-emitting device overlap each other,
wherein the second coloring layer and the first coloring layer are configured to transmit light of different colors,
wherein the first layer and the second layer comprise the same light-emitting material, and
wherein the first layer and the second layer are apart from each other.

2. The display device according to claim 1, comprising a material layer,
wherein in the groove, the material layer is between the first insulating layer and the second insulating layer,
wherein the first layer, the second layer and the material layer comprise the same light-emitting material, and
wherein the first layer, the second layer and the material layer are apart from each other.

3. The display device according to claim 1,
wherein the second insulating layer comprises an organic material, and
wherein the second insulating layer is provided to fill the groove.

4. A display device comprising:
a first light-emitting device, a second light-emitting device, a first insulating layer, a second insulating layer, a first coloring layer and a second coloring layer,
wherein the first light-emitting device comprises a first pixel electrode over the first insulating layer, a first layer over the first pixel electrode, and a common electrode over the first layer,
wherein the second light-emitting device comprises a second pixel electrode over the first insulating layer, a second layer over the second pixel electrode, and the common electrode over the second layer,
wherein the first insulating layer comprises a first groove and a second groove in a region between the first pixel electrode and the second pixel electrode in a top view,
wherein the second insulating layer is over the first insulating layer,
wherein the second insulating layer and each of a side surface of the first layer, a side surface of the second layer, the first groove and the second groove overlap each other,
wherein the common electrode comprises a portion positioned over the second insulating layer,
wherein the first coloring layer and the first light-emitting device overlap each other,
wherein the second coloring layer and the second light-emitting device overlap each other,
wherein the second coloring layer and the first coloring layer are configured to transmit light of different colors, and
wherein the first layer and the second layer comprise the same light-emitting material, and
wherein the first layer and the second layer are apart from each other.

5. The display device according to claim 4, comprising a first material layer and a second material layer,
wherein in the first groove, the first material layer is positioned between the first insulating layer and the second insulating layer,
wherein in the second groove, the second material layer is positioned between the first insulating layer and the second insulating layer,
wherein the first layer, the second layer, the first material layer, and the second material layer comprise the same light-emitting material, and
wherein the first layer, the second layer, the first material layer and the second material layer are apart from each other.

6. The display device according to claim 4,
wherein the second insulating layer comprises an organic material, and
wherein the second insulating layer is provided to fill the first groove and the second groove.

7. The display device according to claim 1,
wherein each of the first layer and the second layer comprises a first light-emitting material capable of emitting blue light and a second light-emitting material capable of emitting light having a longer wavelength than blue light.

8. The display device according to claim 1, further comprising a color conversion layer,
wherein the color conversion layer is between the first light-emitting device and the first coloring layer,
wherein the color conversion layer is configured to convert blue light into first light having a longer wavelength,
wherein the first coloring layer is configured to transmit the first light,
wherein the second coloring layer is configured to transmit blue light, and
wherein the first light-emitting device and the second light-emitting device each emit blue light.

9. The display device according to claim 1,
wherein transmittance of one or two or more of red light, green light and blue light in the second insulating layer is lower than the transmittance in the first insulating layer.

10. The display device according to claim 1,
wherein the first insulating layer comprises a portion in contact with the first pixel electrode and a portion in contact with the second pixel electrode.

11. A display module comprising:
the display device according to claim 1; and
one or both of a connector and an integrated circuit.

12. An electronic device comprising:
the display module according to claim 11; and
one or more of a housing, a battery, a camera, a speaker and a microphone.

13. The display device according to claim 1, further comprising a third layer,
wherein the third layer and each of the first pixel electrode, the groove and the second pixel electrode overlap each other, and
wherein the third layer is interposed between the first layer and the common electrode and between the second layer and the common electrode.

14. The display device according to claim 4,
wherein the first layer and the second layer each comprise a first light-emitting material capable of emitting blue light and a second light-emitting material capable of emitting light having a longer wavelength than blue light.

15. The display device according to claim 4, further comprising a color conversion layer,
wherein the color conversion layer is between the first light-emitting device and the first coloring layer,
wherein the color conversion layer is configured to convert blue light into first light having a longer wavelength,
wherein the first coloring layer is configured to transmit the first light,
wherein the second coloring layer is configured to transmit blue light, and
wherein the first light-emitting device and the second light-emitting device each emit blue light.

16. The display device according to claim 4,
wherein transmittance of one of red light, green light and blue light in the second insulating layer is lower than the transmittance in the first insulating layer.

17. The display device according to claim 4,
wherein the first insulating layer comprises a portion in contact with the first pixel electrode and a portion in contact with the second pixel electrode.

18. A display module comprising:
the display device according to claim 4; and
one or both of a connector and an integrated circuit.

19. An electronic device comprising:
the display module according to claim 18; and
one or more of a housing, a battery, a camera, a speaker and a microphone.

20. The display device according to claim 4, further comprising a third layer,
wherein the third layer and each of the first pixel electrode, the second insulating layer and the second pixel electrode overlap each other, and
wherein the third layer is interposed between the first layer and the common electrode and between the second layer and the common electrode.
